(19) United States
(12) Patent Application Publication
(10) Pub. No.: US 2024/0049591 A1
(43) Pub. Date: Feb. 8, 2024

(54) DINUCLEAR PLATINUM COMPLEXES FOR OLED APPLICATION

(71) Applicants: The University of Hong Kong, Hong Kong (CN); Hong Kong Quantum AI Lab Limited, Hong Kong (CN)

(72) Inventors: Kar-Wai Lo, Hong Kong (CN); Chi-Ming Che, Hong Kong (CN); Gang Cheng, Hong Kong (CN)

(21) Appl. No.: 18/353,717

(22) Filed: Jul. 17, 2023

Related U.S. Application Data
(60) Provisional application No. 63/393,021, filed on Jul. 28, 2022.

(51) Int. Cl. H10K 85/30; C07F 15/00; C09K 11/06

(52) U.S. Cl. CPC H10K 85/346; C07F 15/0086; C09K 11/06; H10K 50/121

(57) ABSTRACT

Described herein are dinuclear platinum(II) emitter complexes and their methods of making and using thereof. The design of the dinuclear platinum(II) emitters results in short radiative lifetimes and high quantum yields. The dinuclear platinum(II) emitter complexes can be used to fabricate blue emitting OLEDs.

### CROSS-REFERENCE TO RELATED APPLICATIONS

This application claims benefit of and priority to U.S. Ser. No. 63/393,021, filed Jul. 28, 2022, which is incorporated herein by reference in its entirety.

### FIELD OF THE INVENTION

The disclosed invention is generally in the field of dinuclear platinum (II) emitter complexes, particularly dinuclear platinum (II) blue emitter complexes containing cyclometalating tridentate ligands, and their use in organic electronics, such as organic light-emitting devices (OLEDs).

### BACKGROUND OF THE INVENTION

Transition metal complexes have gained significant interest in commercial and academic settings as molecular probes, catalysts, and luminescent materials. As luminescent materials, transition metal complexes are increasingly being explored as potential alternatives to pure organic-based materials due to their potential for improved luminescence efficiency and device stability, compared to pure organic-based materials.

The search for operationally stable and high-efficiency blue emitters continues to be insurmountable. Thus, development of new emitters remains a high value target for the OLED industry. Extensive efforts in this area have been directed to the research and development of novel phosphorescent metal complexes. Recently, thermally activated delayed fluorescent (TADF) compounds have been developed due to their intrinsic advantages in achieving high device operational efficiency. These efforts, thus far, have resulted in limited success for these classes of emitter complexes where, as an example, issues concerning low quantum efficiencies, poor operational lifetime, and long radiative lifetimes of the emitters remain. Therefore, device performance and operational stability/lifetime of metal-based OLEDs must be enhanced for practical applications.

Accordingly, there remains a need to develop improved operationally stable and high-efficiency emitter complexes for OLED applications. There is also a need for elongating the operational lifetime of devices containing such emitters to more practical levels by tailoring the radiative lifetime of the emitters.

Therefore, it is an object of the present invention to provide new luminescent dinuclear transition metal complexes containing platinum (II) and cyclometalating tridentate ligands.

It is another object of the present invention to provide new fluorine-free, luminescent dinuclear transition metal complexes containing platinum (II) and cyclometalating tridentate ligands.

### SUMMARY OF THE INVENTION

Dinuclear platinum emitter complexes containing platinum (II) atoms complexed by tridentate N-heterocyclic carbene cyclometalating CCN ligands. The ligands contain a phenyl ring, an imidazolyl N-heterocyclic carbene ring, and a pyrazole ring. Exemplary dinuclear platinum (II) emitter complexes can have a structure as follows:

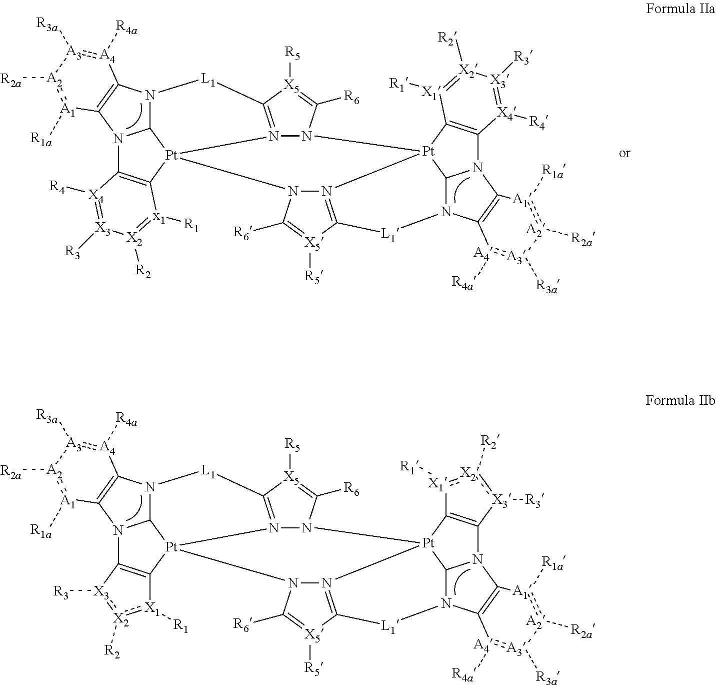

wherein:
the compound has an overall neutral, negative, or positive charge,
the dashed linear lines denote the presence or absence of a bond,
preferably, X₅ and X_{5′} are carbon,
preferably, X₁, X₂, X₃, X₄, X_{1′}, X_{2′}, X_{3′}, and X_{4′} when present, are independently carbon, nitrogen, oxygen, or sulfur, and are independently bonded to one or no hydrogen atom according to valency,
preferably R₅, R₆, R_{5′}, and R_{6′} are independently hydrogen, substituted alkyl, unsubstituted alkyl, substituted aryl, unsubstituted aryl, or R₅ and R₆ together, R₅, and R₆, together, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀ heterocyclyl, fused combinations thereof,
preferably, A₁, A₂, A₃, A₄, A_{1′}, A₂, A_{3′}, and A₄, are independently absent, hydrogen, deuterium, carbon, nitrogen, unsubstituted aryl, or substituted, and, when present, are independently bonded to one, two, three, four, five, or no hydrogen atom according to valency,
preferably, R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, unsubstituted aryl, substituted C₁-C₂₀heterocyclyl, unsubstituted C₁-C₂₀ heterocyclyl, a fused combination thereof (such as dibenzofuran-4-yl, dibenzofuran-3-yl, dibenzothiopen-4-yl, dibenzothiopen-3-yl, etc.), or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, fused combinations thereof,
preferably, R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted alkenyl, unsubstituted alkenyl, substituted alkynyl, unsubstituted alkynyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R_{1′} and R_{2′} together, R_{2′} and R_{3′} together, R_{3′} and R_{4′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof, and/or
preferably, L₁ and L_{1′} are independently substituted C₁-C₁₀ alkyl or unsubstituted C₁-C₁₀ alkyl, preferably wherein the substituted C₁-C₁₀ alkyl contains one or more alkyl substituents (such as methyl, ethyl, propyl, iso-propyl, n-butyl, sec-butyl, tert-butyl), one or more ether bonds, one or more amine groups (such as substituted amine or unsubstituted amine), one or more substituted aryl groups, one or more substituted heteroaryl groups, one or more substituted C₃-C₂₀ cycloalkyl groups, one or more substituted C₁-C₂₀ heterocyclyl groups, or a combination thereof. It is to be understood that L₁ and L_{1′} are at least divalent.

In some forms, the compound can have any one of the following structures:

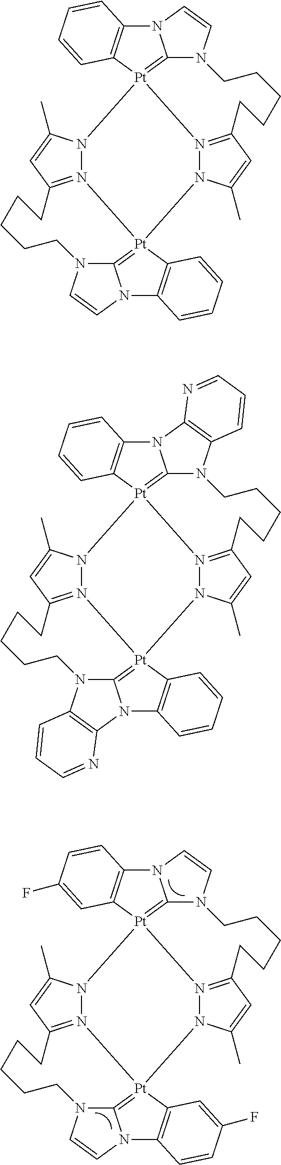

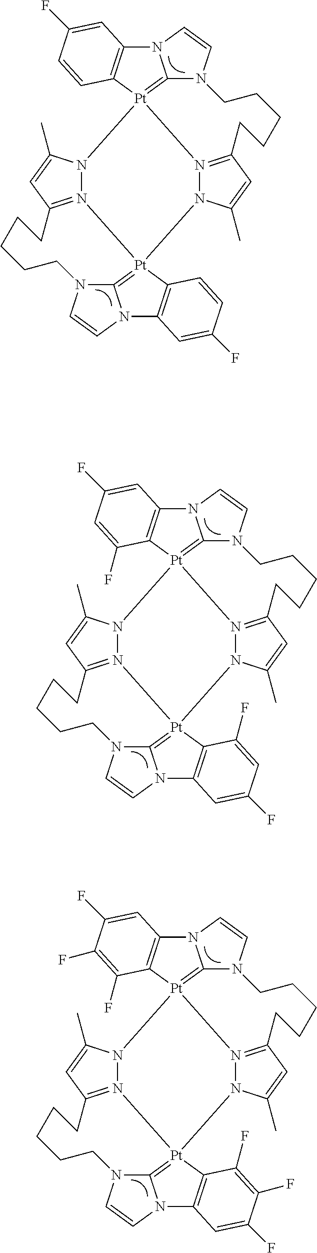

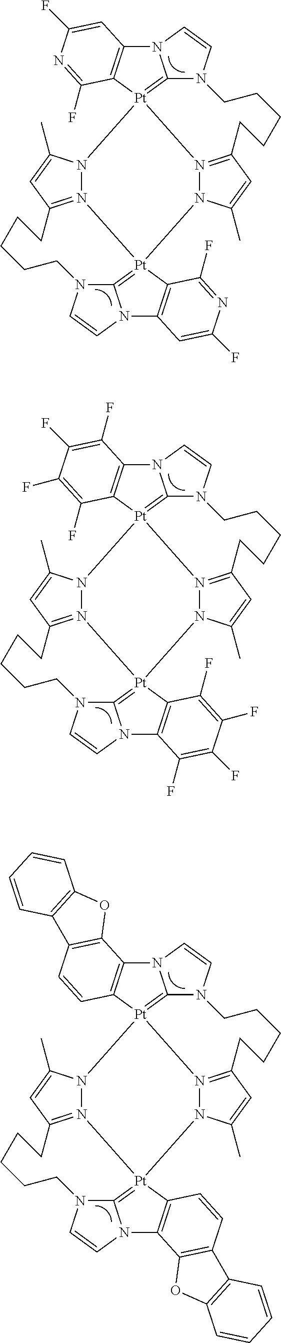

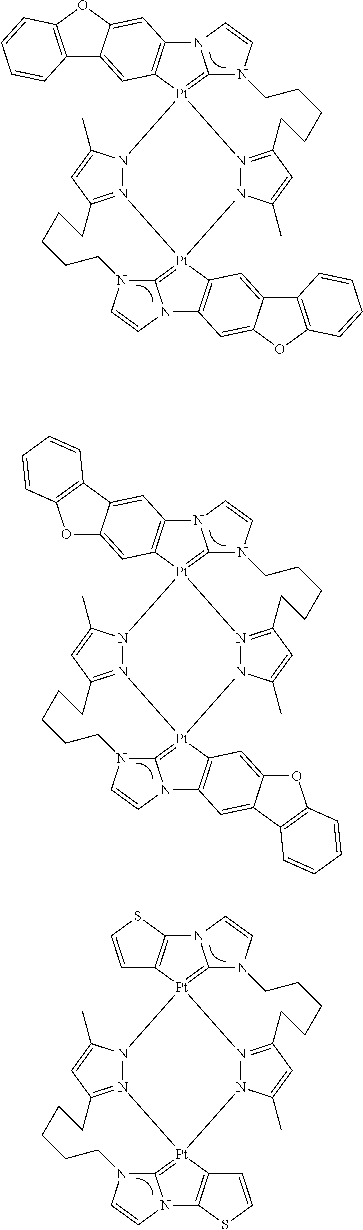

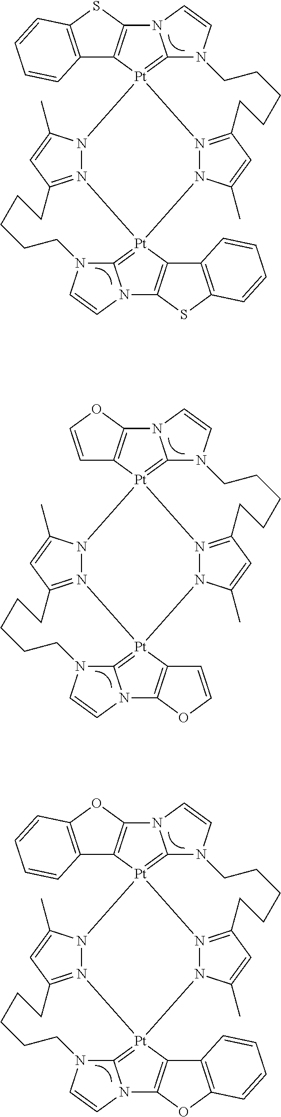

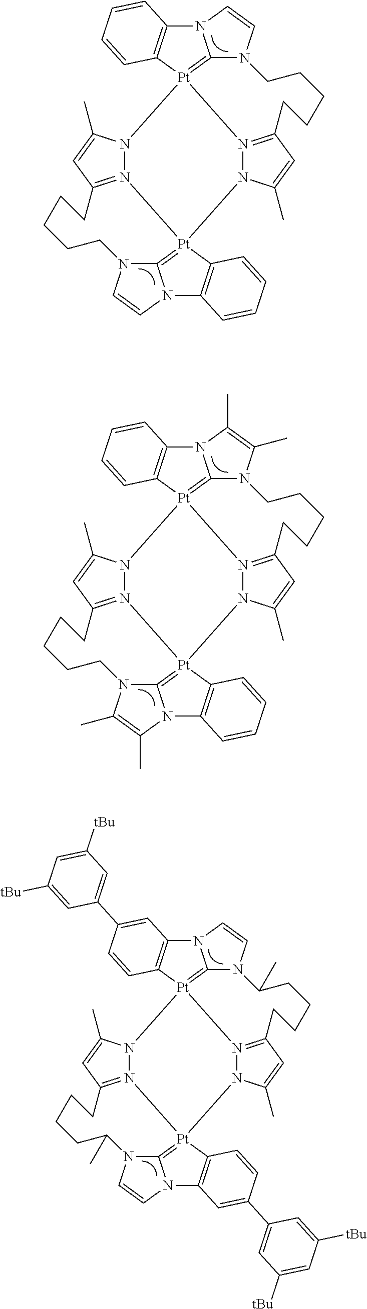

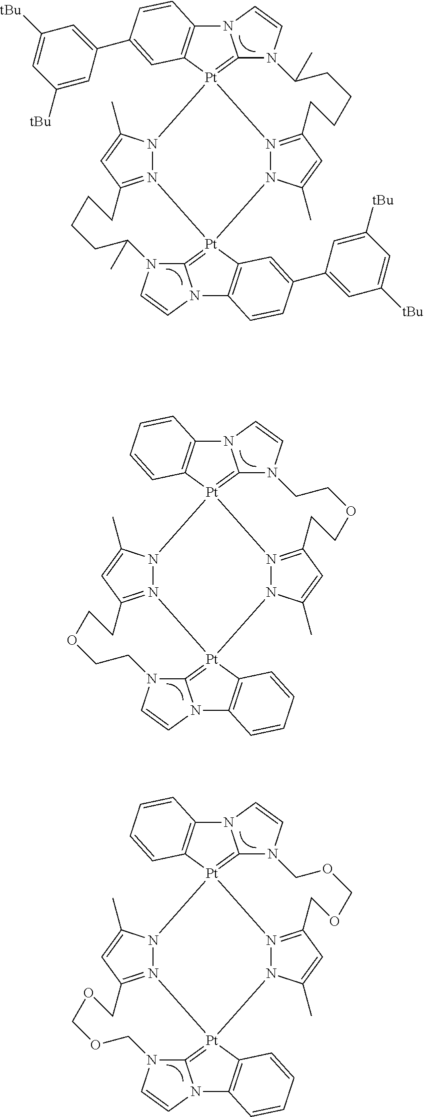

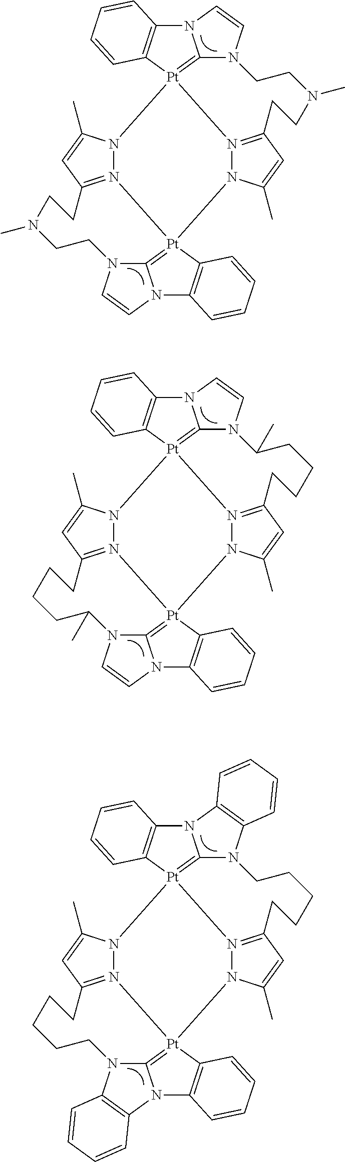

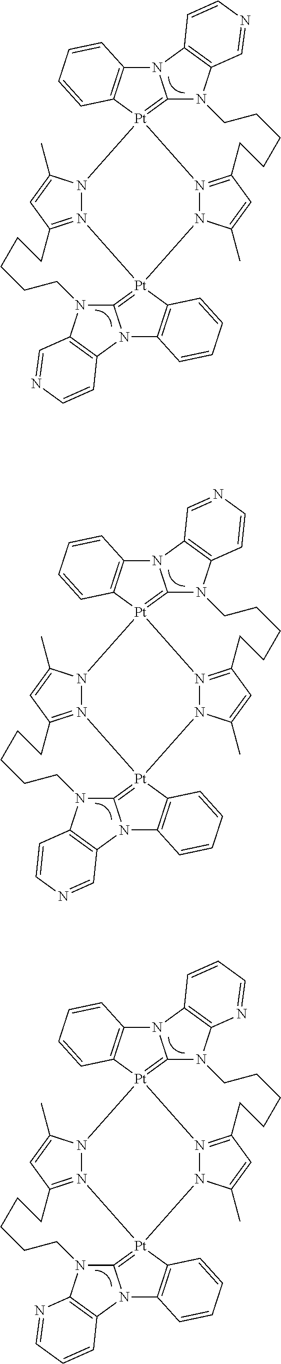

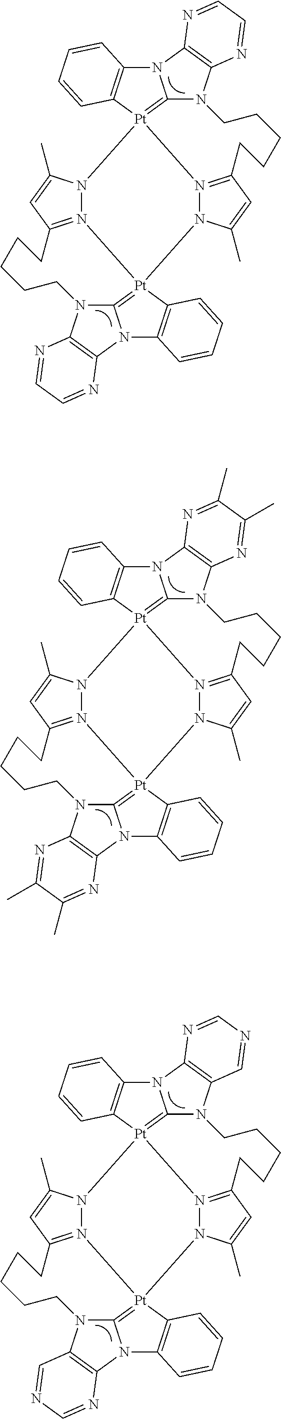

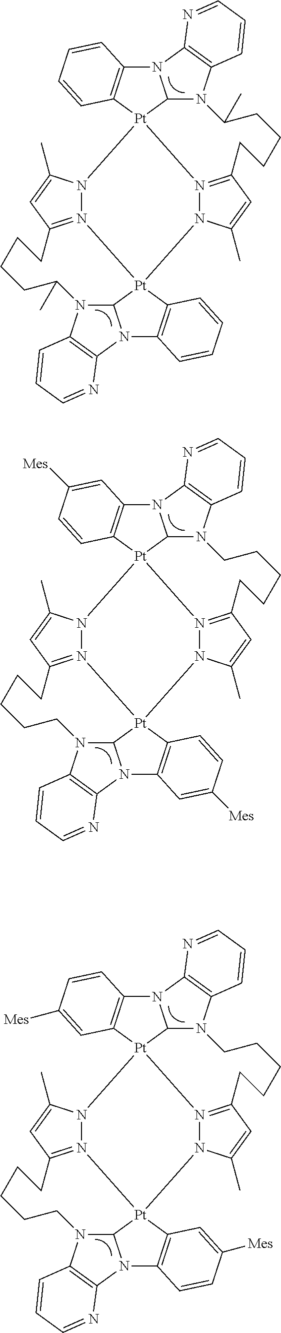

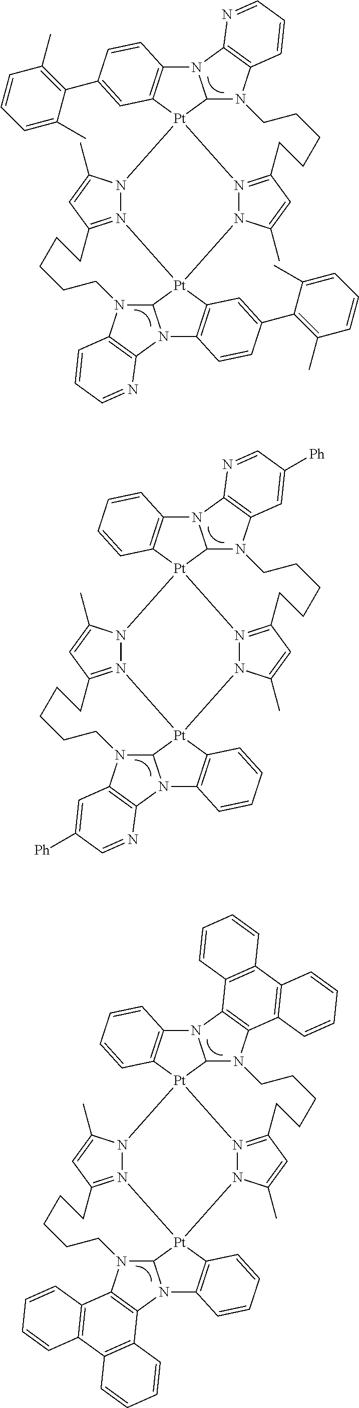

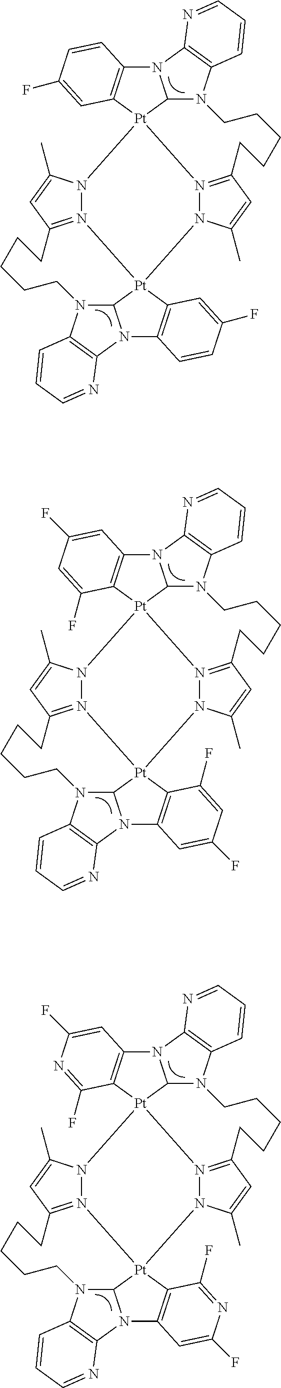

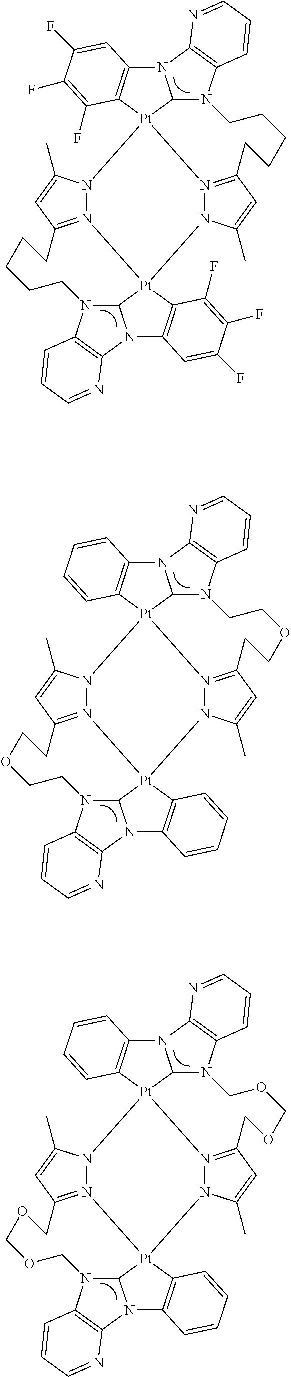

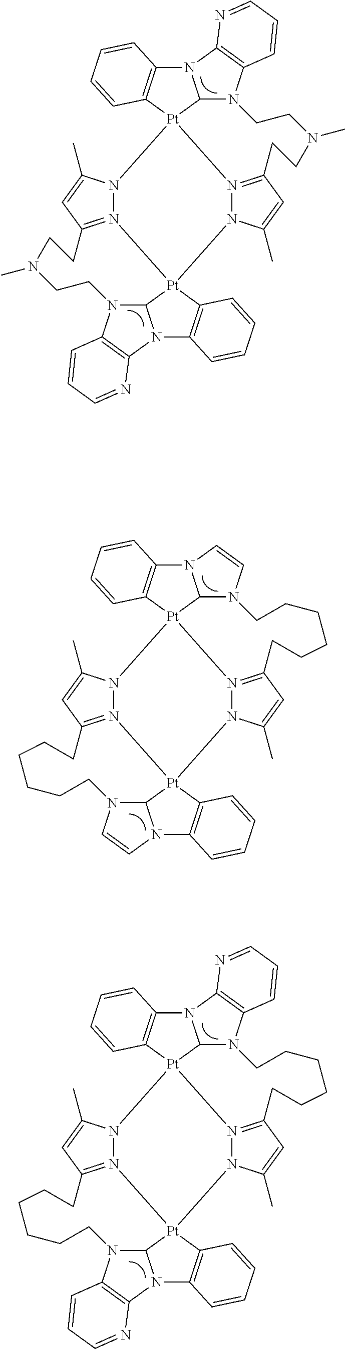

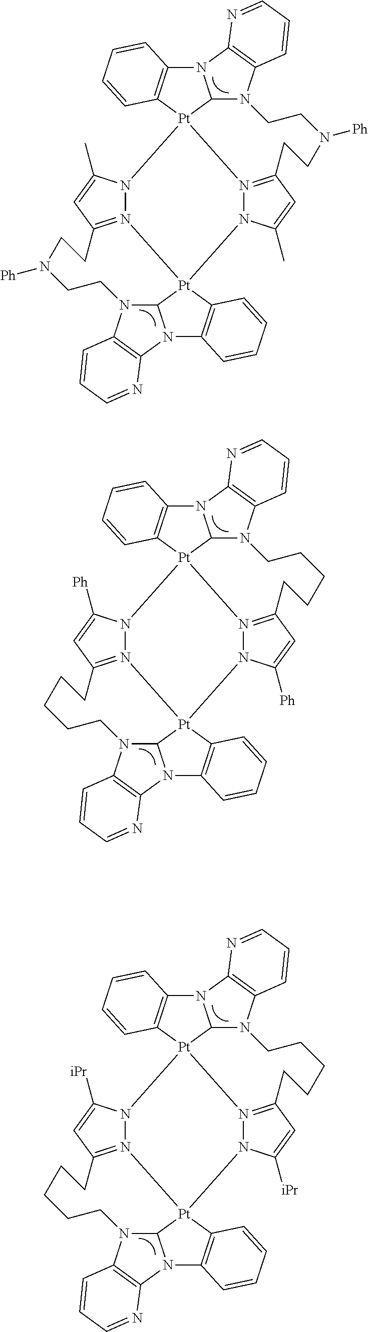

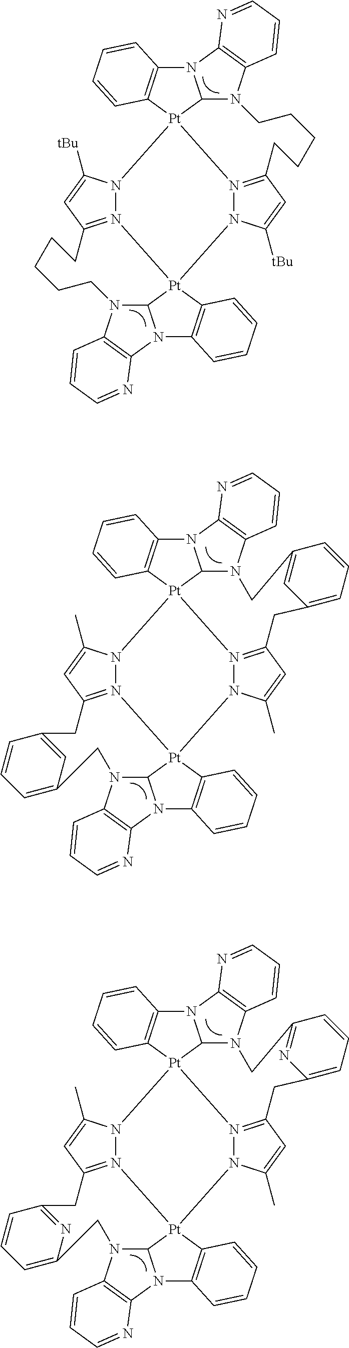

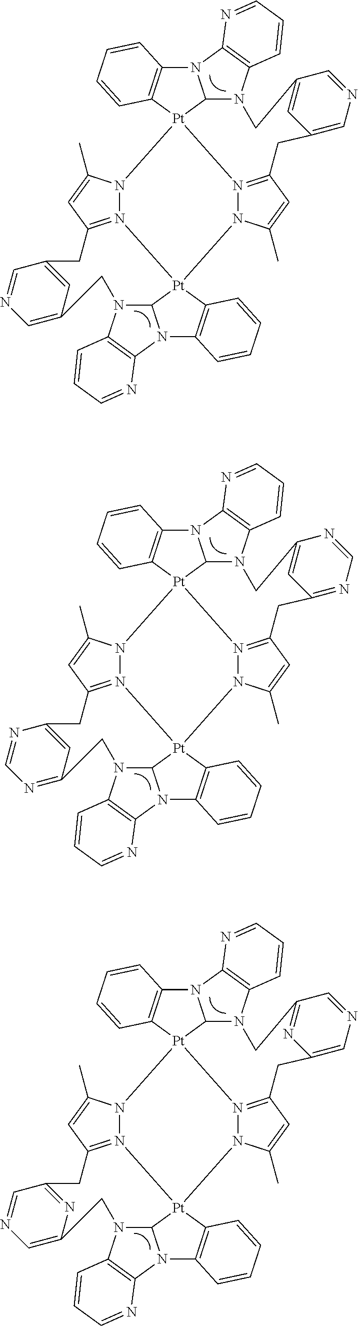

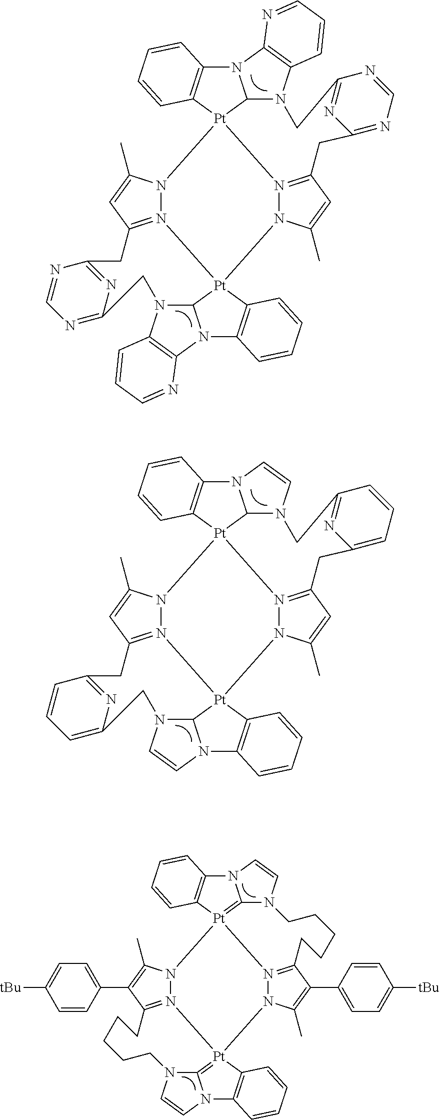

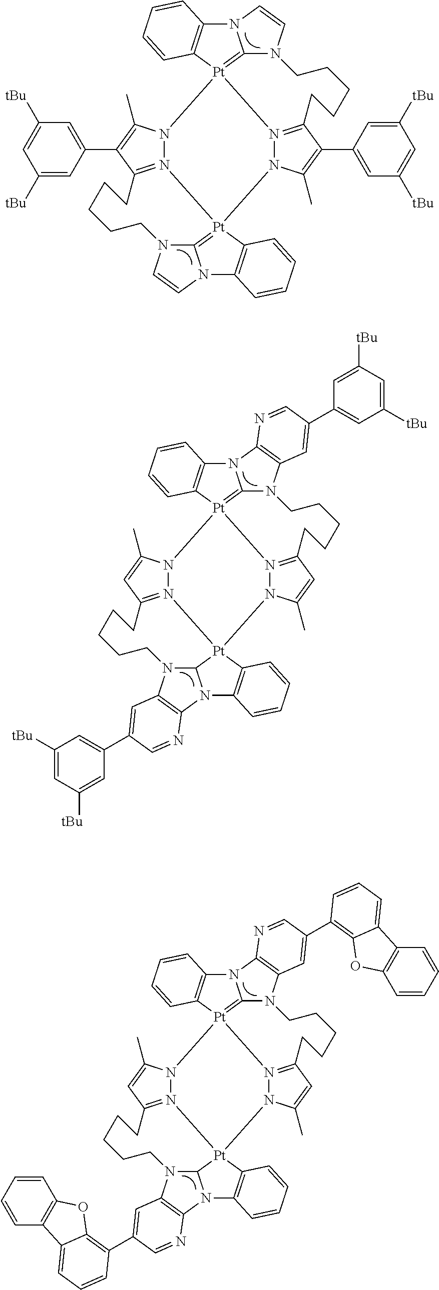

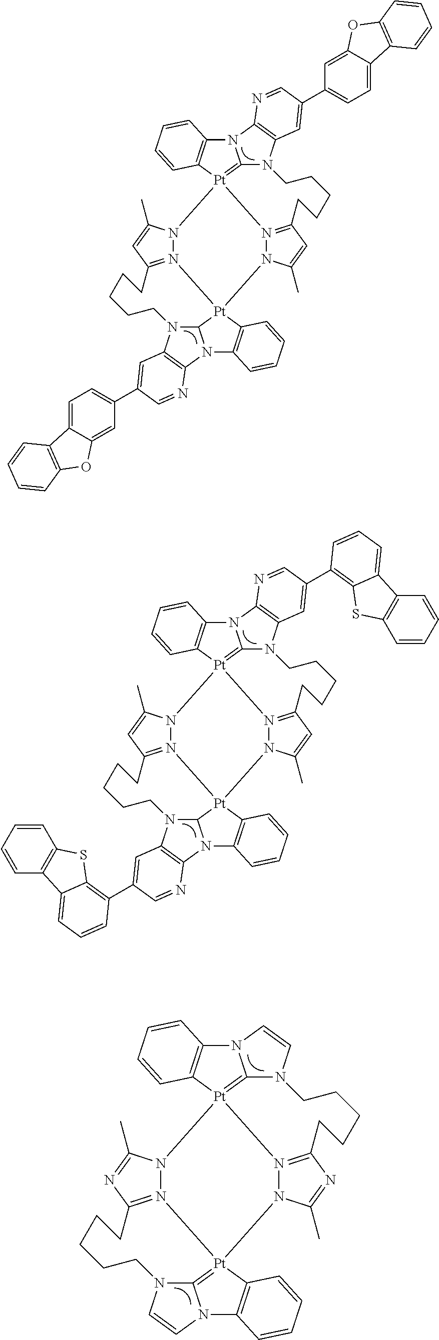

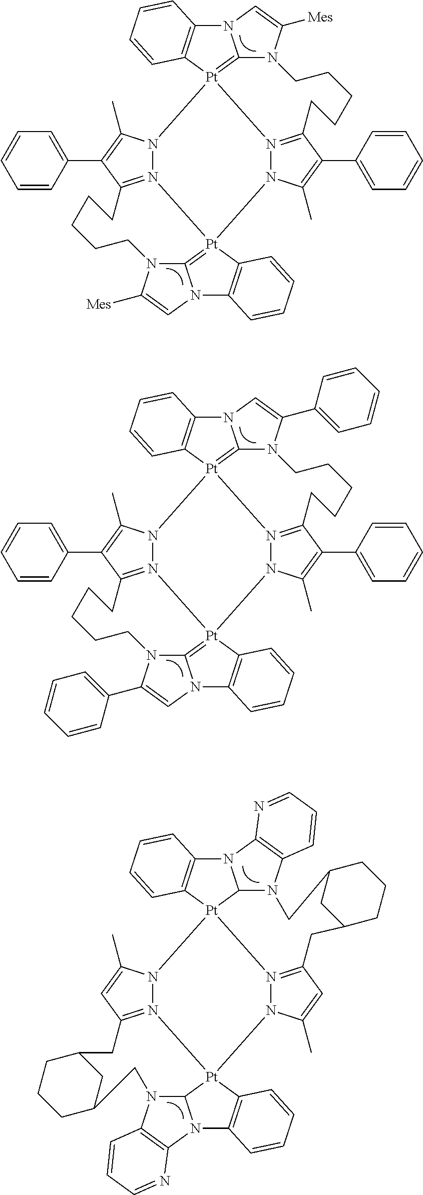

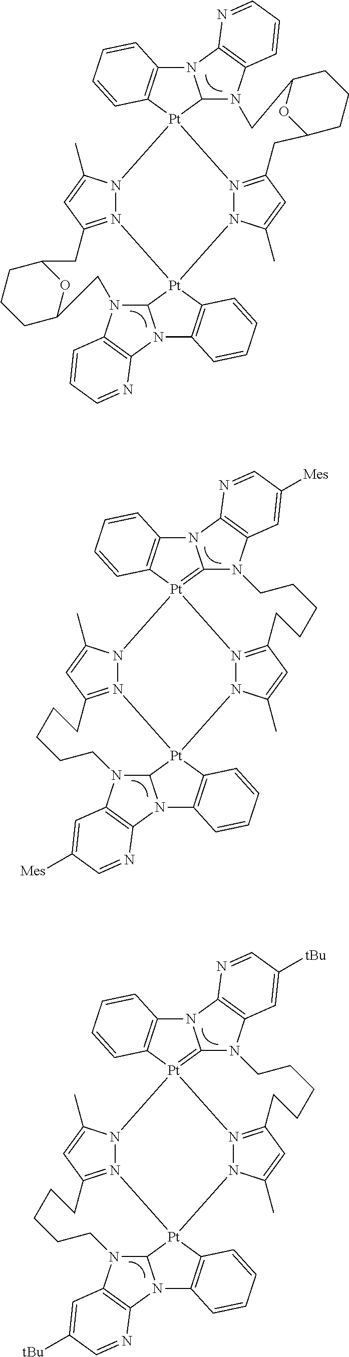

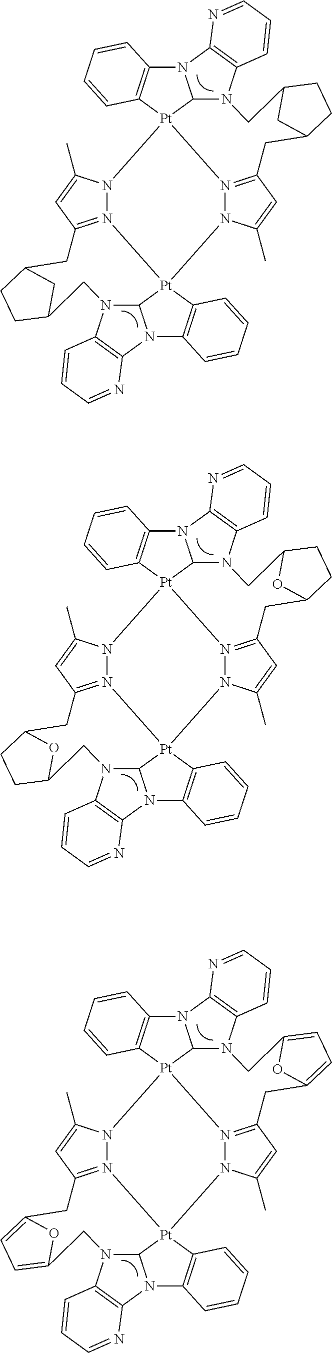

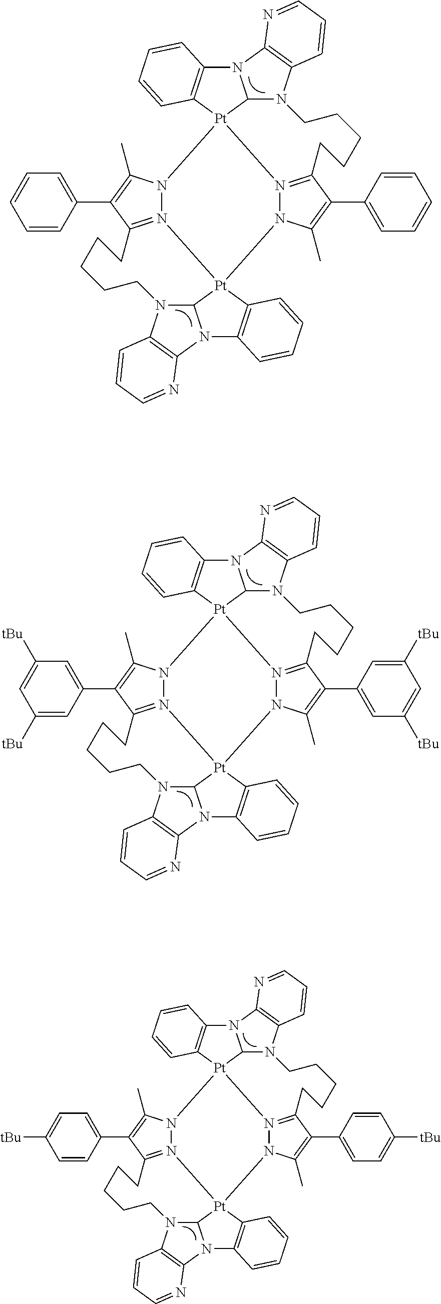

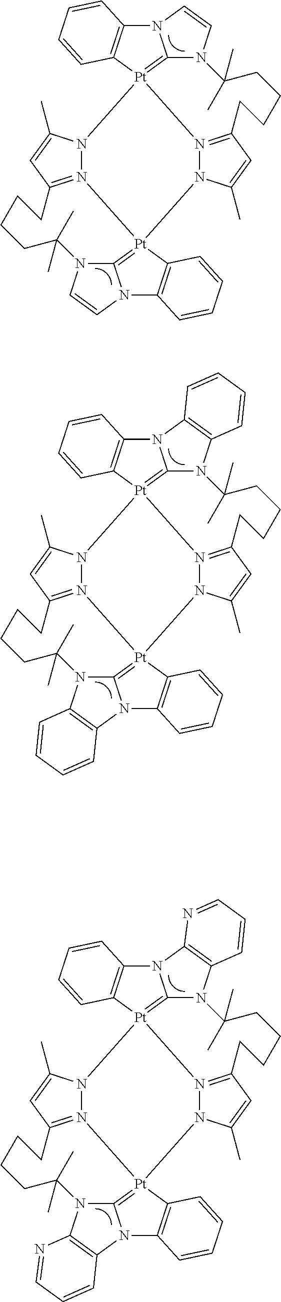

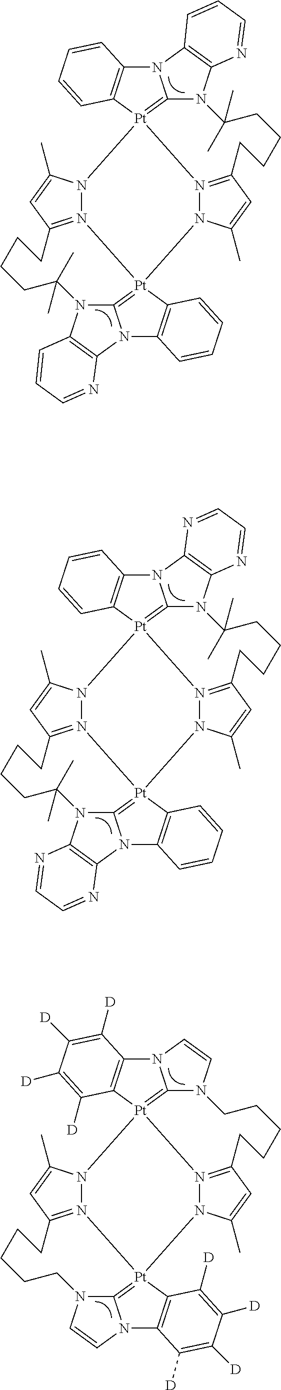

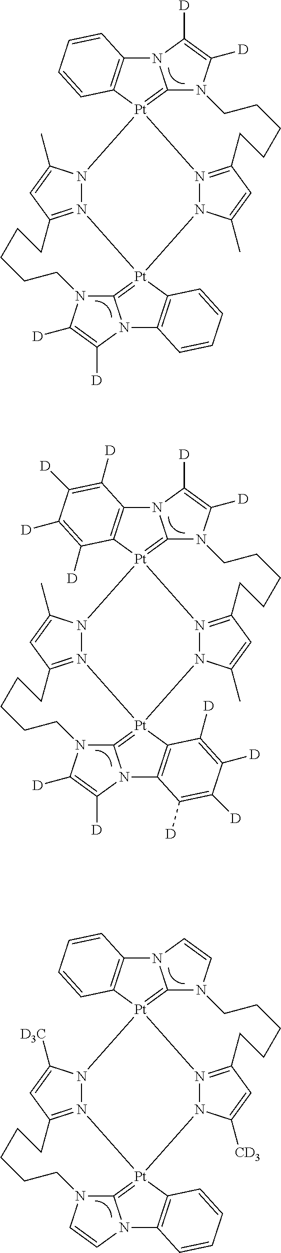

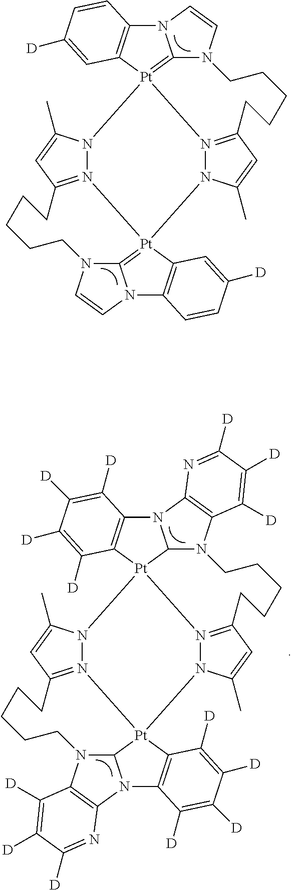

The dinuclear platinum emitter complexes described are phosphorescent and/or electroluminescent. The dinuclear platinum emitter complexes can be emissive at room temperature, low temperature, or both. The dinuclear platinum emitter complexes may be in a solid, liquid, glassy, film, or solution state. The dinuclear platinum emitter complexes can emit light in response to (i) the passage of an electric current or (ii) to an electric field. In some forms, the dinuclear platinum emitter complexes may emit light independent of concentration. The phosphorescent and/or electroluminescent properties of the dinuclear platinum emitter complexes are typically within a wavelength range of between about 380 nm and 550 nm, inclusive. In some forms, the dinuclear platinum emitter complexes preferably emit blue to deep-blue light within a wavelength range of between about 400 nm and 550 nm, inclusive, or any sub-range within. The emissive properties of the dinuclear platinum emitter complexes can be tuned by way of the selection of substituents. The dinuclear platinum emitter complexes may emit exclusively or predominantly in the blue wavelength range of the visible spectrum and may contain one or two emission maxima within.

Preferably, the dinuclear platinum(II) emitter complexes described herein are photo-stable, thermally stable, and/or are emissive at room temperatures, low temperatures, or a combination thereof. Accordingly, the complexes can be incorporated into OLEDs. Such OLEDs can be used in commercial applications such visual display units, mobile visual display units, illumination units, keyboards, clothes, ornaments, garment accessories, wearable devices, medical monitoring devices, wall papers, tablet computers, laptops, advertisement panels, panel display units, household appliances, or office appliances.

### BRIEF DESCRIPTION OF THE DRAWINGS

FIGS. 1A-1D are line graphs showing electroluminescent data for OLED fabricated with Pt-1 with doping concentrations between 4 wt/wt % and 16 wt/wt % (such as 4 wt/wt %, 8 wt/wt %, and 16 wt/wt %). The device structure is; ITO/HAT-CN(5 nm)/TAPC(40 nm)/TcTa(7 nm)/CzSi(3 nm)/Pt-1:CzSi (10 nm)/TSPO1(30 nm)/LiF (1 nm)/Al (100 nm).

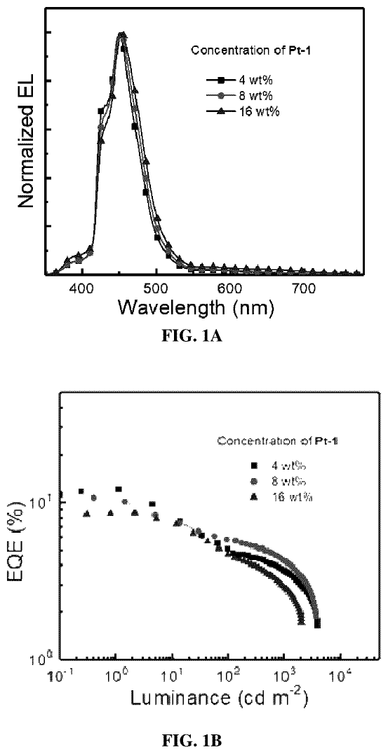

FIG. 2 shows a non-limiting example of an organic light-emitting diode device, 100, having a multilayer architecture. The device contains (i) a cathode 110 including a first layer 120 and a second layer 130; (ii) an electron transporting layer 140; (iii) an optional carrier confinement layer 150; (iv) a light-emitting layer 160; (v) a hole-transporting layer 170; and (vi) an anode 180.

FIG. 3 is a line graph showing the emission spectra of Pt-1 and Pt-2 in PMMA films.

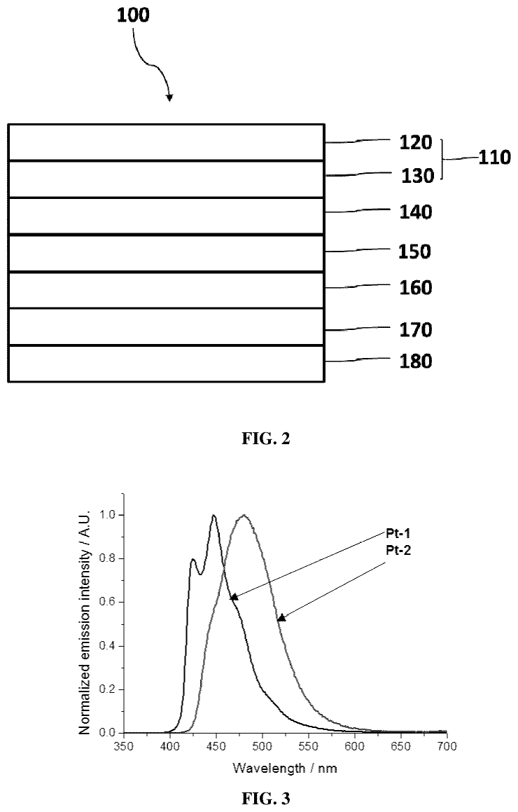

### DETAILED DESCRIPTION OF THE INVENTION

### I. Definitions

“Substituted,” as used herein, refers to all permissible substituents of the compounds or functional groups described herein. In the broadest sense, the permissible substituents include acyclic and cyclic, branched and unbranched, carbocyclic and heterocyclic, aromatic and nonaromatic substituents of organic compounds. Illustrative substituents include, but are not limited to, halogens, hydroxyl groups, or any other organic groupings containing any number of carbon atoms, preferably 1-14 carbon atoms, and optionally include one or more heteroatoms such as oxygen, sulfur, or nitrogen grouping in linear, branched, or cyclic structural formats. Representative substituents include a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, an amino acid. Such a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, and an amino acid can be further substituted.

Heteroatoms such as nitrogen may have hydrogen substituents and/or any permissible substituents of organic compounds described herein which satisfy the valences of the heteroatoms. It is understood that “substitution” or “substituted” includes the implicit proviso that such substitution is in accordance with permitted valence of the substituted atom and the substituent, and that the substitution results in a stable compound, i.e., a compound that does not spontaneously undergo transformation such as by rearrangement, cyclization, elimination, etc.

“Alkyl,” as used herein, refers to the radical of saturated aliphatic groups, including straight-chain alkyl groups, branched-chain alkyl, and cycloalkyl (alicyclic). In some forms, a straight chain or branched chain alkyl has 30 or fewer carbon atoms in its backbone (e.g., C₁-C₃₀ for straight chains, C₃-C₃₀ for branched chains), 20 or fewer, 15 or fewer, or 10 or fewer. Alkyl includes methyl, ethyl, n-propyl, isopropyl, n-butyl, isobutyl, t-butyl, pentyl, hexyl, heptyl, octyl, decyl, tetradecyl, hexadecyl, eicosyl, tetracosyl and the like. Likewise, a cycloalkyl is a non-aromatic carbon-based ring composed of at least three carbon atoms, such as a nonaromatic monocyclic or nonaromatic polycyclic ring containing 3-30 carbon atoms, 3-20 carbon atoms, or 3-10 carbon atoms in their ring structure, and have 5, 6 or 7 carbons in the ring structure. Cycloalkyls containing a polycyclic ring system can have two or more non-aromatic rings in which two or more carbons are common to two adjoining rings (i.e., “fused cycloalkyl rings”). Examples of cycloalkyl groups include, but are not limited to, cyclopropyl, cyclobutyl, cyclopentyl, cyclohexyl, cycloheptyl, cyclooctanyl, etc.

“Substituted alkyl” refers to alkyl moieties having one or more substituents replacing a hydrogen on one or more carbons of the hydrocarbon backbone. Such substituents can be any substituents described above, e.g., halogen (such as fluorine, chlorine, bromine, or iodine), hydroxyl, carbonyl (such as a carboxyl, alkoxycarbonyl, formyl, or an acyl), thiocarbonyl (such as a thioester, a thioacetate, or a thioformate), aryl, alkoxyl, aralkyl, phosphonium, phosphanyl, phosphonyl, phosphoryl, phosphate, phosphonate, a phosphinate, amino, amido, amidine, imine, cyano, nitro, azido, oxo, sulfhydryl, thiol, alkylthio, silyl, sulfinyl, sulfate, sulfonate, sulfamoyl, sulfonamido, sulfonyl, heterocyclyl, an aromatic or heteroaromatic moiety. —NRR′, wherein R and R′ are independently hydrogen, alkyl, or aryl, and wherein the nitrogen atom is optionally quaternized; —SR, wherein R is a phosphonyl, a sulfinyl, a silyl a hydrogen, an alkyl, or an aryl; —CN; —NO₂; —COOH; carboxylate; —COR, —COOR, or —CON(R)₂, wherein R is hydrogen, alkyl, or aryl; imino, silyl, ether, haloalkyl (such as —CF3, —CH₂—CF₃, —CCl₃); —CN; —NCOCOCH₂CH₂; —NCOCOCHCH; and —NCS; and combinations thereof.

It will be understood by those skilled in the art that the moieties substituted on the hydrocarbon chain can themselves be substituted, if appropriate. For instance, the substituents of a substituted alkyl may include halogen, hydroxy, nitro, thiols, amino, aralkyl, azido, imino, amido, phosphonium, phosphanyl, phosphoryl (including phosphonate and phosphinate), oxo, sulfonyl (including sulfate, sulfonamido, sulfamoyl and sulfonate), and silyl groups, as well as ethers, alkylthios, carbonyls (including ketones, aldehydes, carboxylates, and esters), haloalkyls, —CN and the like. Cycloalkyls can be substituted in the same manner.

Unless the number of carbons is otherwise specified, “lower alkyl” as used herein means an alkyl group, as defined above, but having from one to ten carbons, more preferably from one to six carbon atoms in its backbone structure. Likewise, “lower alkenyl” and “lower alkynyl” have similar chain lengths.

“Heteroalkyl,” as used herein, refers to straight or branched chain, or cyclic carbon-containing alkyl radicals, or combinations thereof, containing at least one heteroatom on the carbon backbone. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkyl group” is a cycloalkyl group as defined above where at least one of the carbon atoms of the ring is substituted with a heteroatom such as, but not limited to, nitrogen, oxygen, sulphur, or phosphorus.

The term “alkenyl” as used herein is a hydrocarbon group of from 2 to 24 carbon atoms and structural formula containing at least one carbon-carbon double bond. Alkenyl groups include straight-chain alkenyl groups, branched-chain alkenyl, and cycloalkenyl. A cycloalkenyl is a non-aromatic carbon-based ring composed of at least three carbon atoms and at least one carbon-carbon double bond, such as a nonaromatic monocyclic or nonaromatic polycyclic ring containing 3-30 carbon atoms and at least one carbon-carbon double bond, 3-20 carbon atoms and at least one carbon-carbon double bond, or 3-10 carbon atoms and at least one carbon-carbon double bond in their ring structure, and have 5, 6 or 7 carbons and at least one carbon-carbon double bond in the ring structure. Cycloalkenyls containing a polycyclic ring system can have two or more non-aromatic rings in which two or more carbons are common to two adjoining rings (i.e., “fused cycloalkenyl rings”) and contain at least one carbon-carbon double bond. Asymmetric structures such as (AB)C═C(C′D) are intended to include both the E and Z isomers. This may be presumed in structural formulae herein wherein an asymmetric alkene is present, or it may be explicitly indicated by the bond symbol C. The term “alkenyl” as used throughout the specification, examples, and claims is intended to include both “unsubstituted alkenyls” and “substituted alkenyls,” the latter of which refers to alkenyl moieties having one or more substituents replacing a hydrogen on one or more carbons of the hydrocarbon backbone. The term “alkenyl” also includes “heteroalkenyl.”

The term “substituted alkenyl” refers to alkenyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, oxo, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

“Heteroalkenyl,” as used herein, refers to straight or branched chain, or cyclic carbon-containing alkenyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkenyl group” is a cycloalkenyl group where at least one of the carbon atoms of the ring is substituted with a heteroatom such as, but not limited to, nitrogen, oxygen, sulphur, or phosphorus.

The term “alkynyl group” as used herein is a hydrocarbon group of 2 to 24 carbon atoms and a structural formula containing at least one carbon-carbon triple bond. Alkynyl groups include straight-chain alkynyl groups, branched-chain alkynyl, and cycloalkynyl. A cycloalkynyl is a non-aromatic carbon-based ring composed of at least three carbon atoms and at least one carbon-carbon triple bond, such as a nonaromatic monocyclic or nonaromatic polycyclic ring containing 3-30 carbon atoms and at least one carbon-carbon triple bond, 3-20 carbon atoms and at least one carbon-carbon triple bond, or 3-10 carbon atoms and at least one carbon-carbon triple bond in their ring structure, and have 5, 6 or 7 carbons and at least one carbon-carbon triple bond in the ring structure. Cycloalkynyls containing a polycyclic ring system can have two or more non-aromatic rings in which two or more carbons are common to two adjoining rings (i.e., “fused cycloalkynyl rings”) and contain at least one carbon-carbon triple bond. Asymmetric structures such as (AB)C═C(C″D) are intended to include both the E and Z isomers. This may be presumed in structural formulae herein wherein an asymmetric alkyne is present, or it may be explicitly indicated by the bond symbol C. The term “alkynyl” as used throughout the specification, examples, and claims is intended to include both “unsubstituted alkynyls” and “substituted alkynyls,” the latter of which refers to alkynyl moieties having one or more substituents replacing a hydrogen on one or more carbons of the hydrocarbon backbone. The term “alkynyl” also includes “heteroalkynyl.”

The term “substituted alkynyl” refers to alkynyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

“Heteroalkynyl,” as used herein, refers to straight or branched chain, or cyclic carbon-containing alkynyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkynyl group” is a cycloalkynyl group where at least one of the carbon atoms of the ring is substituted with a heteroatom such as, but not limited to, nitrogen, oxygen, sulphur, or phosphorus.

“Aryl,” as used herein, refers to C₅-C₂₆-membered aromatic or fused aromatic ring systems. Examples of aromatic groups are benzene, naphthalene, anthracene, phenanthrene, chrysene, pyrene, corannulene, coronene, etc.

The term “substituted aryl” refers to an aryl group, wherein one or more hydrogen atoms on one or more aromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), —CN, aryl, heteroaryl, and combinations thereof.

“Heterocycle” and “heterocyclyl” are used interchangeably, and refer to a cyclic radical attached via a ring carbon or nitrogen atom of a non-aromatic monocyclic or polycyclic ring containing 3-30 ring atoms, 3-20 ring atoms, 3-10 ring atoms, or 5-6 ring atoms, where each ring contains carbon and one to four heteroatoms each selected from the group consisting of non-peroxide oxygen, sulfur, and N(Y) wherein Y is absent or is H, O, C₁-C₁₀ alkyl, phenyl or benzyl, and optionally containing 1-3 double bonds and optionally substituted with one or more substituents. Heterocyclyl are distinguished from heteroaryl by definition. Heterocycles can be a heterocycloalkyl, a heterocycloalkenyl, a heterocycloalkynyl, etc, such as piperazinyl, piperidinyl, piperidonyl, 4-piperidonyl, dihydrofuro[2,3-b]tetrahydrofuran, morpholinyl, piperazinyl, piperidinyl, piperidonyl, 4-piperidonyl, piperonyl, pyranyl, 2H-pyrrolyl, 4H-quinolizinyl, quinuclidinyl, tetrahydrofuranyl, 6H-1,2,5-thiadiazinyl. Heterocyclic groups can optionally be substituted with one or more substituents as defined above for alkyl and aryl.

The term “heteroaryl” refers to C₅-C₂₆-membered aromatic or fused aromatic ring systems, in which one or more carbon atoms on one or more aromatic ring structures have been substituted with a heteroatom. Suitable heteroatoms include, but are not limited to, oxygen, sulfur, and nitrogen. Examples of heteroaryl groups pyrrole, furan, thiophene, imidazole, oxazole, thiazole, triazole, tetrazole, pyrazole, pyridine, pyrazine, pyridazine and pyrimidine, and the like. Examples of heteroaryl rings include, but are not limited to, benzimidazolyl, benzofuranyl, benzothiofuranyl, benzothiophenyl, benzoxazolyl, benzoxazolinyl, benzthiazolyl, benztriazolyl, benztetrazolyl, benzisoxazolyl, benzisothiazolyl, benzimidazolinyl, carbazolyl, 4aH-carbazolyl, carbolinyl, chromanyl, chromenyl, cinnolinyl, decahydroquinolinyl, 2H,6H-1,5,2-dithiazinyl, furanyl, furazanyl, imidazolidinyl, imidazolinyl, imidazolyl, 1H-indazolyl, indolenyl, indolinyl, indolizinyl, indolyl, 3H-indolyl, isatinoyl, isobenzofuranyl, isochromanyl, isoindazolyl, isoindolinyl, isoindolyl, isoquinolinyl, isothiazolyl, isoxazolyl, methylenedioxyphenyl, naphthyridinyl, octahydroisoquinolinyl, 1,2,3-oxadiazolyl, 1,2,4-oxadiazolyl, 1,2,5-oxadiazolyl, 1,3,4-oxadiazolyl, oxazolidinyl, oxazolyl, oxindolyl, pyrimidinyl, phenanthridinyl, phenanthrolinyl, phenazinyl, phenothiazinyl, phenoxathinyl, phenoxazinyl, phthalazinyl, pteridinyl, purinyl, pyrazinyl, pyrazolidinyl, pyrazolinyl, pyrazolyl, pyridazinyl, pyridooxazole, pyridoimidazole, pyridothiazole, pyridinyl, pyridyl, pyrimidinyl, pyrrolidinyl, pyrrolinyl, pyrrolyl, quinazolinyl, quinolinyl, quinoxalinyl, tetrahydroisoquinolinyl, tetrahydroquinolinyl, tetrazolyl, 1,2,3-thiadiazolyl, 1,2,4-thiadiazolyl, 1,2,5-thiadiazolyl, 1,3,4-thiadiazolyl, thianthrenyl, thiazolyl, thienyl, thienothiazolyl, thienooxazolyl, thienoimidazolyl, thiophenyl and xanthenyl. One or more of the rings can be substituted as defined below for “substituted heteroaryl.”

The term “substituted heteroaryl” refers to a heteroaryl group in which one or more hydrogen atoms on one or more heteroaromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), —CN, aryl, heteroaryl, and combinations thereof.

The term “polyaryl” refers to a chemical moiety that includes two or more fused aryl groups. When two or more fused heteroaryl groups are involved, the chemical moiety can be referred to as a “polyheteroaryl.”

The term “substituted polyaryl” refers to a polyaryl in which one or more of the aryls are substituted, with one or more substituents including, but not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfoxide, sulfonamido, sulfonyl, heterocyclyl, alkylaryl, haloalkyl, —CN, aryl, heteroaryl, and combinations thereof. When a polyheteroaryl is involved, the chemical moiety can be referred to as a “substituted polyheteroaryl.”

The term “cyclic ring” or “cyclic group” refers to a substituted or unsubstituted monocyclic ring or a substituted or unsubstituted polycyclic ring (such as those formed from single or fused ring systems), such as a substituted or unsubstituted cycloalkyl, a substituted or unsubstituted cycloalkenyl, a substituted or unsubstituted cycloalkynyl, or a substituted or unsubstituted heterocyclyl, that have from three to 30 carbon atoms, as geometric constraints permit. The substituted cycloalkyls, cycloalkenyls, cycloalkynyls, and heterocyclyls are substituted as defined above for the alkyls, alkenyls, alkynyls, and heterocyclyls, respectively.

The term “aralkyl” as used herein is an aryl group or a heteroaryl group having an alkyl, alkynyl, or alkenyl group as defined above attached to the aromatic group, such as an aryl, a heteroaryl, a polyaryl, or a polyheteroaryl. An example of an aralkyl group is a benzyl group.

The terms “alkoxyl” or “alkoxy,” “aroxy” or “aryloxy,” generally describe compounds represented by the formula —OR^{v}, wherein R^{v} includes, but is not limited to, a substituted or unsubstituted alkyl, a substituted or unsubstituted alkenyl, a substituted or unsubstituted alkynyl, a substituted or unsubstituted cycloalkyl, a substituted or unsubstituted heterocyclyl, a substituted or unsubstituted cycloalkenyl, a substituted or unsubstituted heterocycloalkenyl, a substituted or unsubstituted aryl, a substituted or unsubstituted heteroaryl, a substituted or unsubstituted polyaryl, a substituted or unsubstituted polyheteroaryl, a substituted or unsubstituted arylalkyl, a substituted or unsubstituted heteroalkyl, a substituted or unsubstituted alkylaryl, a substituted or unsubstituted alkylheteroaryl, a substituted or unsubstituted aralkyl, a substituted or unsubstituted carbonyl, a phosphonium, a phosphanyl, a phosphonyl, a sulfinyl, a silyl, a thiol, an amido, and an amino. Exemplary alkoxyl groups include methoxy, ethoxy, propyloxy, tert-butoxy and the like. A “lower alkoxy” group is an alkoxy group containing from one to six carbon atoms. An “ether” is two functional groups covalently linked by an oxygen as defined below. Accordingly, the substituent of an alkyl that renders that alkyl an ether is or resembles an alkoxyl, such as can be represented by one of —O-alkyl, —O-alkenyl, —O-alkynyl, —O— arakyl, —O-aryl, —O-heteroaryl, —O-polyaryl, —O-polyheteroaryl, —O-heterocyclyl, etc.

The term “substituted alkoxy” refers to an alkoxy group having one or more substituents replacing one or more hydrogen atoms on one or more carbons of the alkoxy backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, oxo, sulfate, sulfonate, sulfamoyl, sulfonamido, sulfonyl, heterocyclyl, alkylaryl, haloalkyl, —CN, aryl, heteroaryl, and combinations thereof.

The term “ether” as used herein is represented by the formula A²OA¹, where A² and A¹ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a phosphonyl, a sulfinyl, a silyl, a thiol, a substituted or unsubstituted carbonyl, an alkoxy, an amido, or an amino, described above.

The term “polyether” as used herein is represented by the formula:

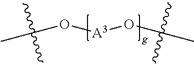

where A³ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a substituted or unsubstituted carbonyl, an alkoxy, an amido, or an amino, described above; g can be a positive integer from 1 to 30.

The term “phenoxy” is art recognized and refers to a compound of the formula —OR^{v} wherein R^{v} is C₆H₅(i.e., —O—C₆H₅). One of skill in the art recognizes that a phenoxy is a species of the aroxy genus.

The term “substituted phenoxy” refers to a phenoxy group, as defined above, having one or more substituents replacing one or more hydrogen atoms on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The terms “aroxy” and “aryloxy,” as used interchangeably herein, are represented by —O-aryl or —O-heteroaryl, wherein aryl and heteroaryl are as defined herein.

The terms “substituted aroxy” and “substituted aryloxy,” as used interchangeably herein, represent —O-aryl or —O-heteroaryl, having one or more substituents replacing one or more hydrogen atoms on one or more ring atoms of the aryl and heteroaryl, as defined herein. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The term “amino” as used herein includes the group

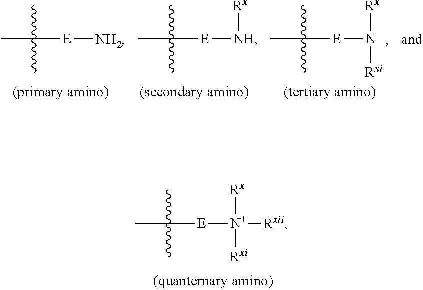

wherein, E is absent, or E is substituted or unsubstituted alkyl, substituted or unsubstituted alkenyl, substituted or unsubstituted alkynyl, substituted or unsubstituted aralkyl, substituted or unsubstituted aryl, substituted or unsubstituted heteroaryl, a substituted or unsubstituted polyaryl, a substituted or unsubstituted polyheteroaryl, substituted or unsubstituted heterocyclyl, wherein independently of E, R^{x}, R^{xi}, and R^{xii} each independently represent a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. The term “quaternary amino” also includes the groups where the nitrogen, R^{x}, R^{xi}, and R^{xii} with the N⁺ to which they are attached complete a heterocyclyl or heteroaryl having from 3 to 14 atoms in the ring structure. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The terms “amide” or “amido” are used interchangeably, refer to both “unsubstituted amido” and “substituted amido” and are represented by the general formula:

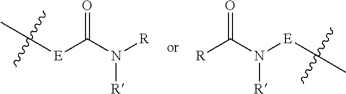

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted aryl, substituted or unsubstituted heteroaryl, a substituted or unsubstituted polyaryl, a substituted or unsubstituted polyheteroaryl, or a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. In some forms, when E is oxygen, a carbamate is formed. It is understood by those of ordinary skill in the art, that the E groups listed above are divalent (e.g., methylene, ethane-1,2-diyl, ethene-1,2-diyl, 1,4-phenylene, cyclohexane-1,2-diyl).

“Carbonyl,” as used herein, is art-recognized and includes such moieties as can be represented by the general formula:

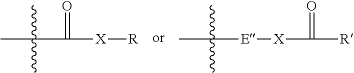

wherein X is a bond, or represents an oxygen or a sulfur, and R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″, or a pharmaceutical acceptable salt; E″ is absent, or E″ is a substituted or unsubstituted alkyl, a substituted or unsubstituted alkenyl, a substituted or unsubstituted alkynyl, a substituted or unsubstituted aralkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl; R′ represents a hydrogen, a substituted or unsubstituted alkyl, a substituted or unsubstituted alkenyl, a substituted or unsubstituted alkynyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″; R″ represents a hydroxyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof. It is understood by those of ordinary skill in the art, that the E″ groups listed above are divalent (e.g., methylene, ethane-1,2-diyl, ethene-1,2-diyl, 1,4-phenylene, cyclohexane-1,2-diyl). Where X is oxygen and R is defined as above, the moiety is also referred to as a carboxyl group. When X is oxygen and R is hydrogen, the formula represents a “carboxylic acid.” Where X is oxygen and R′ is hydrogen, the formula represents a “formate.” Where X is oxygen and R or R′ is not hydrogen, the formula represents an “ester.” In general, where the oxygen atom of the above formula is replaced by a sulfur atom, the formula represents a “thiocarbonyl” group. Where X is sulfur and R or R′ is not hydrogen, the formula represents a “thioester.” Where X is sulfur and R is hydrogen, the formula represents a “thiocarboxylic acid.” Where X is sulfur and R′ is hydrogen, the formula represents a “thioformate.” Where X is a bond and R is not hydrogen, the above formula represents a “ketone.” Where X is a bond and R is hydrogen, the above formula represents an “aldehyde.”

The term “phosphanyl” is represented by the formula

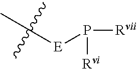

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi} and R^{vii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonium” is represented by the formula

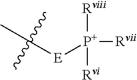

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi}, R^{vii}, and R^{viii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi}, R^{vii}, and R^{viii} taken together with the P⁺ atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonyl” is represented by the formula

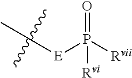

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, oxygen, alkoxy, aroxy, or substituted alkoxy or substituted aroxy, wherein, independently of E, R^{vi} and R^{vii} are independently a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphoryl” defines a phosphonyl in which E is absent, oxygen, alkoxy, aroxy, substituted alkoxy or substituted aroxy, as defined above, and independently of E, R^{vi} and R^{vii} are independently hydroxyl, alkoxy, aroxy, substituted alkoxy or substituted aroxy, as defined above. When E is oxygen, the phosphoryl cannot be attached to another chemical species, such as to form an oxygen-oxygen bond, or other unstable bonds, as understood by one of ordinary skill in the art. When E, R^{vi} and R^{vii} are substituted, the substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfinyl” is represented by the formula

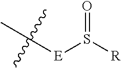

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a silyl, a thiol, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonyl” is represented by the formula

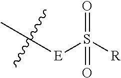

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonic acid” refers to a sulfonyl, as defined above, wherein R is hydroxyl, and E is absent, or E is substituted or unsubstituted cycloalkyl, substituted or unsubstituted heterocyclyl, substituted or unsubstituted alkylaryl, substituted or unsubstituted arylalkyl, substituted or unsubstituted aryl, a substituted or unsubstituted polyaryl, a substituted or unsubstituted polyheteroaryl, or substituted or unsubstituted heteroaryl. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfate” refers to a sulfonyl, as defined above, wherein E is absent, oxygen, alkoxy, aroxy, substituted alkoxy or substituted aroxy, as defined above, and R is independently hydroxyl, alkoxy, aroxy, substituted alkoxy or substituted aroxy, as defined above. When E is oxygen, the sulfate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonate” refers to a sulfonyl, as defined above, wherein E is oxygen, alkoxy, aroxy, substituted alkoxy or substituted aroxy, as defined above, and R is independently hydrogen, substituted or unsubstituted alkyl, substituted or unsubstituted alkenyl, substituted or unsubstituted alkynyl, substituted or unsubstituted amino, substituted or unsubstituted cycloalkyl, substituted or unsubstituted heterocyclyl, substituted or unsubstituted aralkyl, substituted or unsubstituted alkylaryl, substituted or unsubstituted arylalkyl, substituted or unsubstituted aryl, substituted or unsubstituted heteroaryl, a substituted or unsubstituted polyaryl, a substituted or unsubstituted polyheteroaryl, —(CH₂)ₘ—R′″, R′″ represents a hydroxy group, substituted or unsubstituted carbonyl group, an aryl, a cycloalkyl ring, a cycloalkenyl ring, a heterocycle, an amido, an amino, or a polycycle; and m is zero or an integer ranging from 1 to 8. When E is oxygen, sulfonate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfamoyl” refers to a sulfonamide or sulfonamide represented by the formula

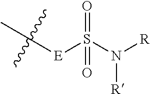

wherein E is absent, or E is substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted cycloalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “silyl group” as used herein is represented by the formula —SiRR′R,″ where R, R′, and R″ can be, independently, a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, a phosphonyl, a sulfinyl, a thiol, an amido, an amino, an alkoxy, or an oxo, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The terms “thiol” are used interchangeably and are represented by —SR, where R can be a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, an amido, an amino, an alkoxy, an oxo, a phosphonyl, a sulfinyl, or a silyl, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted, independently, with the substituents described above in the definition of “substituted.”

The numerical ranges disclose individually each possible number that such a range could reasonably encompass, as well as any sub-ranges and combinations of sub-ranges encompassed therein. For example, in a given range carbon range of C₃-C₉, the range also discloses C₃, C₄, C₅, C₆, C₇, C₈, and C₉, as well as any subrange between these numbers (for example, C₄-C₆), and any possible combination of ranges possible between these values. In yet another example, a given temperature range may be from about 25° C. to 30° C., where the range also discloses temperatures that can be selected independently from about 25, 26, 27, 28, 29, and 30° C., as well as any range between these numbers (for example, 26 to 28° C.), and any possible combination of ranges between these values.

Use of the term “about” is intended to describe values either above or below the stated value, which the term “about” modifies, to be within a range of approximately +/−10%. When the term “about” is used before a range of numbers (i.e., about 1-5) or before a series of numbers (i.e., about 1, 2, 3, 4, etc.) it is intended to modify both ends of the range of numbers and/or each of the numbers recited in the entire series, unless specified otherwise.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted with, independently, with the substituents described above in the definition of “substituted.”

### II. Compositions

Described are a class of dinuclear cyclometalated platinum(II) carbene emitters complexes with a tridentate CCN ligand. The disclosed compounds can be produced via a single step of metalation, and preferably possess low CIE-y values down to about 0.07. Without wishing to be bound by theory, it is believed that the increased denticity, with respect to monodentate and bidentate ligands, increases device stability by preventing emitter degradation.

The disclosed compounds have a structure:

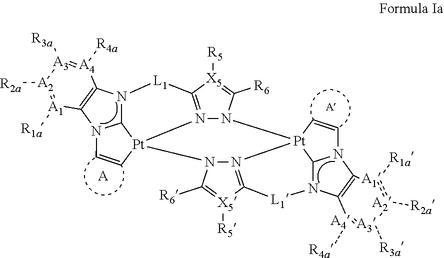

wherein:
the compound has an overall neutral, negative, or positive charge,
the dashed linear lines denote the presence or absence of a bond,
A and A′ are independently a substituted cycloalkyl, an unsubstituted cycloalkyl, a substituted cycloalkenyl, an unsubstituted cycloalkenyl, a substituted cycloalkynyl, an unsubstituted cycloalkynyl, a substituted C₁-C₂₀ heterocyclyl, an unsubstituted C₁-C₂₀heterocyclyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, or fused combinations thereof; preferably A and A′ are independently a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀heterocyclyl, or fused combinations thereof;
X₅, and X₅, are independently carbon or nitrogen, and are independently bonded to one or no hydrogen atom according to valency, preferably, X₅ and X₅, are carbon,
R₅, R₆, R_{5′}, and R₆, are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or R₅ and R₆ together, R₅, and R₆, together, with the atom to which they are attached, form a substituted aryl, an unsubstituted aryl, a substituted heteroaryl, an unsubstituted heteroaryl, a substituted C₁-C₂₀ heterocyclyl, an unsubstituted C₁-C₂₀ heterocyclyl, fused combinations thereof, preferably R₅, R₆, R_{5′}, and R₆, are independently absent, hydrogen, substituted alkyl, unsubstituted alkyl, substituted aryl, unsubstituted aryl,
A₁, A₂, A₃, A₄, A_{1′}, A₂, A_{3′}, and A₄, are independently absent, hydrogen, deuterium, carbon, nitrogen, unsubstituted aryl, or substituted aryl, and, when present, are independently bonded to one, two, three, four, five, or no hydrogen atom according to valency,
R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀cycloalkyl, substituted C₁-C₂₀heterocyclyl, unsubstituted C₁-C₂₀ heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, a fused combination thereof (such as dibenzofuran-4-yl, dibenzofuran-3-yl, dibenzothiopen-4-yl, dibenzothiopen-3-yl, etc.), or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, fused combinations thereof, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀ heterocyclyl, an unsubstituted C₁-C₂₀heterocyclyl, fused combinations thereof, and
L₁ and L_{1′} are independently substituted alkyl, unsubstituted alkyl, substituted alkenyl, unsubstituted alkenyl, substituted alkynyl, unsubstituted alkynyl, unsubstituted alkoxy, substituted alkoxy, unsubstituted aroxy, substituted aroxy, unsubstituted alkylthio, substituted alkylthio, unsubstituted carbonyl, substituted carbonyl, unsubstituted carboxyl, substituted carboxyl, unsubstituted ester, substituted ester, unsubstituted ether, substituted ether, unsubstituted polyether, substituted polyether, substituted amino, unsubstituted amino, substituted amide, unsubstituted amide, substituted aryl, unsubstituted aryl, substituted heteroaryl, unsubstituted heteroaryl, substituted polyaryl, unsubstituted polyaryl, substituted polyheteroaryl, unsubstituted polyheteroaryl, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or fused combinations thereof. In some forms, L₁ and L_{1′} are independently substituted alkyl or unsubstituted alkyl. In some forms, L₁ and L_{1′} are independently substituted C₁-C₁₀ alkyl or unsubstituted C₁-C₁₀ alkyl. In some forms, L₁ and L_{1′} are independently substituted C₂-C₁₀ alkyl or unsubstituted C₂-C₁₀ alkyl. In some forms of L₁ and L_{1′} the substituted alkyl, substituted C₁-C₁₀ alkyl, or substituted C₂-C₁₀ alkyl contains one or more alkyl substituents (such as methyl, ethyl, propyl, iso-propyl, n-butyl, sec-butyl, tert-butyl), one or more ether bonds, one or more amine groups (such as substituted amine or unsubstituted amine), one or more substituted aryl groups, one or more substituted heteroaryl groups, one or more substituted C₃-C₂₀ cycloalkyl groups, one or more substituted C₁-C₂₀ heterocyclyl groups, or a combination thereof. In some forms, the compound is fluorine-free, i.e., not covalently bonded to a fluorine atom. It is to be understood that L₁ and L₁, are at least divalent. Without wishing to be bound by theory, fluorine-containing emitter complexes have poorer thermal and electrochemical stability. For example, cleavage of fluorine happens during the sublimation process. This means that the stability of fluorine-containing emitter in electroluminescent devices can be decreased and hence device lifetime can be shortened.

In some forms, the compound is as described above for Formula Ia, except that the compound has a structure:

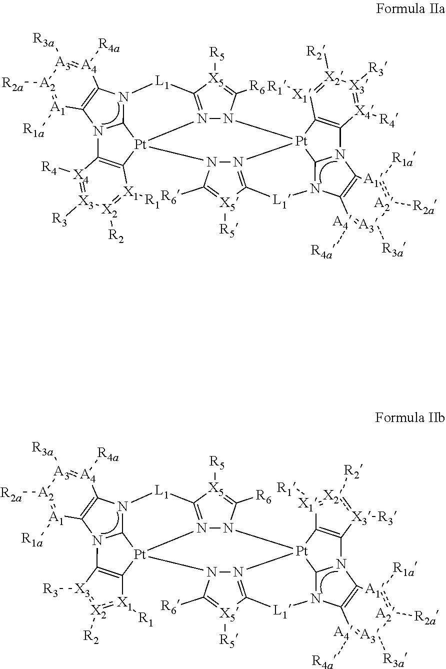

wherein:
the dashed linear lines denote the presence or absence of a bond,
(i) A₁, A₂, A₃, A₄, A_{1′}, A_{2′}, A_{3′}, and A_{4′}, (ii) R₁ₐ, R₂ₐ, R₃ₐ, R₄ₐ, R_{1a′}, R_{2a′}, R_{3a′}, and R_{4a′}, (iii) L₁ and L_{1′}, and (iv) X₅, X_{5′}, R₅, R₆, R_{5′}, and R_{6′} are as described above for Formula Ia,
X₁, X₂, X₃, X₄, X_{1′}, X_{2′}, X_{3′}, and X_{4′} when present, are independently carbon, nitrogen, oxygen, or sulfur, and are independently bonded to one or no hydrogen atom according to valency,
R₁, R₂, R₃, R₄, R_{1′}, R_{2′}, R_{3′}, and R₄, are independently absent, deuterium, hydrogen, substituted alkyl (such as trifluoromethyl), unsubstituted alkyl, substituted alkenyl, unsubstituted alkenyl, substituted alkynyl, unsubstituted alkynyl, substituted aryl (such as mesityl (2,4,6-trimethylphenyl), 3,5-di-tert-butylphenyl, 2,6-dimethylphenyl), unsubstituted aryl, halogen (such as fluorine), hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, or R₁ and R₂ together, R₂ and R₃ together, R₃ and R₄ together, R_{1′} and R_{2′} together, R_{2′} and R₃ together, R_{3′} and R_{4′} together, or a combination thereof, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, or fused combinations thereof. In some forms, R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R₁, and R_{2′} together, R_{2′} and R_{3′} together, R_{3′} and R₄, together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

In some forms, the compound is as described above for Formula Ia, IIa, or IIb, except that the compound has a structure:

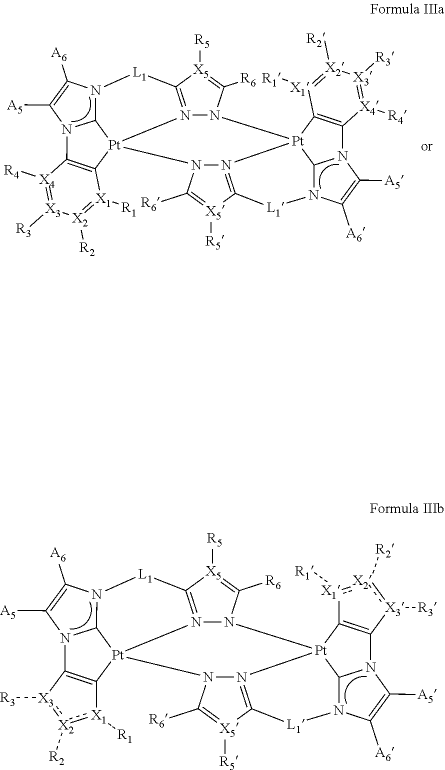

wherein:
the dashed linear lines denote the presence or absence of a bond,
A₅, A₆, A_{5′}, and A₆, are independently hydrogen, deuterium, unsubstituted alkyl, substituted alkyl, substituted aryl, unsubstituted aryl, unsubstituted heteroaryl, substituted heteroaryl, unsubstituted polyheteroaryl, substituted polyheteroaryl, substituted C₁-C₂₀heterocyclyl, or unsubstituted C₁-C₂₀heterocyclyl; or preferably hydrogen, unsubstituted alkyl, substituted alkyl, deuterium, substituted aryl, or unsubstituted aryl. In some forms, A₅, A₆, A_{5′}, and A₆, are hydrogen or deuterium. In some forms, A₅, A₆, A_{5′}, and A₆, are unsubstituted alkyl (such as unsubstituted C₁-C₁₀ alkyl, unsubstituted C₁-C₅ alkyl, or unsubstituted C₁-C₃ alkyl) or substituted alkyl (such as substituted C₁-C₁₀ alkyl, substituted C₁-C₅ alkyl, or substituted C₁-C₃ alkyl). In some forms, A₅, A₆, A_{5′}, and A₆, are hydrogen, substituted aryl, or unsubstituted aryl, with the proviso at least one of A₅ and A₆, or As, and A₆, is substituted aryl or unsubstituted aryl.

In some forms, the compound is as described above for Formula IIa or IIIa, except that X₁, X₂, X₃, X₄, X_{1′}, X_{2′}, X_{3′}, and X₄, are carbon, and are independently bonded to one or no hydrogen atom according to valency.

In some forms, the compound is as described above for Formula IIa or IIIa, except that one or more of X₁, X₂, X₃, X₄, and one or more of X_{1′}, X_{2′}, X_{3′}, and X₄, are nitrogen, and X₁, X₂, X₃, X₄, X_{1′}, X_{2′}, X_{3′}, and X₄, are independently bonded to one or no hydrogen atom according to valency. In some forms, the compound is as described above for Formula IIa or IIIa, except that X₂ and X_{2′} are nitrogen, X₁, X₃, X₄, X_{1′}, X_{3′}, and X₄, are carbon, and X₁, X₂, X₃, X₄, X_{1′}, X_{2′}, X_{3′}, and X_{4′} are independently bonded to one or no hydrogen atom according to valency.

In some forms, the compound is as described above for Formula IIa or IIIa, except that R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

In some forms, the compound is as described above for Formula IIa or IIIa, except that R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, or halogen (such as fluorine).

In some forms, the compound is as described above for Formula IIa or IIIa, except that R₁ and R₂ together, R₂ and R₃ together, R₃ and R₄ together, R₁, and R_{2′} together, R_{2′} and R₃ together, R₃ and R_{4′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof. In some forms, R₁ and R₂ together, R₂ and R₃ together, R₃ and R₄ together, R₁, and R_{2′} together, R_{2′} and R₃ together, R_{3′} and R_{4′} together, or a combination thereof, with the atom to which they are attached, form:

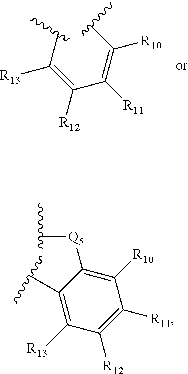

wherein Q₅ can be NR₁₄, carbon, or sulfur, or oxygen; and R₁₀-R₁₄ can be independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₁-C₂₀ heterocyclyl, or unsubstituted C₁-C₂₀ heterocyclyl. In some forms, Q₅ can be NR₁₄, carbon, or sulfur, or oxygen, such as oxygen; and R₁₀-R₁₄ can be independently absent, hydrogen, substituted alkyl, or unsubstituted alkyl. In some forms, Q₅ can be oxygen; and R₁₀-R₁₄ can be hydrogen.

In some forms, the compound is as described above for Formula IIb or IIIb, except that one or more of X₁, X₂, and X₃, and one or more of X_{1′}, X_{2′} and X₃, are sulfur, oxygen, or nitrogen, and X₁, X₂, X₃, X_{1′}, X_{2′}, and X₃, are independently bonded to one or no hydrogen atom according to valency. In some forms, the compound is as described above for Formula IIb or IIIb, except that one or more of X₁, X₂, and X₃, and one or more of X_{1′}, X_{2′} and X₃, are sulfur and X₁, X₂, X₃, X_{1′}, X_{2′}, and X₃, are independently bonded to one or no hydrogen atom according to valency. In some forms, the compound is as described above for Formula IIb or IIIb, except that one of X₁, X₂, and X₃, and one of X_{1′}, X_{2′} and X₃, are sulfur and X₁, X₂, X₃, X_{1′}, X_{2′}, and X₃, are independently bonded to one or no hydrogen atom according to valency.

In some forms, the compound is as described above for Formula IIb or IIIb, except that one or more of X₁, X₂, and X₃, and one or more of X_{1′}, X_{2′} and X_{3′}, are oxygen, and X₁, X₂, X₃, X_{1′}, X_{2′}, and X_{3′} are independently bonded to one or no hydrogen atom according to valency. In some forms, the compound is as described above for Formula IIb or IIIb, except that one of X₁, X₂, and X₃, and one of X_{1′}, X_{2′} and X_{3′}, are oxygen, and X₁, X₂, X₃, X_{1′}, X_{2′}, and X_{3′} are independently bonded to one or no hydrogen atom according to valency.

In some forms, the compound is as described above for Formula IIb or IIIb, except that R₁, R₂, R₃, R_{1′}, R_{2′}, and R_{3′} are independently absent, hydrogen, substituted alkyl, unsubstituted alkyl, substituted aryl, unsubstituted aryl, halogen, or R₁ and R₂ together, R₂ and R₃ together, R₁, and R_{2′} together, R_{2′} and R_{3′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

In some forms, the compound is as described above for Formula IIb or IIIb, except that R₁, R₂, R₃, R_{1′}, R_{2′}, and R_{3′} are hydrogen, substituted alkyl, unsubstituted alkyl, substituted aryl, unsubstituted aryl, halogen. In some forms, the compound is as described above for Formula IIb or IIIb, except that R₁, R₂, R₃, R_{1′}, R_{2′}, and R_{3′} are absent, hydrogen, or a combination thereof.

In some forms, the compound is as described above for Formula IIb or IIIb, except that R₁ and R₂ together, R₂ and R₃ together, R₁, and R_{2′} together, R_{2′} and R_{3′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof. In some forms, the compound is as described above for Formula IIb or IIIb, except that R₁ and R₂ together, R₂ and R₃ together, R₁, and R_{2′} together, R_{2′} and R_{3′} together, or a combination thereof, with the atom to which they are attached, form:

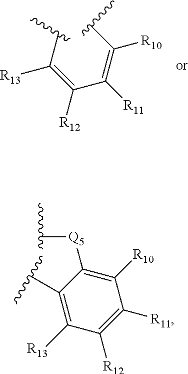

wherein Q₅ can be NR₁₄, carbon, or sulfur, or oxygen; and R₁₀-R₁₄ can be independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₁-C₂₀ heterocyclyl, or unsubstituted C₁-C₂₀ heterocyclyl. In some forms, Q₅ can be NR₁₄, carbon, or sulfur, or oxygen, such as sulfur, and R₁₀-R₁₄ can be independently absent, hydrogen, substituted alkyl, or unsubstituted alkyl. In some forms, Q₅ can be sulfur; and R₁₀-R₁₄ can be hydrogen.

In some forms, the compound is as described above for Formula Ia, IIa, or IIb, except that the compound has a structure:

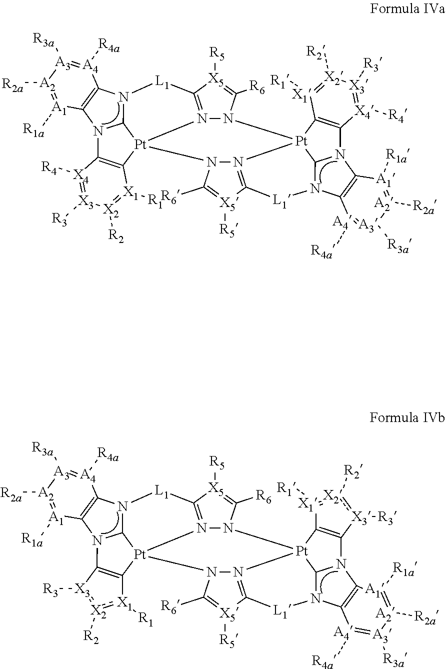

wherein:
the dashed linear lines denote the presence or absence of a bond, (i) R₁ₐ, R₂ₐ, R₃ₐ, R₄ₐ, R_{1a′}, R_{2a′}, R_{3a′}, and R_{4a′}, (ii) L₁ and L_{1′}, and (iii) X₅, X_{5′}, R₅, R₆, R_{5′}, and R_{6′} are as described above for Formula Ia,
A₁, A₂, A₃, A₄, A_{1′}, A_{2′}, A_{3′}, and A₄, are independently carbon, nitrogen, oxygen, or sulfur, and are independently bonded to one or no hydrogen atom according to valency,
X₁, X₂, X₃, X₄, X_{1′}, X_{2′}, X_{3′}, and X_{4′} when present, are independently carbon, nitrogen, oxygen, or sulfur, and are independently bonded to one or no hydrogen atom according to valency, and
R₁, R₂, R₃, R₄, R_{1′}, R_{2′}, R_{3′}, and R₄, are independently absent, hydrogen, deuterium, substituted alkyl, unsubstituted alkyl, substituted alkenyl, unsubstituted alkenyl, substituted alkynyl, unsubstituted alkynyl, substituted aryl (such as mesityl (2,4,6-trimethylphenyl), 3,5-di-tert-butylphenyl, 2,6-dimethylphenyl), unsubstituted aryl, halogen (such as fluorine), hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀ heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, or R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀ heterocyclyl, an unsubstituted C₁-C₂₀heterocyclyl, or fused combinations thereof. In some forms, R₁, R₂, R₃, R₄, R_{1′}, R_{2′}, R_{3′}, and R₄, are independently absent, hydrogen, deuterium, substituted alkyl, unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀ heterocyclyl, an unsubstituted C₁-C₂₀ heterocyclyl, or fused combinations thereof. In some forms, R₁, R₂, R₃, R₄, R_{1′}, R_{2′}, R_{3′}, and R₄, are independently absent, hydrogen, deuterium, substituted alkyl, unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine).

In some forms, the compounds are as described above for Formula Ia, IIa, or IVa, except that A₁, A₂, A₃, A₄, A_{1′}, A_{2′}, A_{3′}, and A₄, are carbon, and are independently bonded to one or no hydrogen atom according to valency, and X₁, X₂, X₃, X₄, X_{1′}, X_{2′}, X_{3′}, and X_{4′} are carbon, and are independently bonded to one or no hydrogen atom according to valency. In some forms, R₁, R₂, R₃, R₄, R_{1′}, R_{2′}, R_{3′}, and R₄, are independently absent, hydrogen, substituted alkyl, unsubstituted alkyl, substituted aryl, unsubstituted aryl, or halogen. In some forms, R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, or an unsubstituted aryl. In some forms, R₁ₐ and R₂ₐ together, R₃ₐ and R₄ₐ together, R_{1a′} and R_{2a′} together, R_{3a′} and R_{4a′} together, with the atom to which they are attached, form a substituted aryl, or an unsubstituted aryl.

In some forms, the compounds are as described above for Formula Ia, IIa, or IVa, except that one or more of A₁, A₂, A₃, and A₄ are oxygen, nitrogen, or sulfur, one or more of A_{1′}, A_{2′}, A_{3′}, and A₄, are oxygen, nitrogen, or sulfur, and A₁, A₂, A₃, A₄, A_{1′}, A_{2′}, A_{3′}, and A₄, are independently bonded to one or no hydrogen atom according to valency, and X₁, X₂, X₃, X₄, X_{1′}, X_{2′}, X_{3′}, and X₄, are carbon, and are independently bonded to one or no hydrogen atom according to valency. In some forms, R₁, R₂, R₃, R₄, R_{1′}, R_{2′}, R_{3′}, and R₄, are independently absent, hydrogen, deuterium, substituted alkyl, unsubstituted alkyl, substituted aryl (such as mesityl (2,4,6-trimethylphenyl), 3,5-di-tert-butylphenyl, 2,6-dimethylphenyl), unsubstituted aryl, or halogen (such as fluorine). In some forms, R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl (such as phenyl).

In some forms, the compounds are as described above for Formula Ia, IIa, or IVa, except that one or more of A₁, A₂, A₃, and A₄ are nitrogen, one or more of A_{1′}, A₂, A_{3′}, and A₄, are nitrogen, and A₁, A₂, A₃, A₄, A_{1′}, A_{2′}, A_{3′}, and A₄, are independently bonded to one or no hydrogen atom according to valency, and X₁, X₂, X₃, X₄, X_{1′}, X_{2′}, X_{3′}, and X₄, are carbon, and are independently bonded to one or no hydrogen atom according to valency. In some forms, the compounds are as described above for Formula Ia, IIa, or IVa, except that one of A₁, A₂, A₃, and A₄ is nitrogen and the others are carbon, one of A_{1′}, A_{2′}, A_{3′}, and A₄, is nitrogen and the others are carbon, and A₁, A₂, A₃, A₄, A_{1′}, A_{2′}, A_{3′}, and A₄, are independently bonded to one or no hydrogen atom according to valency, and X₁, X₂, X₃, X₄, X_{1′}, X_{2′}, X_{3′}, and X_{4′} are carbon, and are independently bonded to one or no hydrogen atom according to valency. In some forms, the compounds are as described above for Formula Ia, IIa, or IVa, except that two of A₁, A₂, A₃, and A₄ are nitrogen and the others are carbon, two of A_{1′}, A_{2′}, A_{3′}, and A₄, are nitrogen and the others are carbon, and A₁, A₂, A₃, A₄, A_{1′}, A_{2′}, A_{3′}, and A₄, are independently bonded to one or no hydrogen atom according to valency, and X₁, X₂, X₃, X₄, X_{1′}, X_{2′}, X_{3′}, and X₄, are carbon, and are independently bonded to one or no hydrogen atom according to valency.

In some forms, the compounds are as described above for Formula Ia, IIa, or IVa, except that one or more of A₁, A₂, A₃, and A₄ are oxygen, nitrogen, or sulfur, one or more of A_{1′}, A_{2′}, A_{3′}, and A₄, are nitrogen or sulfur, and A₁, A₂, A₃, A₄, A_{1′}, A_{2′}, A_{3′}, and A₄, are independently bonded to one or no hydrogen atom according to valency, and one or more of X₁, X₂, X₃, X₄, X_{1′}, X_{2′}, X_{3′}, and X_{4′} are oxygen, nitrogen, or sulfur, and X₁, X₂, X₃, X₄, X_{1′}, X_{2′}, X_{3′}, and X_{4′} are independently bonded to one or no hydrogen atom according to valency. In some forms, R₁, R₂, R₃, R₄, R_{1′}, R_{2′}, R_{3′}, and R₄, are independently absent, hydrogen, substituted alkyl, unsubstituted alkyl, substituted aryl, unsubstituted aryl, or halogen (such as fluorine). In some forms, R₁ₐ, R₂ₐ, R₃ₐ, R₄ₐ, R_{1a′}, R_{2a′}, R_{3a′}, and R_{4a′} are independently absent, hydrogen, substituted alkyl, unsubstituted alkyl, substituted aryl, or unsubstituted aryl.

In some forms, the compounds are as described above for Formula Ia, IIa, or IVa, except that one or more of A₁, A₂, A₃, and A₄ are nitrogen, one or more of A_{1′}, A₂, A_{3′}, and A₄, are nitrogen, and A₁, A₂, A₃, A₄, A_{1′}, A_{2′}, A_{3′}, and A₄, are independently bonded to one or no hydrogen atom according to valency, and one or more of X₁, X₂, X₃, X₄, X_{1′}, X_{2′}, X_{3′}, and X_{4′} are nitrogen, and X₁, X₂, X₃, X₄, X_{1′}, X_{2′}, X_{3′}, and X₄, are independently bonded to one or no hydrogen atom according to valency. In some forms, the compounds are as described above for Formula Ia, IIa, or IVa, except that one of A₁, A₂, A₃, and A₄ is nitrogen and the others are carbon, one of A_{1′}, A_{2′}, A_{3′}, and A₄, is nitrogen and the others are carbon, and A₁, A₂, A₃, A₄, A_{1′}, A_{2′}, A_{3′}, and A₄, are independently bonded to one or no hydrogen atom according to valency, and one of X₁, X₂, X₃, and X₄ is nitrogen and the others are carbon, one of X_{1′}, X_{2′}, X_{3′}, and X₄, is nitrogen and the others are carbon, and X₁, X₂, X₃, X₄, X_{1′}, X_{2′}, X_{3′}, and X_{4′} are independently bonded to one or no hydrogen atom according to valency.

In some forms, the compound has a structure selected from:

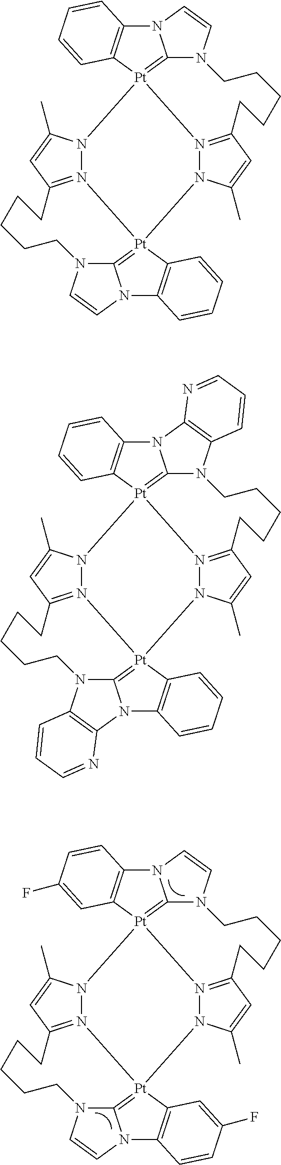

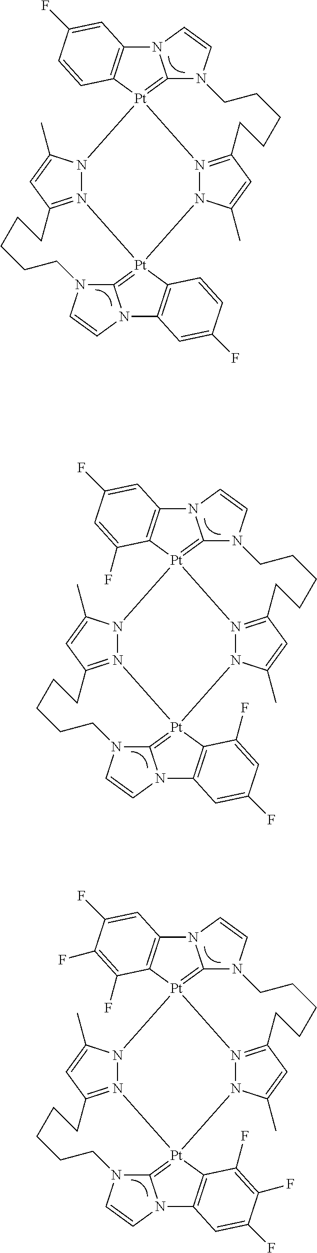

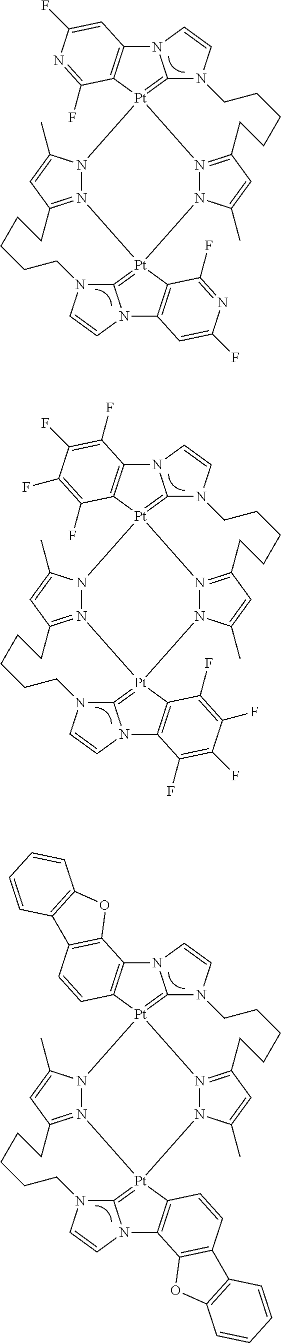

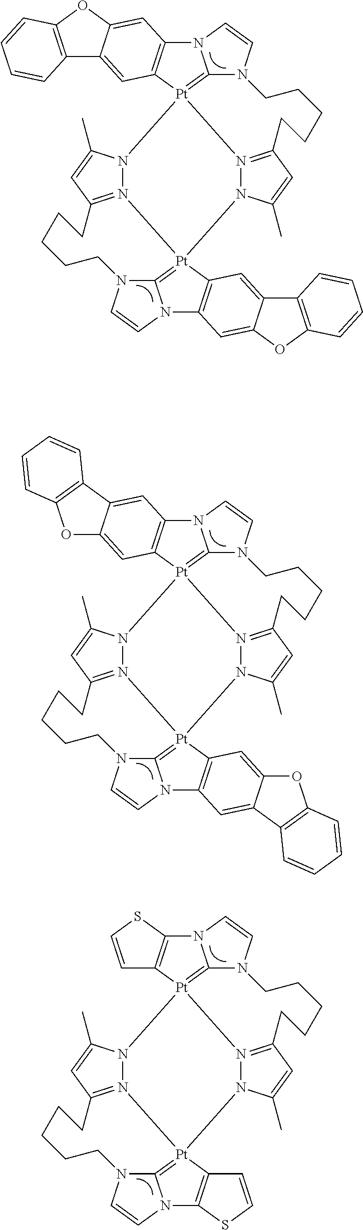

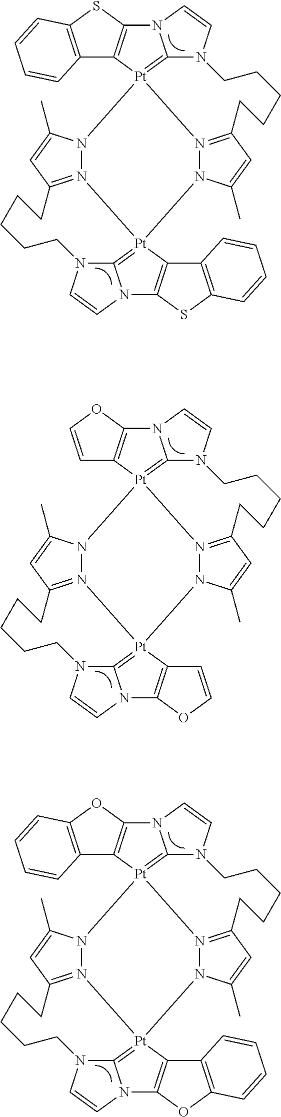

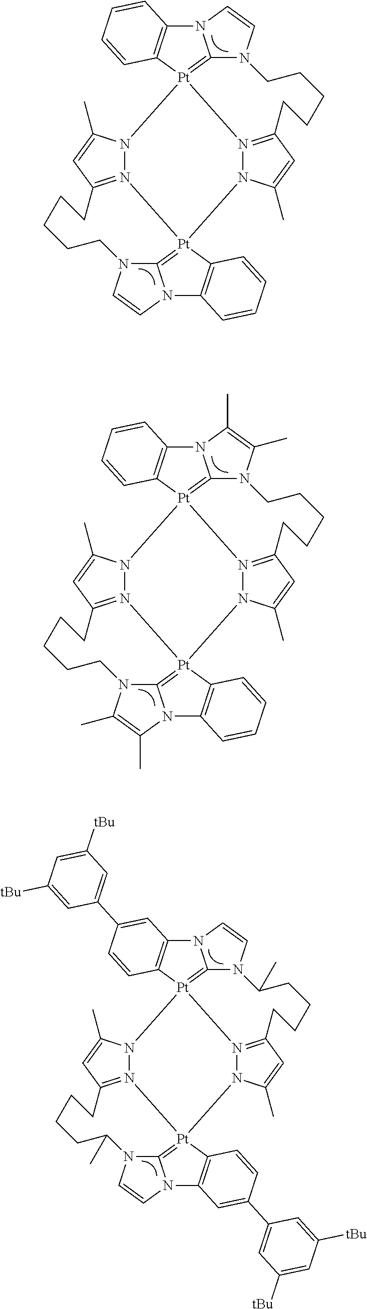

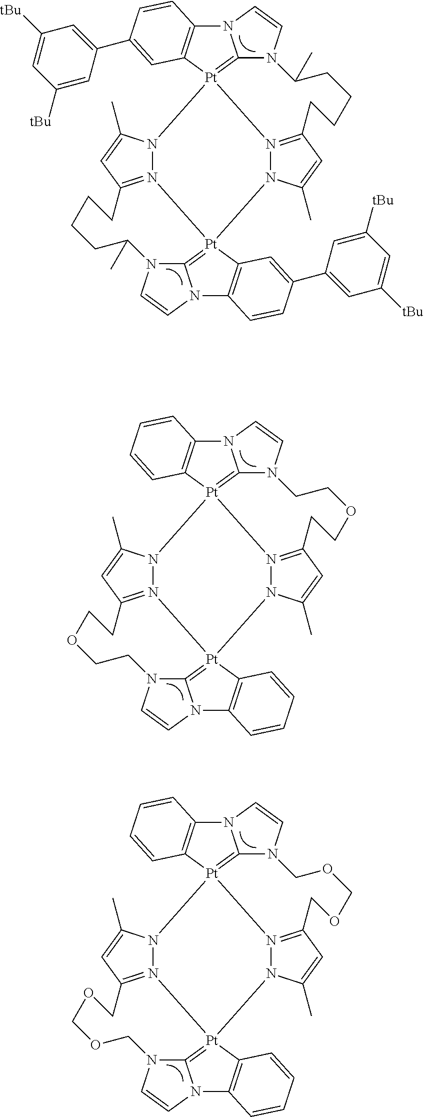

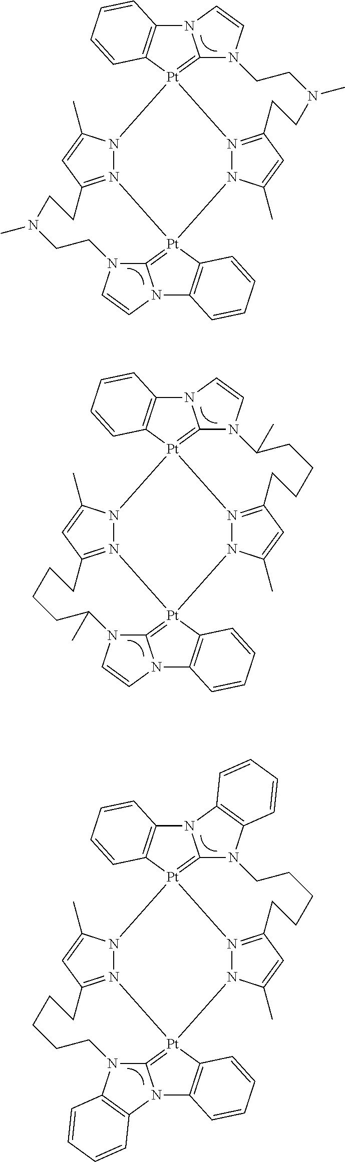

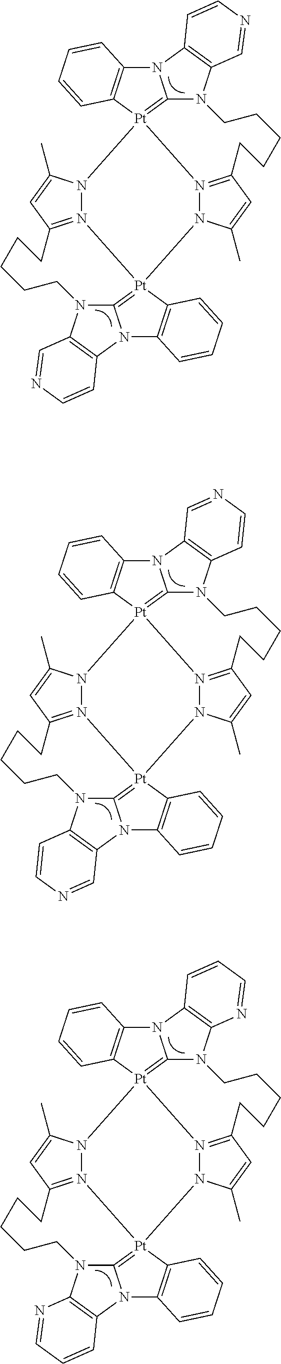

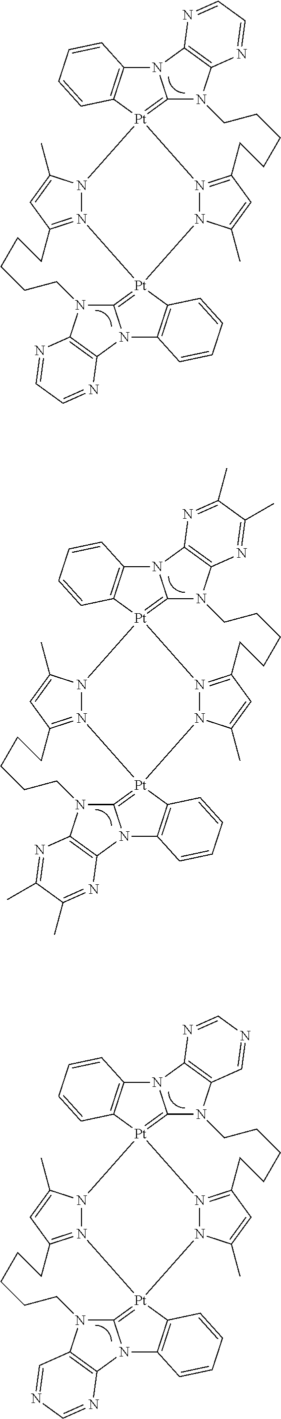

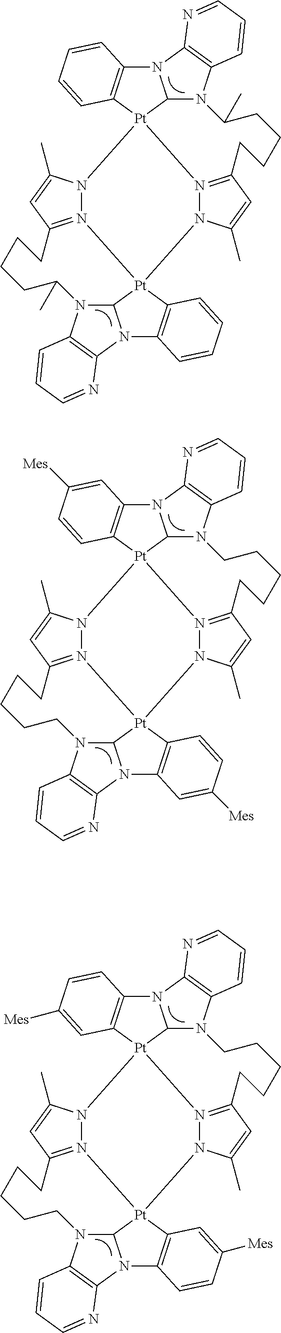

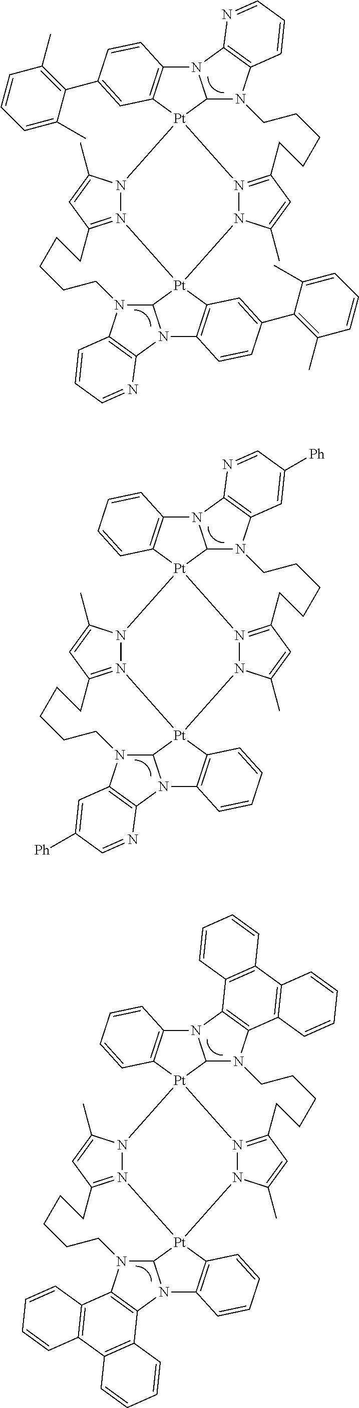

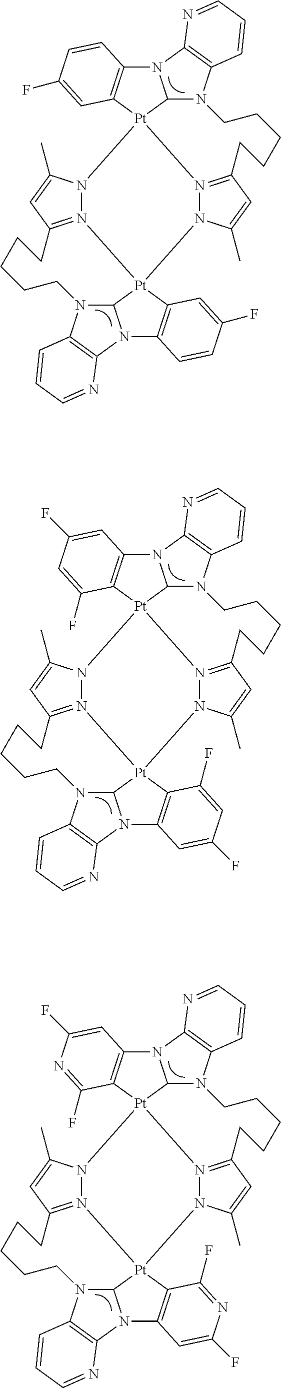

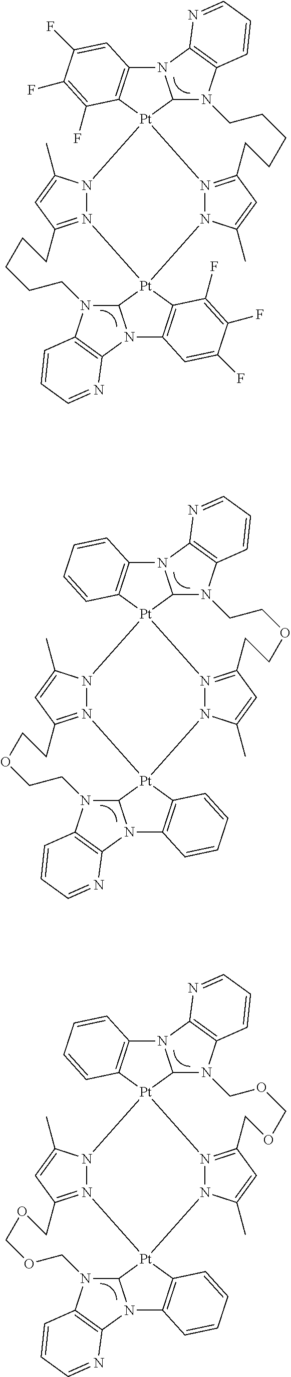

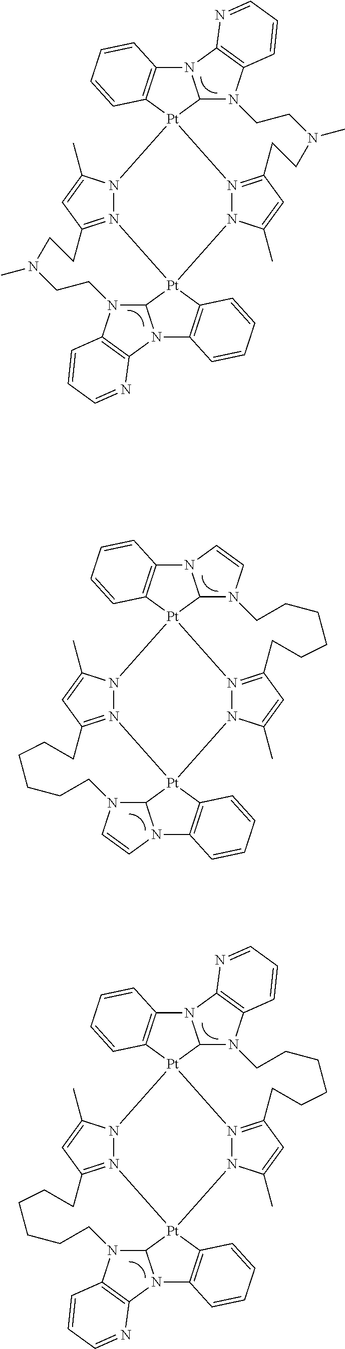

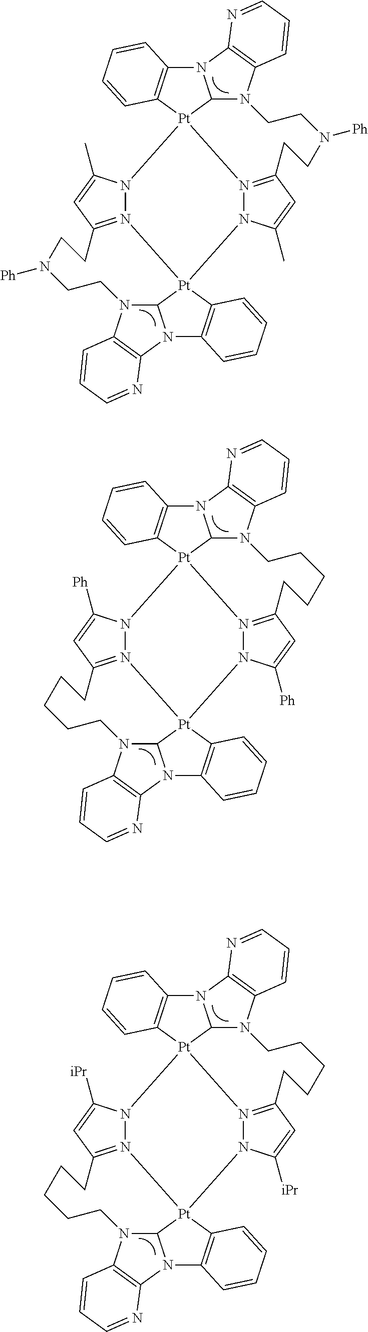

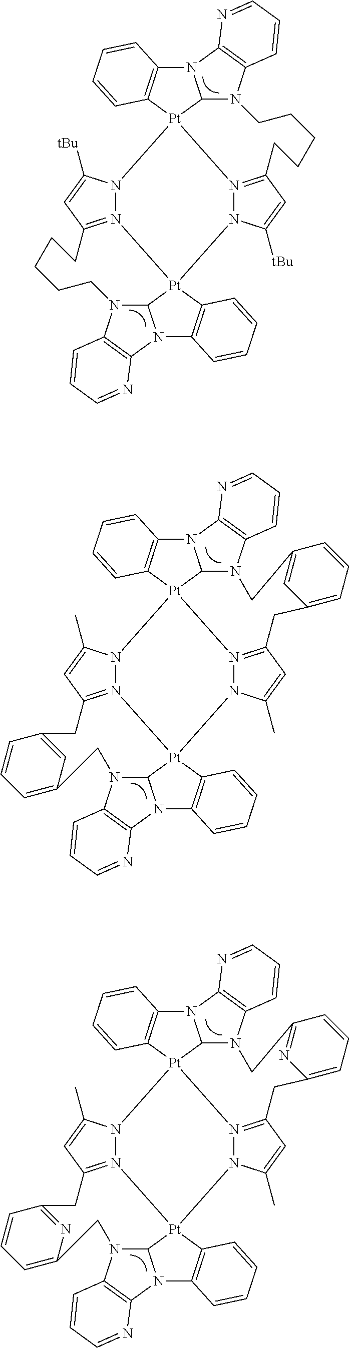

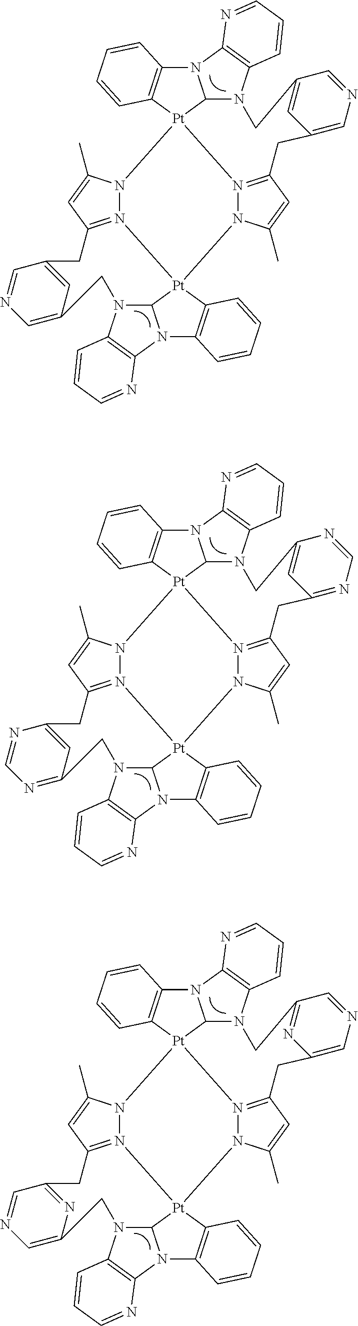

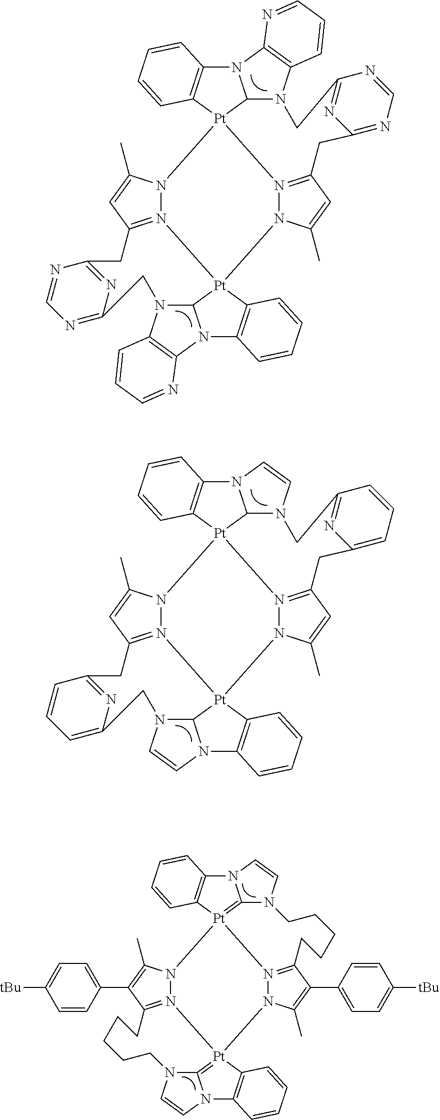

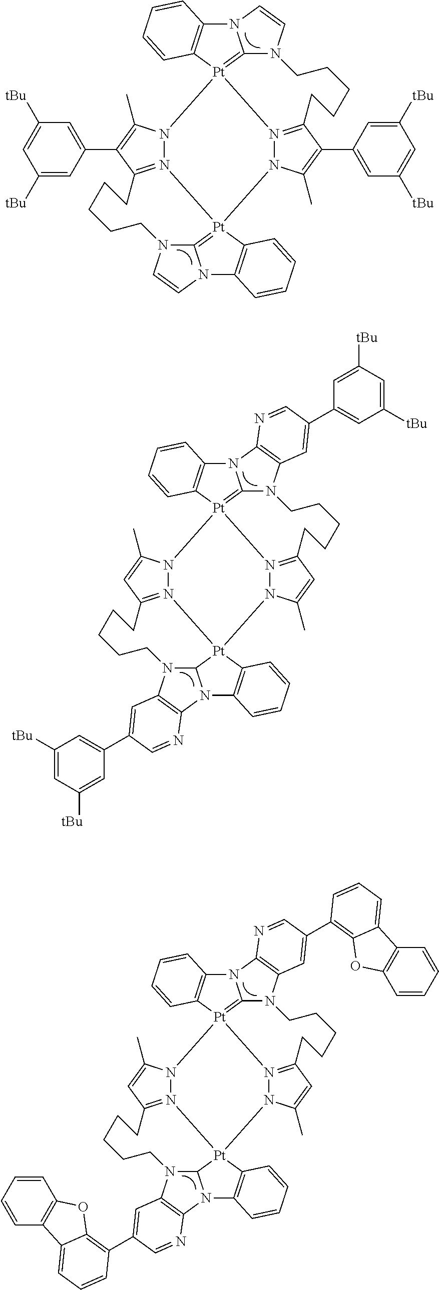

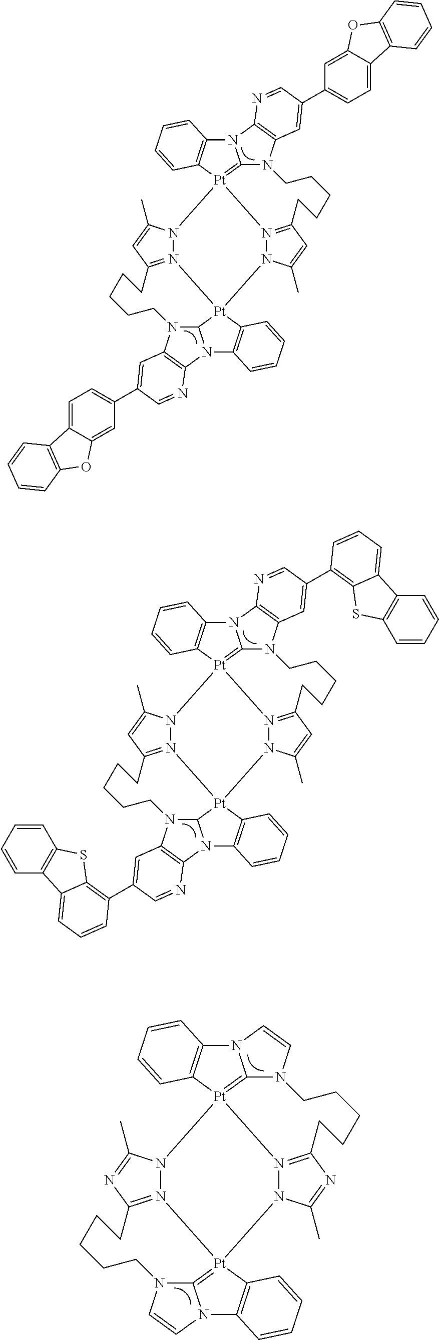

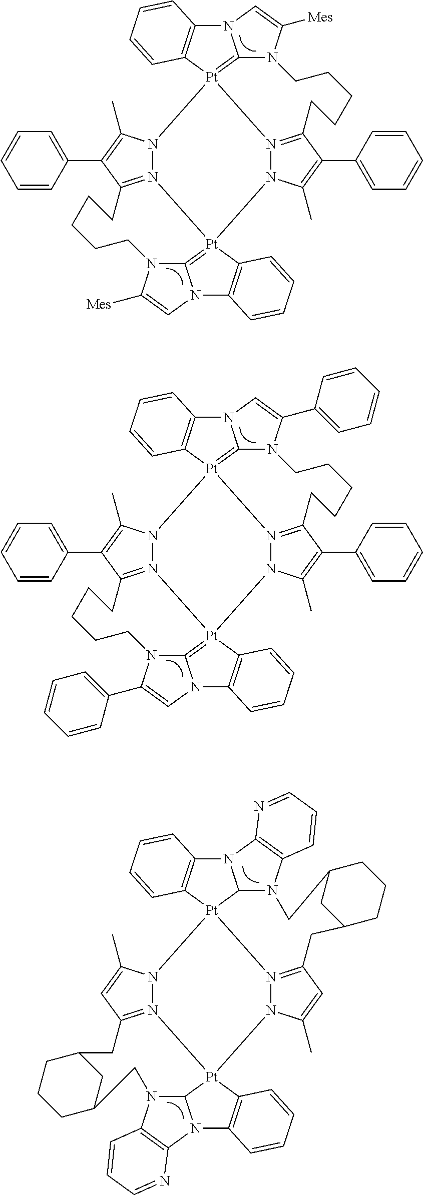

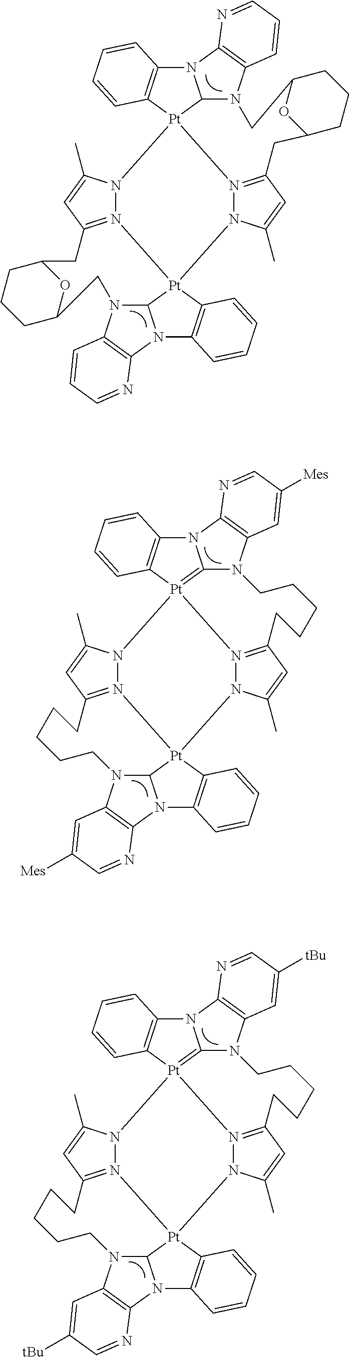

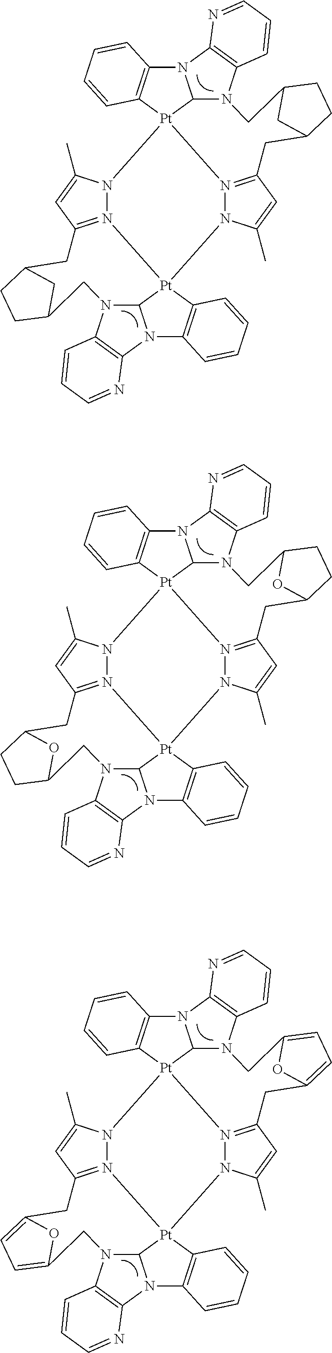

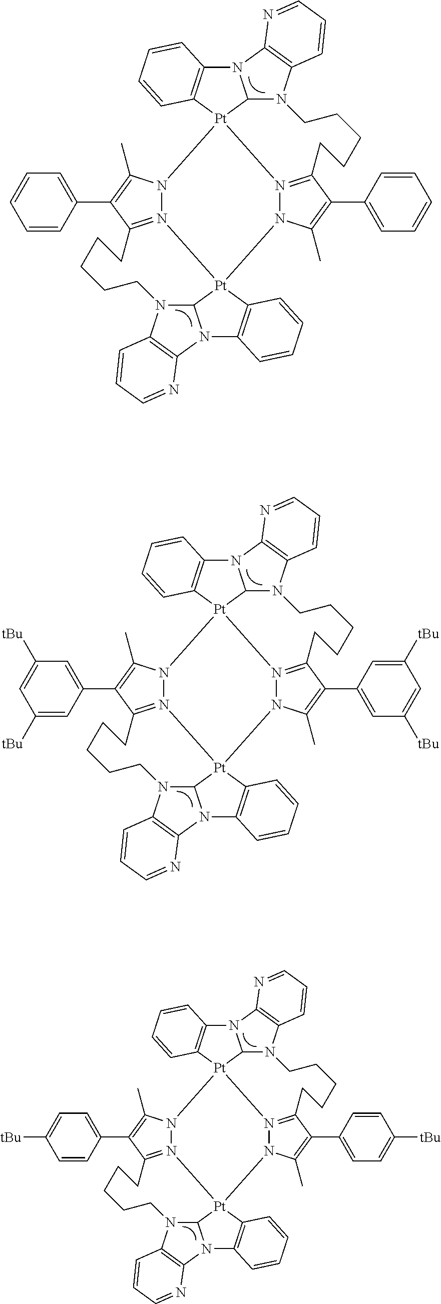

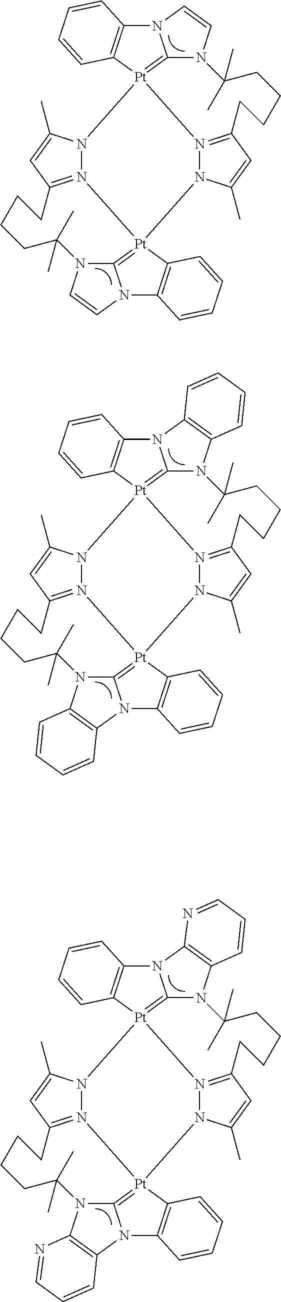

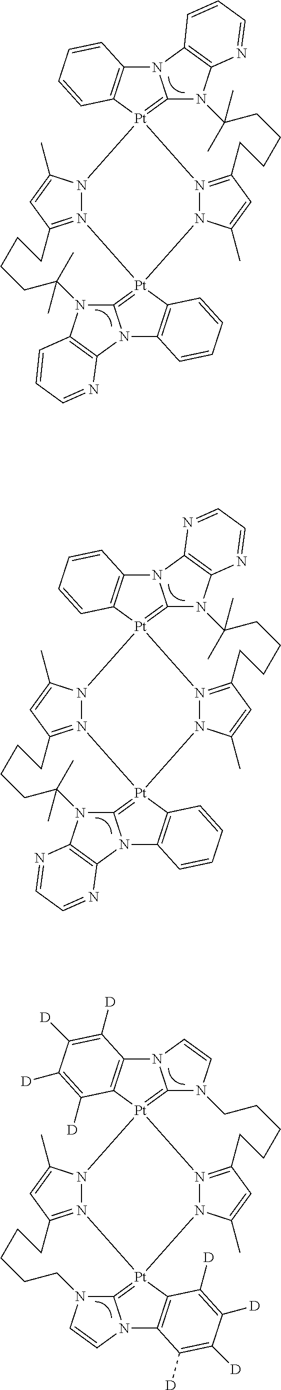

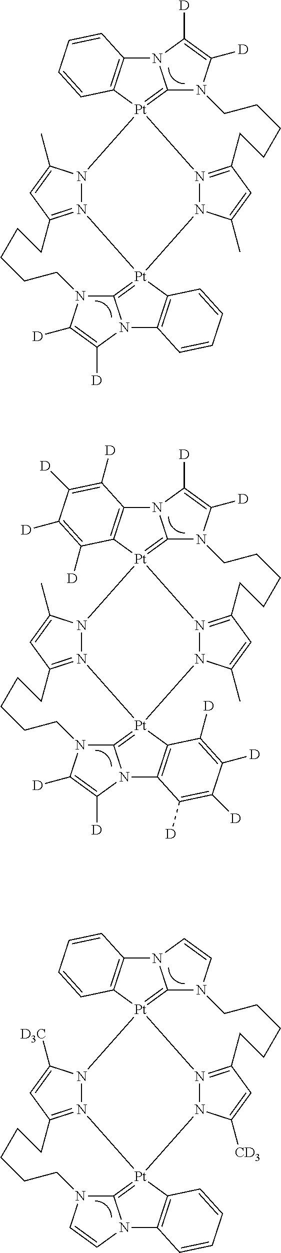

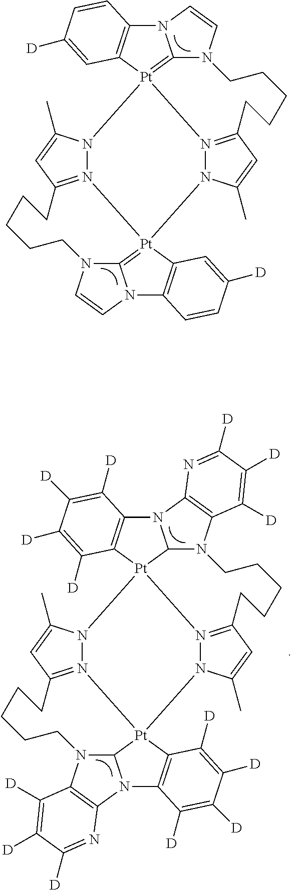

### III. Methods of Making and Reagents therefor

A. Dinuclear Platinum (II) Emitter Complexes

The dinuclear platinum(II) emitter complexes and the ligands described herein can be synthesized using methods known in the art of organic chemical synthesis. For instance, ligands can be purchased from commercial chemical manufacturers or may be prepared according to procedures reported and/or adapted from the literature. The selection of appropriate synthetic conditions, reagents, reaction workup conditions, purification techniques (as needed) are known to those in the field of synthesis. Exemplary and non-limiting syntheses of ligands and dinuclear platinum(II) emitter complexes are discussed in the Examples below.

B. Ligands

Synthetic methods for preparing ligands of the compounds described above are known or may be adapted from the literature. In some instances, pyrazole and triazole ligands described herein and used in the examples below can be readily obtained from commercial chemical manufacturers. Example syntheses of an NHC ligands and a bridging ligands are described in the Examples below.

C. Organic Light-Emitting Devices

Also described are methods of making organic light-emitting devices, such as OLEDs, containing one or more dinuclear platinum(II) emitter complexes described above. In some forms, preparation of the OLEDs can be via vacuum deposition or solution processing techniques such as spin-coating and ink printing (such as, ink-jet printing or roll-to-roll printing). An exemplary and nonlimiting method of making an OLED including containing one or more dinuclear platinum(II) emitter complexes described herein is disclosed in the Examples.

While non-specific tridentate ligands are generally known in the field, metal complexes formed from the tridentate ligands are typically and most generally mononuclear. It is not straight forward to obtain dinuclear metal complexes, particularly from methods used to form mononuclear complexes. Further, changing the denticity of a ligand from bidentate to tridentate, can induce structural distortions to the metal complexes, resulting in unknown photophysical properties. In addition, the synthetic methods for the tridentate ligands have to be developed.

### IV. Methods of Using

Preferably, the dinuclear platinum(II) emitter complexes described herein are photo-stable, thermally stable, and/or are emissive at room temperatures, low temperatures, or a combination thereof. Accordingly, the complexes can be incorporated into organic electronic components including, but not limited to, OLEDs or a light-emitting electrochemical cell (LEEC). Such OLEDs can be used in commercial applications such smart phones, televisions, monitors, digital cameras, tablet computers, lighting fixtures that usually operate at room temperatures, a fixed visual display unit, mobile visual display unit, illumination unit, keyboard, clothes, ornaments, garment accessary, wearable devices, medical monitoring devices, wall paper, tablet PC, laptop, advertisement panel, panel display unit, household appliances, and office appliances.

In some forms of the organic electronic component, the compounds are in a light-emitting layer. In some forms, the compounds are in a light-emitting layer that also contains a pure organic emitter. In these forms, the compounds can act as a sensitizer to transfer energy to the pure organic emitter. In these forms, the compounds can have a higher-lying singlet state than the pure organic emitter. The phrase “pure organic emitter” as used throughout this application refers to a light-emitting organic molecule formed exclusively from main group elements of the periodic table, such that the light-emitting organic molecule does not contain a covalent bond or a dative bond to a main group metal. Notably, the phrase is not intended to define or specify a level of purity of a composition containing the light-emitting organic molecule. In some forms, the organic electronic component contains an anode, a cathode, a hole transport region, and an electron transport region. In some forms, the hole transport region contains a hole injection layer and/or a hole transport layer, and optionally an electron blocking layer. In some forms, the electron transport region contains an electron transport layer and/or an electron injection layer, and optionally a hole blocking layer. In some forms, the light emitting layer is located in between the anode and the cathode. In some forms, the hole transport region is located between the anode and the light-emitting layer. In some forms, the electron transport region is located in between the cathode and the light-emitting layer.

Methods of preparing OLEDs containing one or more dinuclear platinum(II) emitter complexes, as described above, are well-known in the art of organic electronics. Such method of making OLEDs can involve vacuum deposition or solution processing techniques, such as spin-coating and ink-jet printing. The selection of suitable materials (anode, cathode, hole transport layer, electron transport layer, etc.) and fabrication parameters (such as deposition conditions or solvent selections) needed to fabricate OLEDs containing the dinuclear platinum(II) emitter complexes described herein are known in the art.

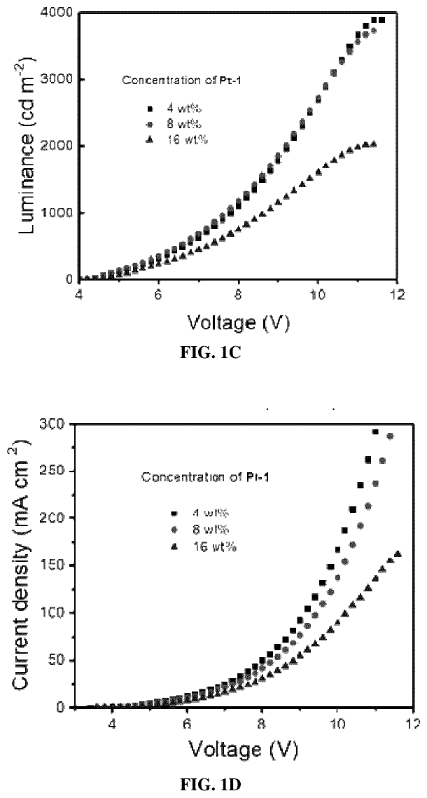

In one non-limiting example, organic light-emitting devices can have an ordered structure containing at least an anode, a hole-transporting layer, a light-emitting layer, an electron-transporting layer, and a cathode, wherein the light-emitting layer contains a dinuclear platinum(II) emitter complex, as described above. Referring to FIG. 2, an organic light-emitting device OLED 100 can include (i) a cathode 110 preferably including an aluminum layer 120 and a lithium layer 130; (ii) optionally, an electron transporting layer 140; (iii) optionally, a carrier confinement layer 150; (iv) a light-emitting layer 160 containing a dinuclear platinum(II) emitter complex described herein; (v) optionally, a hole-transporting layer 170; and (vi) an anode 180, such as indium tin oxide-coated glass. Flexible substrates other than glass, such as on plastic are also known in the art. The above is a non-limiting illustration of an OLED device which may be fabricated. It is understood that various other OLED architectures are possible.

The light-emitting layer can be formed by doping the dinuclear platinum(II) emitter complex, as a dopant, into a host compound and the luminescent compound has a percent composition between about 3 wt/wt % and about 20 wt/wt %, such as about 4 wt/wt % and about 16 wt/wt %, such as about 4 wt/wt %, about 8 wt/wt %, and about 16 wt/wt %, of the light-emitting layer. In some forms, the light-emitting layer has a thickness between about 5 nm and about 120 nm, between about 5 nm and about 60 nm, such as between about 10 nm and about 60 nm.

In some forms, the light-emitting layer contains a host compound selected from, but is not limited to, 1,3-bis(N-carbazolyl)benzene (mCP), 4,4′-bis(carbazol-9-yl)biphenyl (CBP), 4,4′,4″-tris(carbazol-9-yl)-triphenylamine (TCTA), 3-(4-biphenylyl)-4-phenyl-5-tert-butylphenyl-1,2,butylphenyl-1,2,4-triazole (TAZ), p-bis(triphenylsilyl)benzene (UGH2), 9-(4-tert-Butylphenyl)-3,6-bis(triphenylsilyl)-9H-carbazole (CzSi), Bis-4-(N-carbazolyl)phenyl)phenylphosphine oxide (BCPO), diphenyl-4-triphenylsilylphenyl-phosphine oxide (TSPO1), 2,8-bis(diphenylphosphoryl)dibenzo[b,d]furan (PPF), bis[2-(diphenylphosphino)phenyl]ether oxide (DPEPO), 3,3′-di(9H-carbazol-9-yl)-1,1′-biphenyl (mCBP), poly(methyl methacrylate) (PMMA), polystyrene (PS), and suitable combinations thereof. For example, two hosts, such as CzSi:TSPO1, BCPO:TSPO1, and BCPO:CzSi may be used in some forms at suitable relative ratios. Exemplary relative molar ratios of two respective hosts can range from between about 0.5:1 to 2:1.

In some forms, the hole-transporting layer contains an organic compound that can be, but is not limited to, 4,4′-bis[N-(1-naphthyl)-N-phenylamino]biphenyl (NPB), 4,4′-bis[N-(3-methylphenyl)-N-phenylamino]biphenyl (TPD), 4,4′,4″-tris[(3-methylphenyl)phenylamino]triphenylamine (MTDATA), and di-[4-(N,N-ditolyl-amino)phenyl]cyclohexane (TAPC). In addition, polymeric hole-transporting materials can be used including poly(N-vinylcarbazole) (PVK), polythiophene, polypyrrole, polyaniline, and copolymers including PEDOT:PSS. In some forms, the hole-transporting layer has a thickness between about 10 nm and 70 nm, such as 40 nm.

In some forms, the electron-transporting layer contains an organic compound that can be, but is not limited to, 1,3,5-tris(phenyl-2-benzimidazolyl)-benzene (TPBI), 1,3,5-tri[(3-pyridyl)-phen-3-yl] benzene (TmPyPB), bathocuproine (BCP), bathophenanthroline (BPhen) and bis(2-methyl-8-quinolinolate)-4-(phenylphenolate)-aluminum (BAlq), 1,3,5-tri[(3-pyridyl)-phen-3-yl]benzene (TmPyPB),1,3-bis[3,5-di(pyridin-3-yl)-phenyl]benzene (BmPyPhB) and 1,3,5-tris(6-(3-(pyridin-3-yl)phenyl)pyridin-2-yl)benzene (Tm3PyP26PyB). In some forms, the electron-transporting layer has a thickness between about 10 nm and 60 nm, such as 40 nm.

In some forms, the light-emitting device can contain a carrier confinement layer inserted between the hole-transporting layer and the light-emitting layer, or between the light-emitting layer and the electron-transporting layer. Preferably, the carrier confinement layer improves the performance of the light-emitting device. In some forms, the carrier confinement layer contains an organic compound that can be, but is not limited to, CBP, TCTA, 3TPYMB, BmPyPhB, and Tm3PyP26PyB. In some forms, the carrier confinement layer has a thickness between about 5 nm and about 50 nm, such as between about 10 nm and about 50 nm.

Preferably, the anode of the light-emitting device contains indium tin oxide-coated glass. Preferably, the cathode of the light-emitting device can contain lithium fluoride, aluminium, or a combination thereof. In some forms, the lithium fluoride forms a layer having a thickness between about 0.05 nm and 5 nm, such as 1 nm. In some forms, the aluminium forms a layer having a thickness between about 50 nm and about 250 nm, between about 50 nm and about 200 nm, such as 150 nm.

OLEDs containing the dinuclear platinum(II) emitter complexes can demonstrate maximum current efficiencies (CE) of up to 35 cd/A. In some forms, the CE can include, but is not limited to values of about 5 cd/A, 7.5 cd/A, 10 cd/A, 15 cd/A, 20 cd/A, 25 cd/A, 30 cd/A, or 35 cd/A. The CE values at luminances of 1000 cd/m² may be up to 30 cd/A. In some forms, the CE at luminances of 1000 cd/m² can include, but is not limited to values of about 2 cd/A, 2.5 cd/A, 5 cd/A, 10 cd/A, 15 cd/A, 20 cd/A, 25 cd/A, or 30 cd/A.

OLEDs containing the dinuclear platinum(II) emitter complexes can demonstrate maximum power efficiencies (PE) of up to 30 lumens per watt. In some forms, the PE can include, but is not limited to values of about 5 lm/W, 10 lm/W, 15 lm/W, 20 lm/W, 25 lm/W, or 30 lm/W. The PE values at luminances of 1000 cd/m² may be up to 25 lm/W. In some forms, the PE at luminances of 1000 cd/m² can include, but is not limited to values of about 5 lm/W, 5.5 lm/W, 6 lm/W, 6.5 lm/W, 10 lm/W, 15 lm/W, 20 lm/W, 25 lm/W.

OLEDs containing the dinuclear platinum(II) emitter complexes can demonstrate maximum external quantum efficiencies (EQE) of up to about 30%. In some forms, the EQE can include, but is not limited to values of about 10 to 30%. The EQE values at luminances of 1000 cd/m² may be up to 20% or 25%. In some forms, the PE at luminances of 1000 cd/m² can include, but is not limited to values of about 1% to about 20%, about 1% to about 15%, about 1% to about 10%, or about 1% to about 5%.

The disclosed compositions and methods can be further understood through the following numbered paragraphs.

1. A compound having a structure:

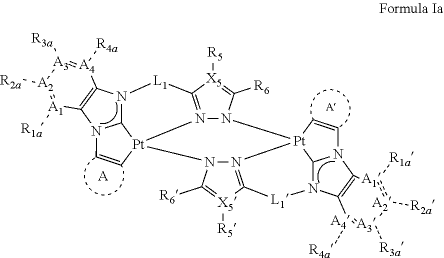

wherein:
the compound has an overall neutral, negative, or positive charge,
the dashed linear lines denote the presence or absence of a bond,
A and A′ are independently a substituted cycloalkyl, an unsubstituted cycloalkyl, a substituted cycloalkenyl, an unsubstituted cycloalkenyl, a substituted cycloalkynyl, an unsubstituted cycloalkynyl, a substituted C₁-C₂₀ heterocyclyl, an unsubstituted C₁-C₂₀heterocyclyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, or fused combinations thereof; preferably A and A′ are independently a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀heterocyclyl, or fused combinations thereof,
X₅, and X₅, are independently carbon or nitrogen, and are independently bonded to one or no hydrogen atom according to valency, preferably, X₅ and X₅, are carbon,
R₅, R₆, R_{5′}, and R₆, are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or R₅ and R₆ together, R₅, and R₆, together, with the atom to which they are attached, form a substituted aryl, an unsubstituted aryl, a substituted heteroaryl, an unsubstituted heteroaryl, a substituted C₁-C₂₀ heterocyclyl, an unsubstituted C₁-C₂₀ heterocyclyl, fused combinations thereof, or preferably R₅, R₆, R_{5′}, and R₆, are independently absent, hydrogen, substituted alkyl, unsubstituted alkyl, substituted aryl, unsubstituted aryl,
A₁, A₂, A₃, A₄, A_{1′}, A_{2′}, A_{3′}, and A₄, are independently absent, hydrogen, deuterium, carbon, nitrogen, unsubstituted aryl, or unsubstituted aryl, and, when present, are independently bonded to one, two, three, four, five, or no hydrogen atom according to valency, R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀heterocyclyl, unsubstituted C₁-C₂₀ heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, unsubstituted C₁-C₂₀heterocyclyl, a fused combination thereof (such as dibenzofuran-4-yl, dibenzofuran-3-yl, dibenzothiopen-4-yl, dibenzothiopen-3-yl, etc.), or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀ heterocyclyl, an unsubstituted C₁-C₂₀heterocyclyl, fused combinations thereof, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀heterocyclyl, fused combinations thereof, and
L₁ and L_{1′} are independently substituted alkyl, unsubstituted alkyl, substituted alkenyl, unsubstituted alkenyl, substituted alkynyl, unsubstituted alkynyl, unsubstituted alkoxy, substituted alkoxy, unsubstituted aroxy, substituted aroxy, unsubstituted alkylthio, substituted alkylthio, unsubstituted carbonyl, substituted carbonyl, unsubstituted carboxyl, substituted carboxyl, unsubstituted ester, substituted ester, unsubstituted ether, substituted ether, unsubstituted polyether, substituted polyether, substituted amino, unsubstituted amino, substituted amide, unsubstituted amide, substituted aryl, unsubstituted aryl, substituted heteroaryl, unsubstituted heteroaryl, substituted polyaryl, unsubstituted polyaryl, substituted polyheteroaryl, unsubstituted polyheteroaryl, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or fused combinations thereof.

2. The compound of paragraph 1, wherein L₁ and L_{1′} are independently substituted alkyl or unsubstituted alkyl.

3. The compound of paragraph 1 or 2, wherein L₁ and L_{1′} are independently substituted C₁-C₁₀ alkyl, unsubstituted C₁-C₁₀ alkyl, substituted C₂-C₁₀ alkyl or unsubstituted C₂-C₁₀ alkyl, preferably wherein the substituted alkyl, substituted C₁-C₁₀ alkyl, substituted C₂-C₁₀ alkyl contains one or more alkyl substituents (such as methyl, ethyl, propyl, iso-propyl, n-butyl, sec-butyl, tert-butyl), one or more ether bonds, one or more amine groups (such as substituted amine or unsubstituted amine), one or more substituted aryl groups, one or more substituted heteroaryl groups, one or more substituted C₃-C₂₀ cycloalkyl groups, one or more substituted C₁-C₂₀ heterocyclyl groups, or a combination thereof.

4. The compound of any one of paragraphs 1 to 3, wherein R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀heterocyclyl, fused combinations thereof.

5. The compound of any one of paragraphs 1 to 4, having a structure:

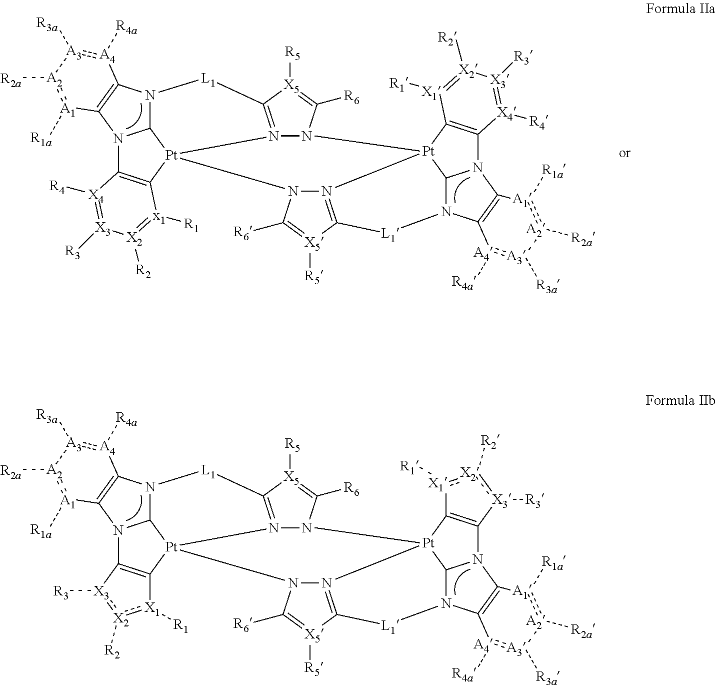

wherein:
the dashed linear lines denote the presence or absence of a bond,
X₁, X₂, X₃, X₄, X_{1′}, X_{2′}, X_{3′}, and X_{4′} when present, are independently carbon, nitrogen, oxygen, or sulfur, and are independently bonded to one or no hydrogen atom according to valency, R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted alkenyl, unsubstituted alkenyl, substituted alkynyl, unsubstituted alkynyl, substituted aryl (such as mesityl (2,4,6-trimethylphenyl), 3,5-di-tert-butylphenyl, 2,6-dimethylphenyl), unsubstituted aryl, halogen (such as fluorine), hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, or R₁ and R₂ together, R₂ and R₃ together, R₃ and R₄ together, R_{1′} and R_{2′} together, R_{2′} and R₃ together,
R_{3′} and R_{4′} together, or a combination thereof, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, or fused combinations thereof.

6. The compound of paragraph 5, wherein R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R₁, and R_{2′} together, R_{2′} and R₃ together, R₃ and R₄, together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

7. The compound of any one of paragraphs 1 to 6, having a structure:

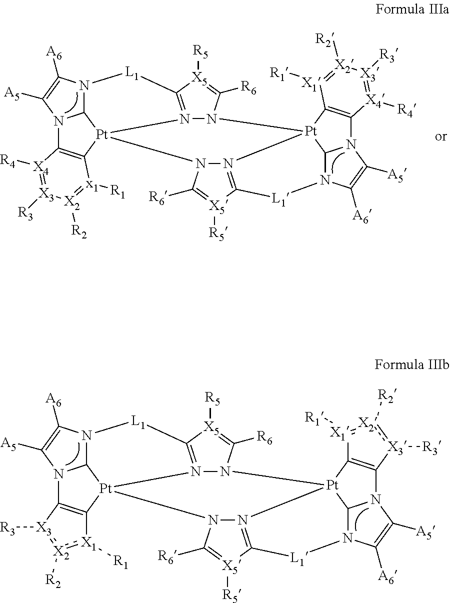

wherein:
the dashed linear lines denote the presence or absence of a bond,
A₅, A₆, A_{5′}, and A₆, are independently hydrogen, deuterium, unsubstituted alkyl, substituted alkyl, substituted aryl, unsubstituted aryl, unsubstituted heteroaryl, substituted heteroaryl, unsubstituted polyheteroaryl, substituted polyheteroaryl, substituted C₁-C₂₀heterocyclyl, or unsubstituted C₁-C₂₀heterocyclyl; or preferably hydrogen, unsubstituted alkyl, substituted alkyl, deuterium, substituted aryl, or unsubstituted aryl.

8. The compound of paragraph 7, wherein A₅, A₆, A_{5′}, and A₆, are hydrogen or deuterium.

9. The compound of paragraph 7, wherein A₅, A₆, A_{5′}, and A₆, are (i) unsubstituted alkyl (such as unsubstituted C₁-C₁₀ alkyl, unsubstituted C₁-C₅ alkyl, or unsubstituted C₁-C₃ alkyl) or substituted alkyl (such as substituted C₁-C₁₀ alkyl, substituted C₁-C₅ alkyl, or substituted C₁-C₃ alkyl), or (ii) hydrogen, substituted aryl, or unsubstituted aryl, with the proviso at least one of A₅ and A₆, or A₅, and A₆, is substituted aryl or unsubstituted aryl.

10. The compound of any one of paragraphs 5 to 9, wherein for Formula IIa or IIIa, X₁, X₂, X₃, X₄, X_{1′}, X_{2′}, X_{3′}, and X₄, are carbon, and are independently bonded to one or no hydrogen atom according to valency.

11. The compound of any one of paragraphs 5 to 9, wherein for Formula IIa or IIIa, one or more of X₁, X₂, X₃, and X₄, and one or more of X_{1′}, X_{2′}, X_{3′}, and X_{4′} are nitrogen, and X₁, X₂, X₃, X₄, X_{1′}, X_{2′}, X_{3′}, and X_{4′} are independently bonded to one or no hydrogen atom according to valency.

12. The compound of any one of paragraphs 5 to 9 or 11, wherein for Formula IIa or IIIa, X₂ and X_{2′} are nitrogen, X₁, X₃, X₄, X_{1′}, X_{3′}, and X_{4′} are carbon, and X₁, X₂, X₃, X₄, X_{1′}, X_{2′}, X_{3′}, and X₄, are independently bonded to one or no hydrogen atom according to valency.

13. The compound of any one of paragraphs 5 to 12, wherein for Formula IIa or IIIa, R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R₁, and R_{2′} together, R_{2′} and R₃ together, R₃ and R₄, together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

14. The compound of any one of paragraphs 5 to 12, wherein for Formula IIa or IIIa, R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, or halogen (such as fluorine).

15. The compound of any one of paragraphs 5 to 13, wherein for Formula IIa or IIIa, R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

16. The compound of any one of paragraphs 5 to 13, or 15, wherein for Formula IIa or IIIa, R₁ and R₂ together, R₂ and R₃ together, R₃ and R₄ together, R₁, and R_{2′} together, R_{2′} and R_{3′} together, R₃ and R₄, together, or a combination thereof, with the atom to which they are attached, form:

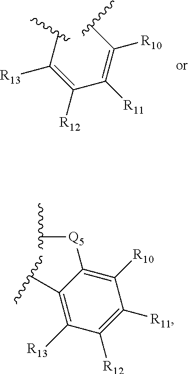

wherein Q₅ is NR₁₄, carbon, or sulfur, or oxygen; and R₁₀-R₁₄ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₁-C₂₀ heterocyclyl, or unsubstituted C₁-C₂₀ heterocyclyl.

17. The compound of paragraph 16, wherein Q₅ is NR₁₄, carbon, or sulfur, or oxygen, such as oxygen; and R₁₀-R₁₄ are independently absent, hydrogen, substituted alkyl, or unsubstituted alkyl.

18. The compound of paragraph 16 or 17, wherein Q₅ is oxygen; and R₁₀-R₁₄ are hydrogen.

19. The compound of any one of paragraphs 5 to 9, wherein for Formula IIb or IIIb, one or more of X₁, X₂, and X₃, and one or more of X_{1′}, X_{2′} and X_{3′} are sulfur, oxygen, or nitrogen, and X₁, X₂, X₃, X_{1′}, X_{2′} and X_{3′} are independently bonded to one or no hydrogen atom according to valency.

20. The compound of any one of paragraphs 5 to 9, or 19, wherein for Formula IIb or IIIb, one of X₁, X₂, and X₃, and one of X_{1′}, X_{2′} and X_{3′} are sulfur, and X₁, X₂, X₃, X_{1′}, X_{2′} and X_{3′} are independently bonded to one or no hydrogen atom according to valency.

21. The compound of any one of paragraphs 5 to 9, or 19, wherein for Formula IIb or IIIb, one of X₁, X₂, and X₃, and one of X_{1′}, X_{2′} and X_{3′}, are oxygen, and X₁, X₂, X₃, X_{1′}, X_{2′}, and X_{3′} are independently bonded to one or no hydrogen atom according to valency.

22. The compound of any one of paragraphs 5 to 9, or 19 to 21, wherein for Formula IIb or IIIb, R₁, R₂, R₃, R_{1′}, R_{2′}, and R_{3′} are independently absent, hydrogen, substituted alkyl, unsubstituted alkyl, substituted aryl, unsubstituted aryl, halogen, or R₁ and R₂ together, R₂ and R₃ together, R₁, and R_{2′} together, R_{2′} and R_{3′} together, or a combination thereof, with the atom to which they are attached, form a substituted aryl, an unsubstituted aryl, a substituted heteroaryl, an unsubstituted heteroaryl, a substituted C₁-C₂₀ heterocyclyl, an unsubstituted C₁-C₂₀heterocyclyl, or fused combinations thereof.

23. The compound of any one of paragraphs 5 to 9, or 19 to 22, wherein for Formula IIb or IIIb, R₁, R₂, R₃, R_{1′}, R_{2′}, and R_{3′} are absent, hydrogen, or a combination thereof.

24. The compound of any one of paragraphs 5 to 9, or 19 to 22, wherein for Formula IIb or IIIb, R₁ and R₂ together, R₂ and R₃ together, R₁, and R_{2′} together, R_{2′} and R_{3′} together, or a combination thereof, with the atom to which they are attached, form a substituted aryl, an unsubstituted aryl, a substituted heteroaryl, an unsubstituted heteroaryl, a substituted C₁-C₂₀ heterocyclyl, an unsubstituted C₁-C₂₀heterocyclyl, or fused combinations thereof.

25. The compound of any one of paragraphs 5 to 9, 19 to 22, or 23, wherein for Formula IIb or IIIb, R₁ and R₂ together, R₂ and R₃ together, R₁, and R_{2′} together, R_{2′} and R_{3′} together, or a combination thereof, with the atom to which they are attached, form:

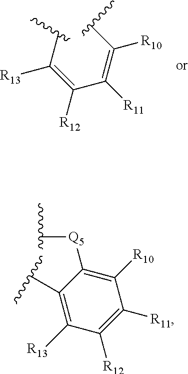

wherein Q₅ is NR₁₄, carbon, or sulfur, or oxygen; and R₁₀-R₁₄ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₁-C₂₀ heterocyclyl, or unsubstituted C₁-C₂₀ heterocyclyl.

26. The compound of paragraph 27, wherein Q₅ is NR₁₄, carbon, sulfur, or oxygen, such as sulfur, and R₁₀-R₁₄ are independently absent, hydrogen, substituted alkyl, or unsubstituted alkyl.

27. The compound of paragraph 25 or 26, wherein Q₅ is sulfur; and R₁₀-R₁₄ are hydrogen.

28. The compound of any one of paragraphs 1 to 6, wherein for Formula Ia, IIa, or IIb, the compound has a structure:

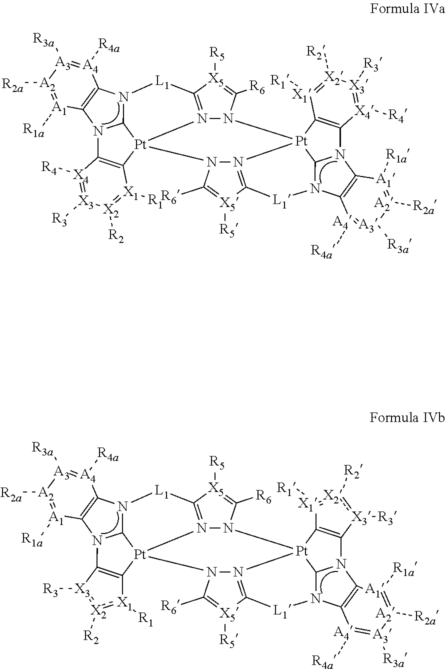

wherein:
A₁, A₂, A₃, A₄, A_{1′}, A_{2′}, A_{3′}, and A₄, are independently carbon, nitrogen, oxygen, or sulfur, and are independently bonded to one or no hydrogen atom according to valency, and
X₁, X₂, X₃, X₄, X_{1′}, X_{2′}, X_{3′}, and X_{4′} when present, are independently carbon, nitrogen, oxygen, or sulfur, and are independently bonded to one or no hydrogen atom according to valency.

29. The compound of paragraph 28, wherein for Formula IVa, A₁, A₂, A₃, A₄, A_{1′}, A₂, A_{3′}, and A_{4′} are carbon, and are independently bonded to one or no hydrogen atom according to valency, and X₁, X₂, X₃, X₄, X_{1′}, X_{2′}, X_{3′}, and X_{4′} are carbon, and are independently bonded to one or no hydrogen atom according to valency.

30. The compound of paragraph 28 or 29, wherein for Formula IVa, R₁, R₂, R₃, R₄, R_{1′}, R_{2′}, R_{3′}, and R₄, are independently absent, hydrogen, deuterium, substituted alkyl, unsubstituted alkyl, substituted aryl, unsubstituted aryl, or halogen.

31. The compound of any one of paragraphs 28 to 30, wherein for Formula IVa, R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, or an unsubstituted aryl.

32. The compound of any one of paragraphs 28 to 31, wherein for Formula IVa, R₁ₐ and R₂ₐ together, R₃ₐ and R₄ₐ together, R_{1a′} and R_{2a′} together, R_{3a′} and R_{4a′} together, with the atom to which they are attached, form a substituted aryl, or an unsubstituted aryl.

33. The compound of any one of paragraphs 1 to 6 or 28, wherein for Formula Ia, IIa, or IVa, one or more of A₁, A₂, A₃, and A₄ are nitrogen, one or more of A_{1′}, A₂, A_{3′}, and A₄, are nitrogen, and A₁, A₂, A₃, A₄, A_{1′}, A_{2′}, A_{3′}, and A₄, are independently bonded to one or no hydrogen atom according to valency, and X₁, X₂, X₃, X₄, X_{1′}, X_{2′}, X_{3′}, and X_{4′} are carbon, and are independently bonded to one or no hydrogen atom according to valency.

34. The compound of paragraph 33, wherein for Formula IVa, R₁, R₂, R₃, R₄, R_{1′}, R_{2′}, R_{3′}, and R₄, are independently absent, hydrogen, deuterium, substituted alkyl, unsubstituted alkyl, substituted aryl (such as mesityl (2,4,6-trimethylphenyl), 3,5-di-tert-butylphenyl, 2,6-dimethylphenyl), unsubstituted aryl, or halogen (such as fluorine).

35. The compound of paragraph 33 or 34, wherein R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl (such as phenyl).

36. The compound of any one of paragraphs 33 to 35, wherein for Formula IVa, one of A₁, A₂, A₃, and A₄ is nitrogen and the others are carbon, one of A_{1′}, A₂, A_{3′}, and A₄, is nitrogen and the others are carbon, and A₁, A₂, A₃, A₄, A_{1′}, A_{2′}, A_{3′}, and A₄, are independently bonded to one or no hydrogen atom according to valency.

37. The compound of any one of paragraphs 33 to 35, wherein for Formula IVa, two of A₁, A₂, A₃, and A₄ are nitrogen and the others are carbon, two of A_{1′}, A_{2′}, A_{3′}, and A₄, are nitrogen and the others are carbon, and A₁, A₂, A₃, A₄, A_{1′}, A_{2′}, A_{3′}, and A₄, are independently bonded to one or no hydrogen atom according to valency.

38. The compound of any one of paragraphs 1 to 6 or 28, wherein for Formula Ia, IIa, or IVa, one or more of A₁, A₂, A₃, and A₄ are oxygen, nitrogen, or sulfur, one or more of A_{1′}, A_{2′}, A_{3′}, and A₄, are oxygen, nitrogen, or sulfur, and A₁, A₂, A₃, A₄, A_{1′}, A₂, A_{3′}, and A_{4′} are independently bonded to one or no hydrogen atom according to valency, and one or more of X₁, X₂, X₃, X₄, X_{1′}, X_{2′}, X_{3′}, and X_{4′} are oxygen, nitrogen, or sulfur, and X₁, X₂, X₃, X₄, X_{1′}, X_{2′}, X_{3′}, and X_{4′} are independently bonded to one or no hydrogen atom according to valency.

39. The compound of paragraph 38, wherein for Formula IVa, R₁, R₂, R₃, R₄, R_{1′}, R_{2′}, R_{3′}, and R₄, are independently absent, hydrogen, deuterium, substituted alkyl, unsubstituted alkyl, substituted aryl, unsubstituted aryl, or halogen (such as fluorine).

40. The compound of paragraph 38 or 39, wherein R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl.

41. The compound of any one of paragraphs 38 to 40, wherein for Formula IVa, one or more of A₁, A₂, A₃, and A₄ are nitrogen, one or more of A_{1′}, A₂, A_{3′}, and A₄, are nitrogen, and A₁, A₂, A₃, A₄, A_{1′}, A_{2′}, A_{3′}, and A₄, are independently bonded to one or no hydrogen atom according to valency, and one or more of X₁, X₂, X₃, X₄, X_{1′}, X_{2′}, X_{3′}, and X_{4′} are nitrogen, and X₁, X₂, X₃, X₄, X_{1′}, X_{2′}, X_{3′}, and X_{4′} are independently bonded to one or no hydrogen atom according to valency.

42. The compound of any one of paragraphs 38 to 41, wherein for Formula IVa, one of A₁, A₂, A₃, and A₄ is nitrogen and the others are carbon, one of A_{1′}, A_{2′}, A_{3′}, and A₄, is nitrogen and the others are carbon, and A₁, A₂, A₃, A₄, A_{1′}, A_{2′}, A_{3′}, and A₄, are independently bonded to one or no hydrogen atom according to valency, and one of X₁, X₂, X₃, and X₄ is nitrogen and the others are carbon, one of X_{1′}, X_{2′}, X_{3′}, and X_{4′} is nitrogen and the others are carbon, and X₁, X₂, X₃, X₄, X_{1′}, X_{2′}, X_{3′}, and X₄, are independently bonded to one or no hydrogen atom according to valency.

43. The compound of any one of paragraphs 1 to 42, having a structure:

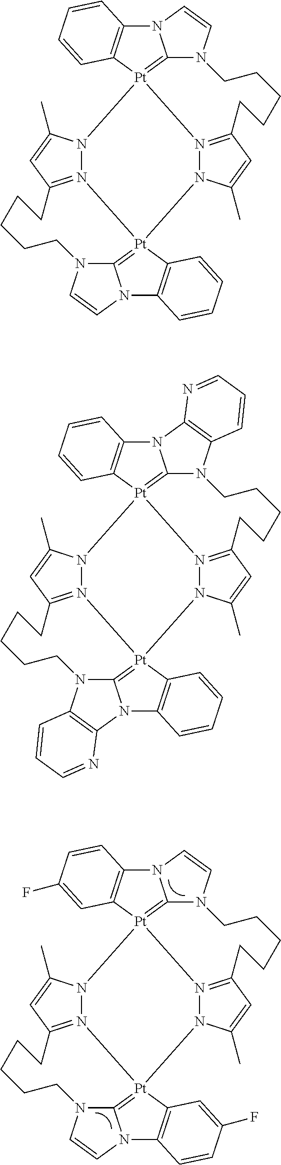

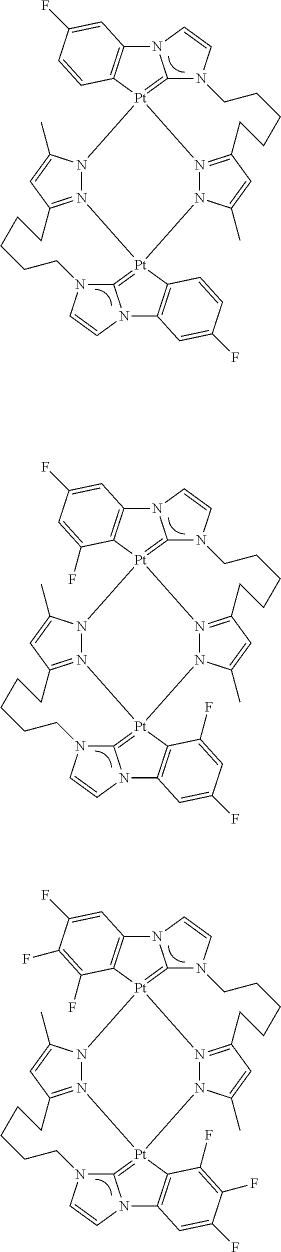

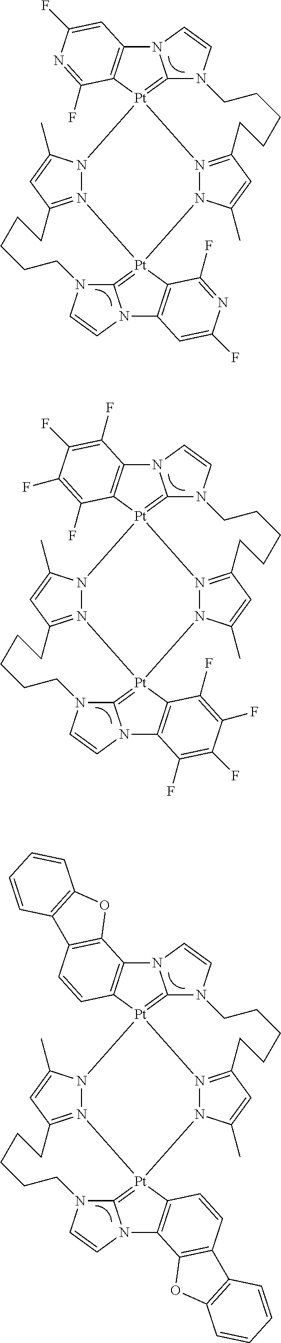

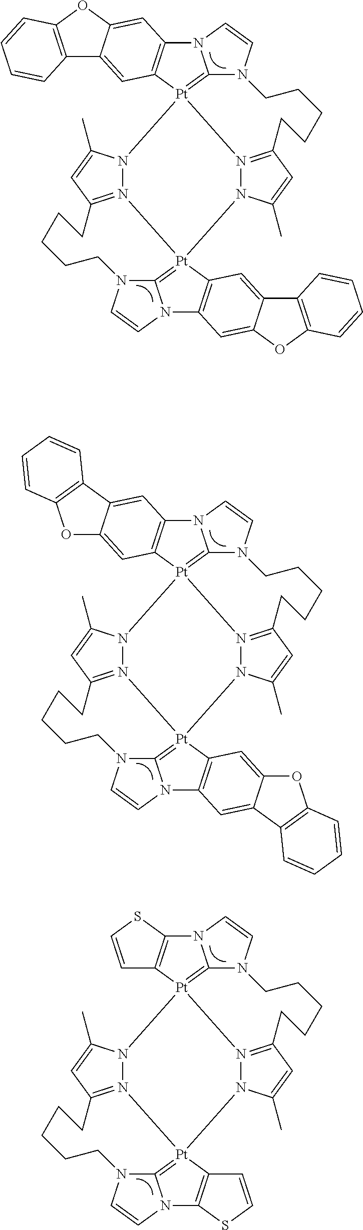

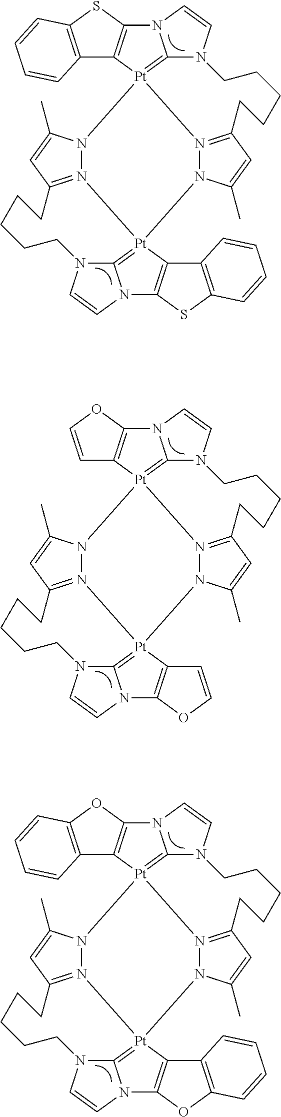

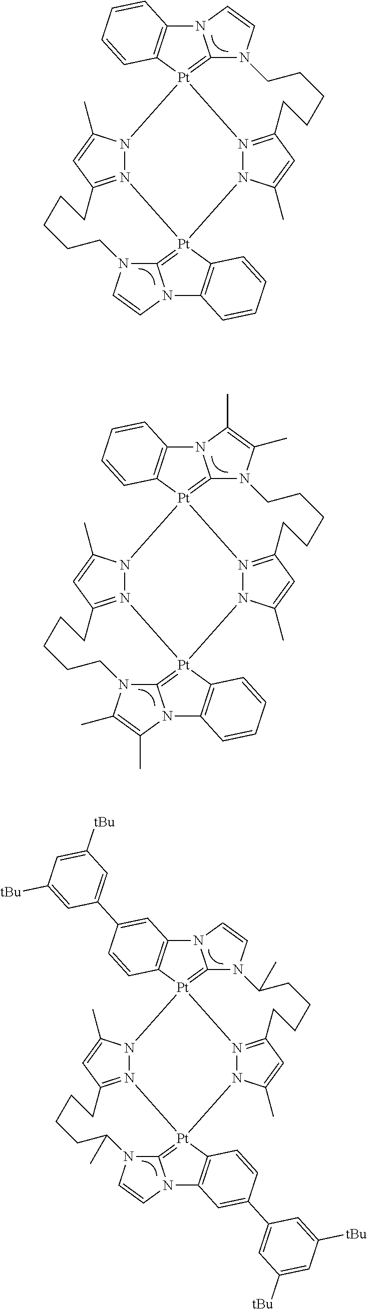

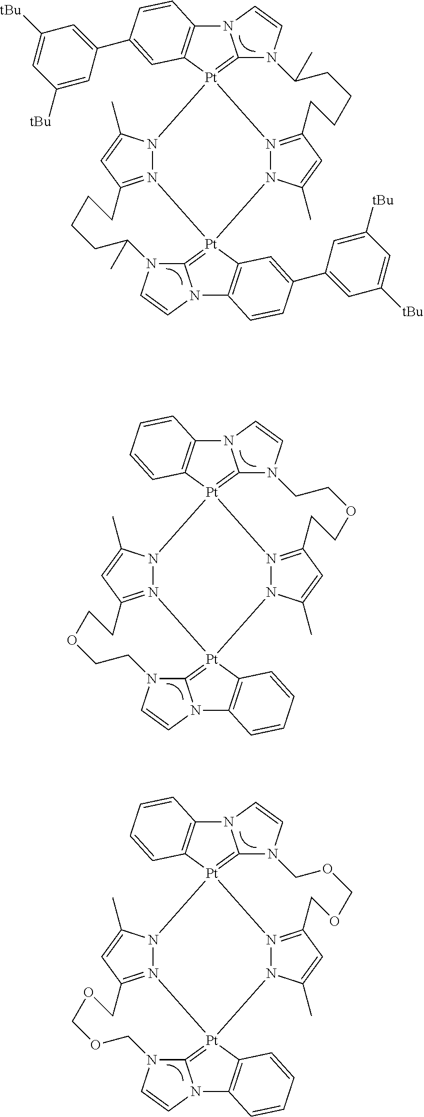

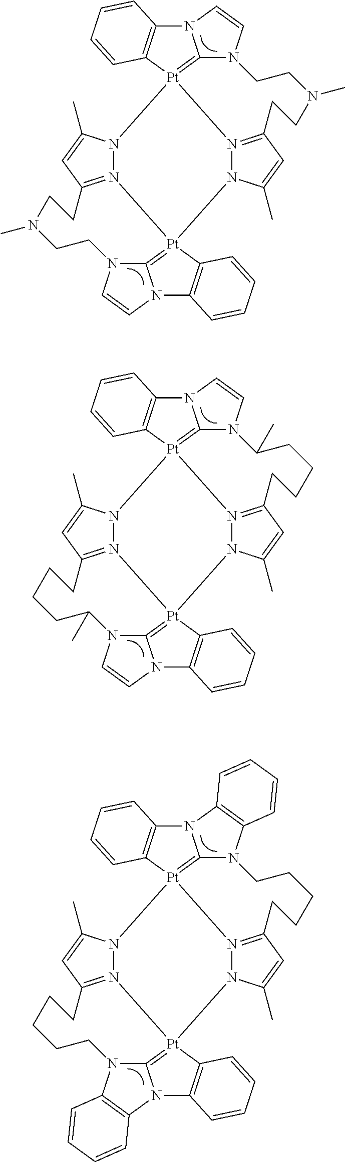

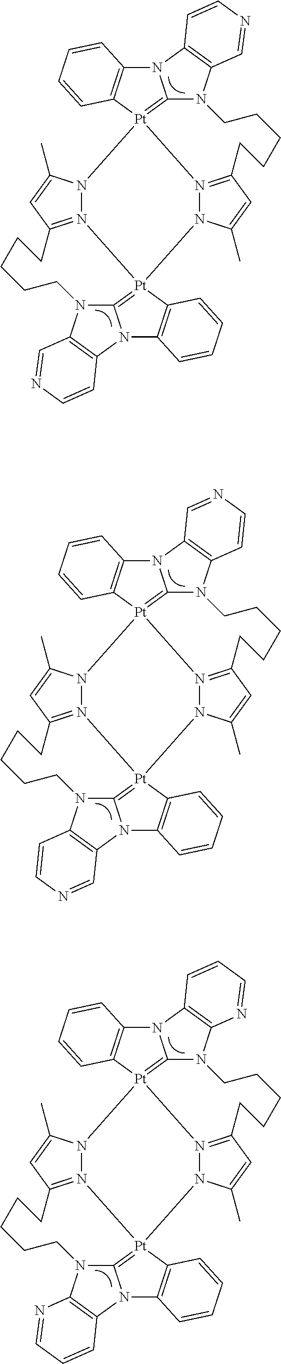

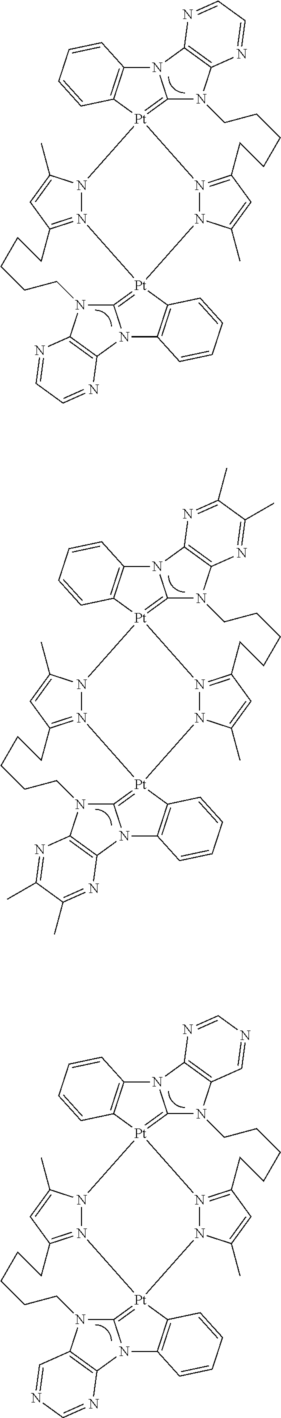

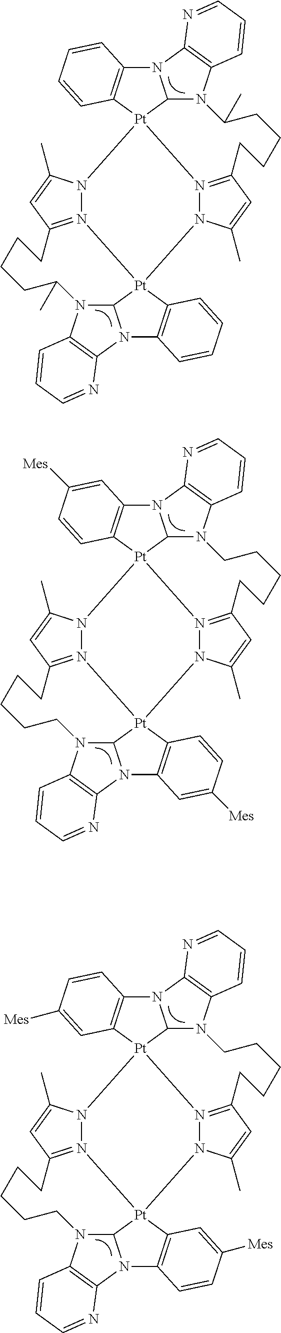

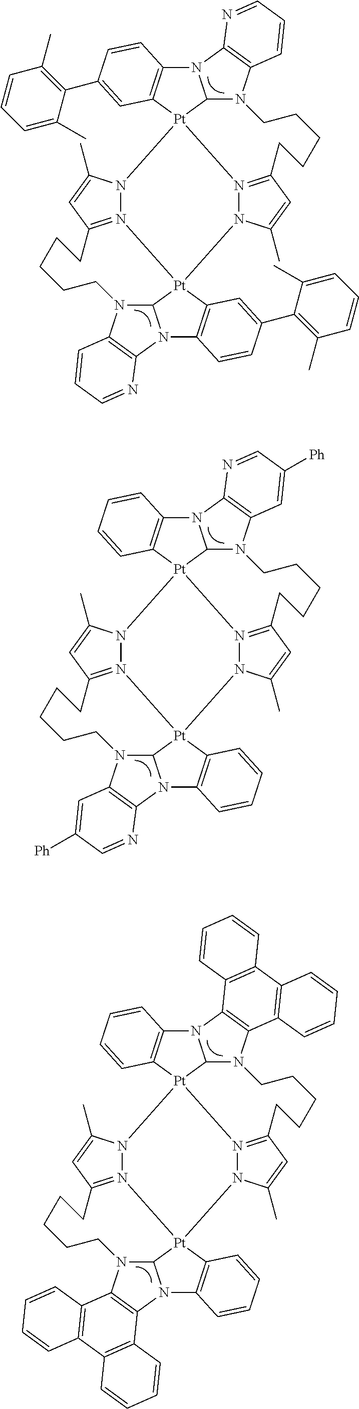

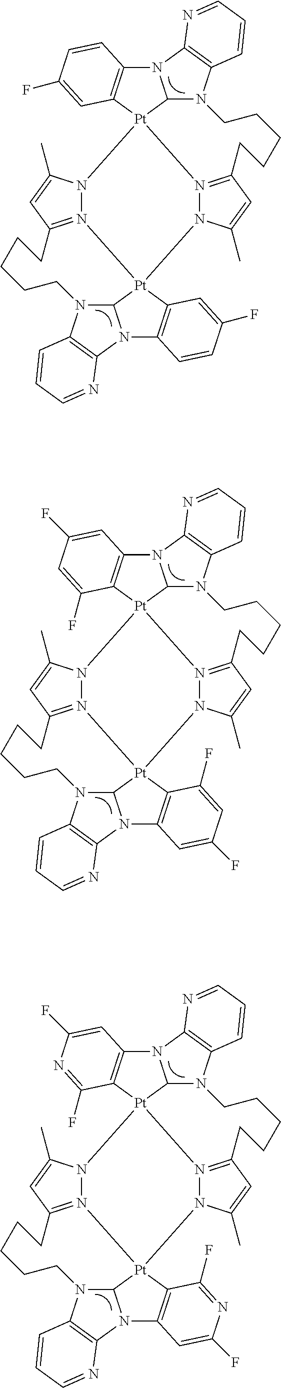

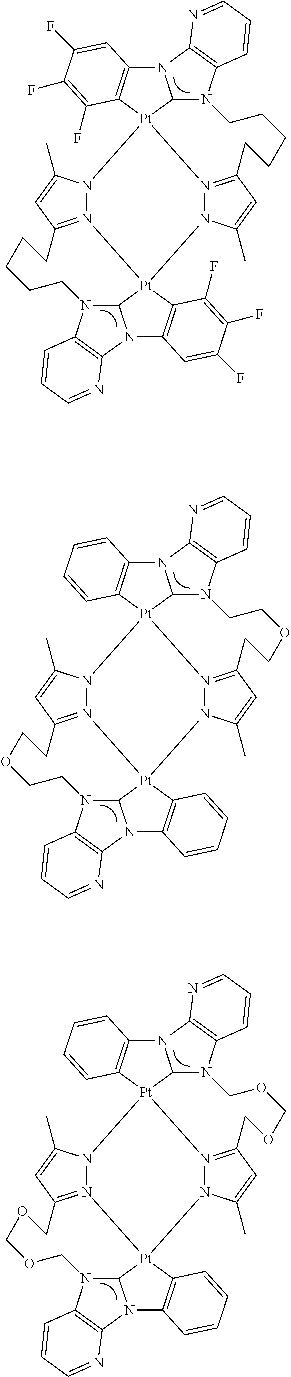

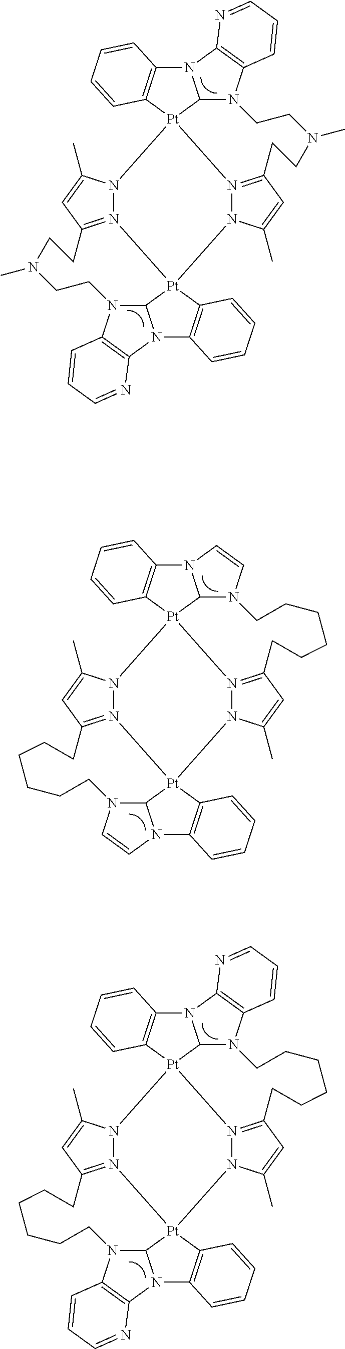

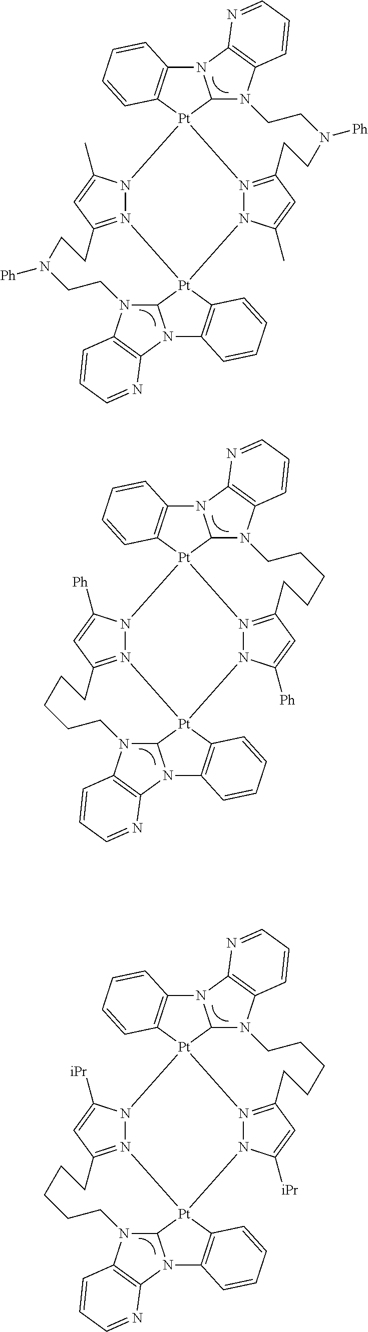

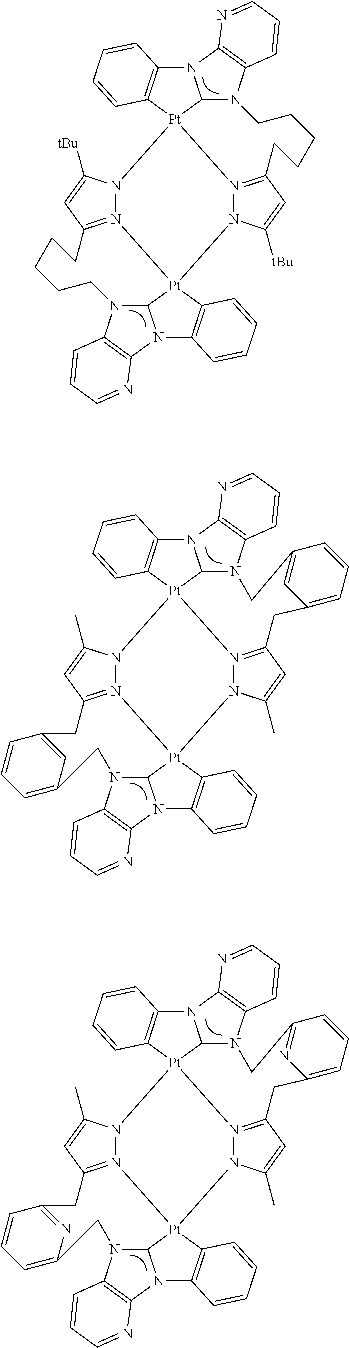

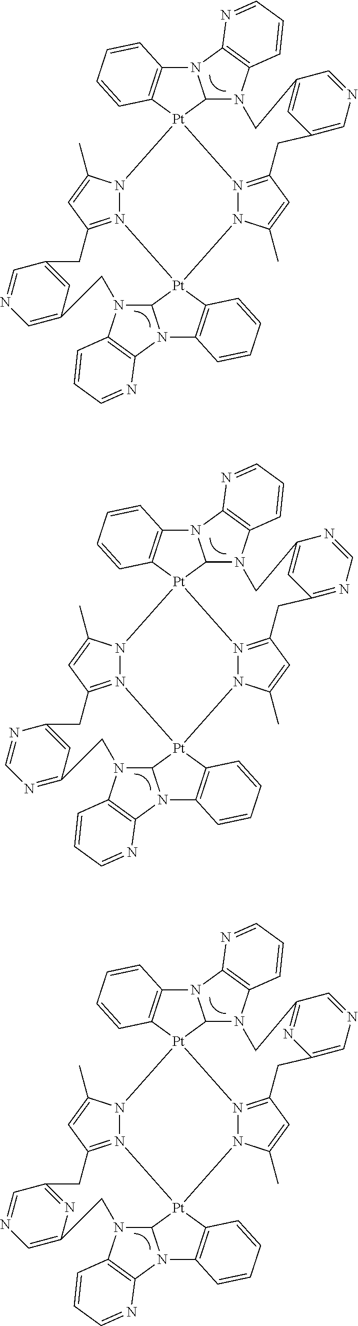

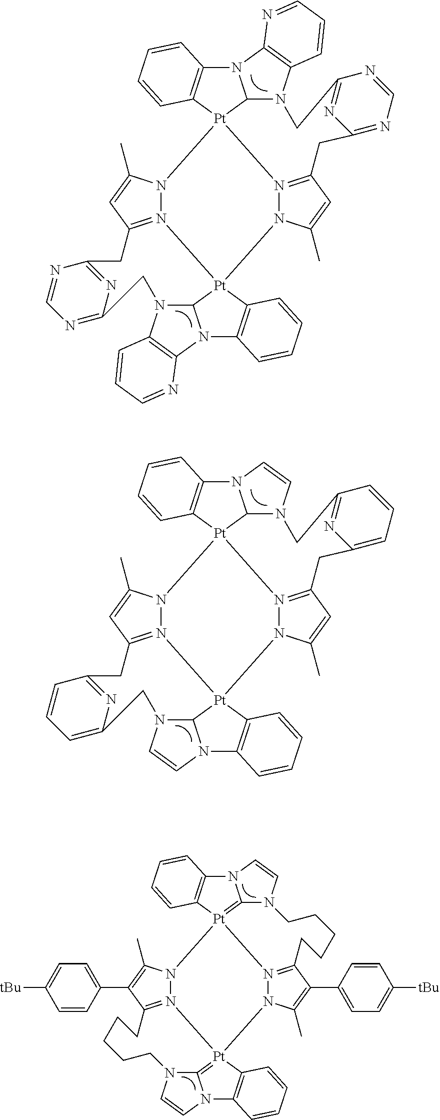

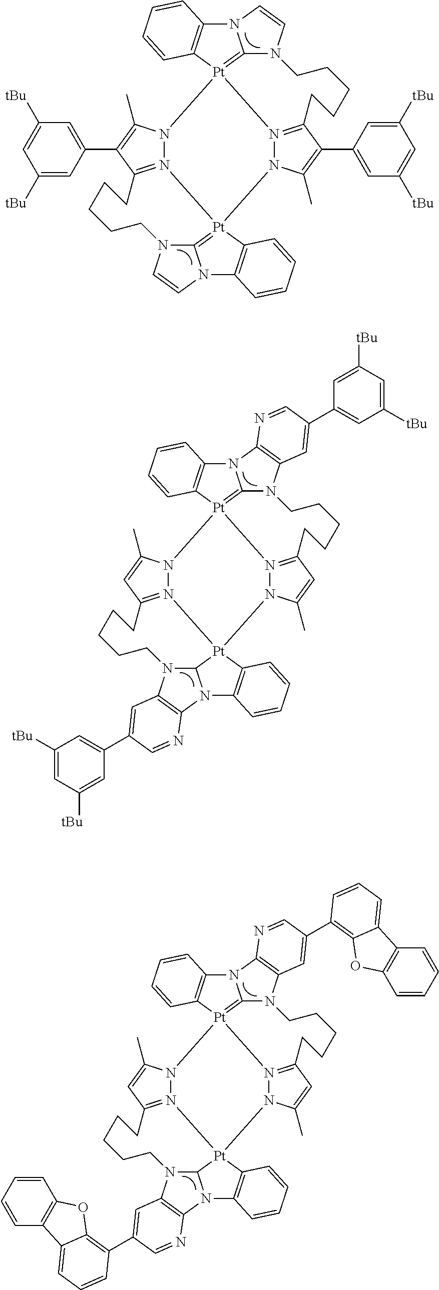

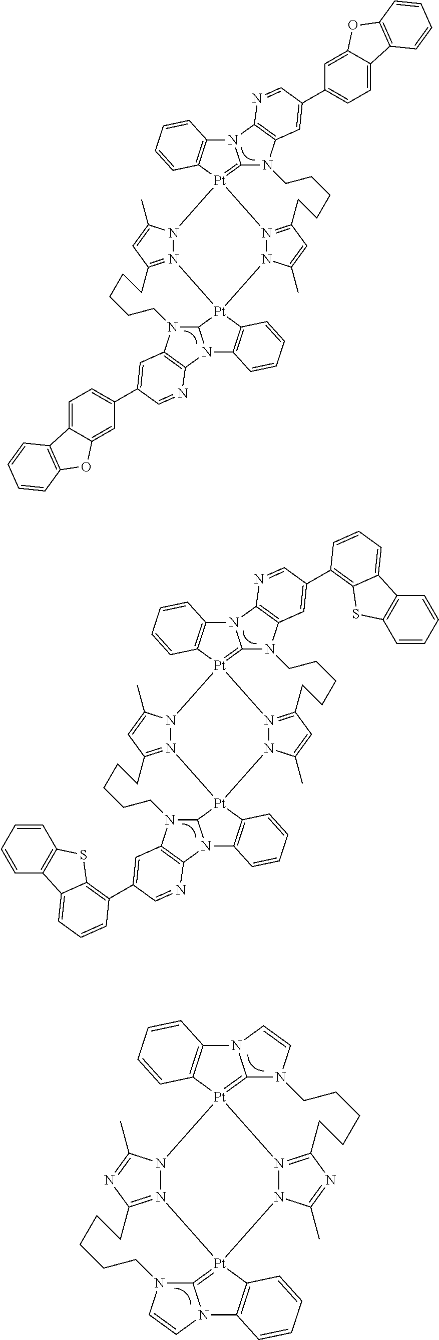

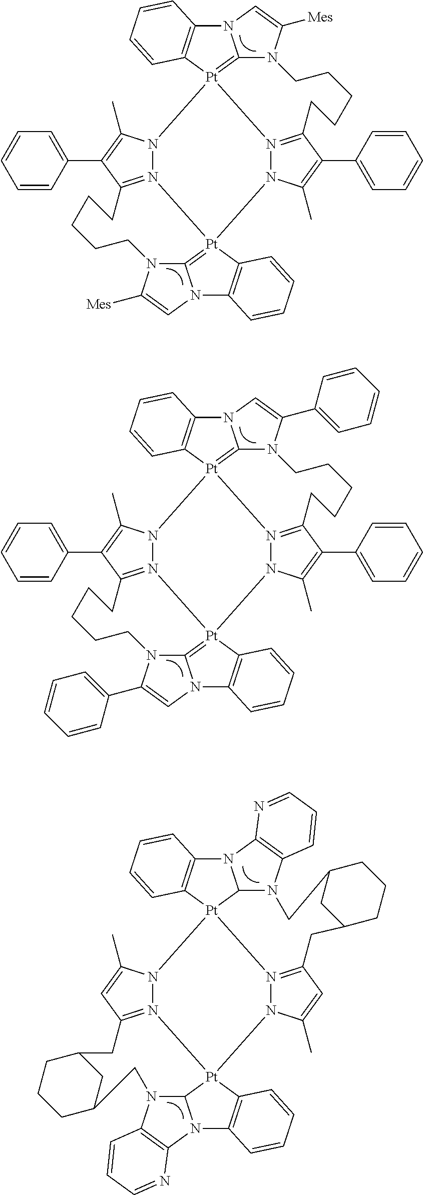

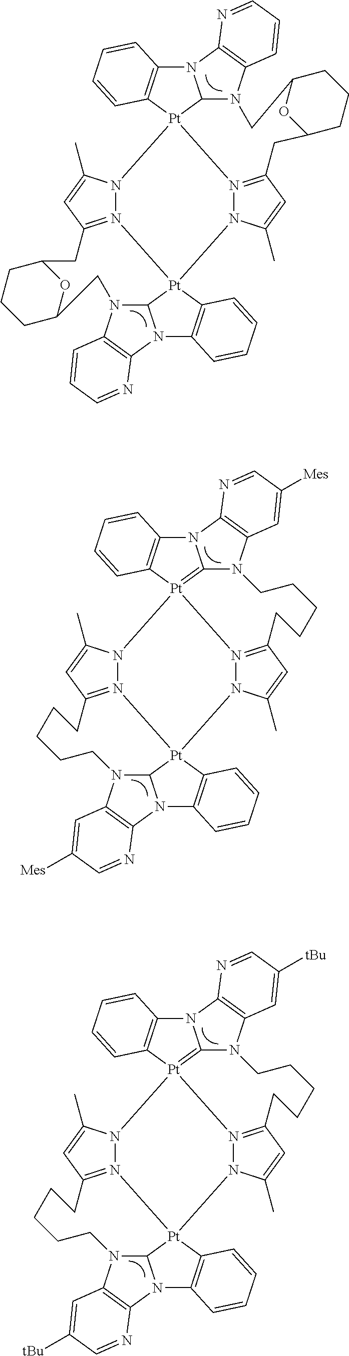

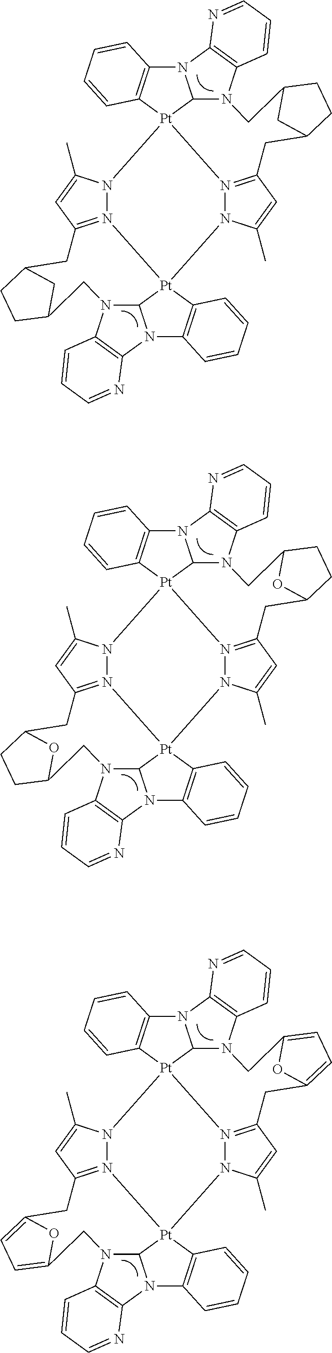

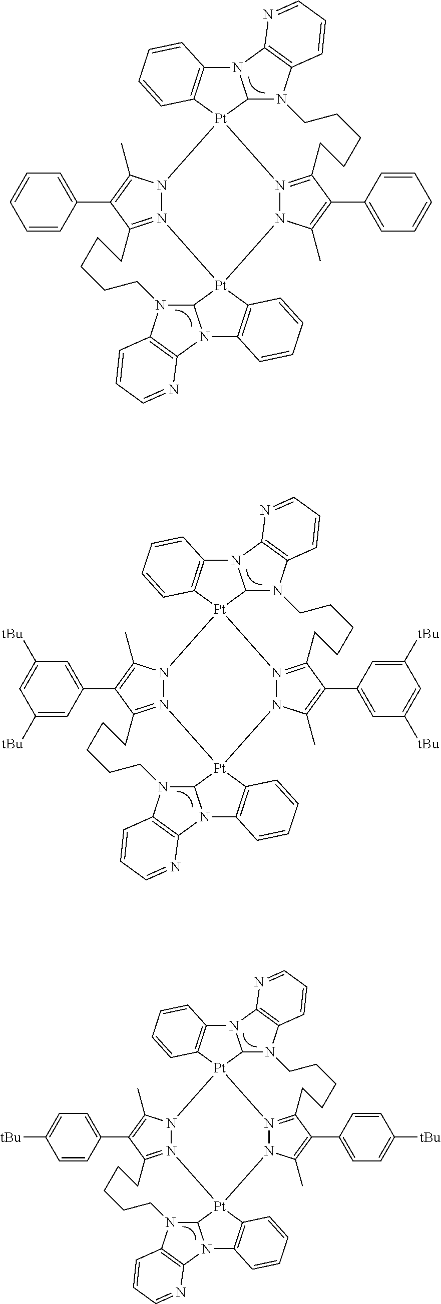

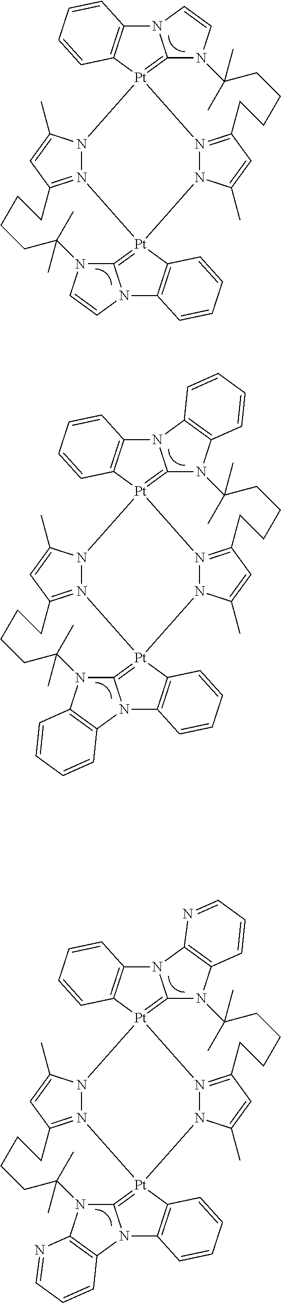

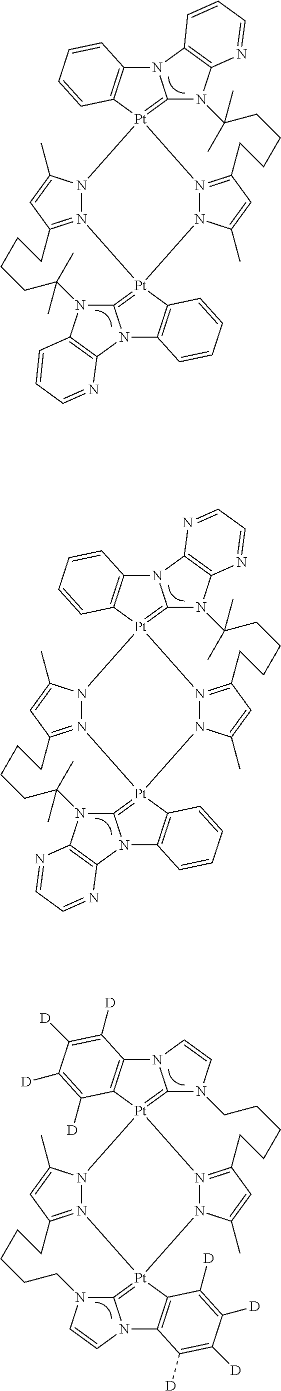

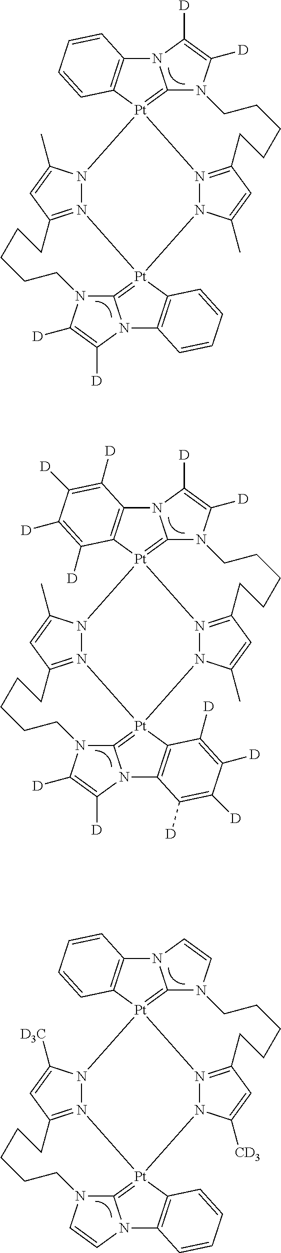

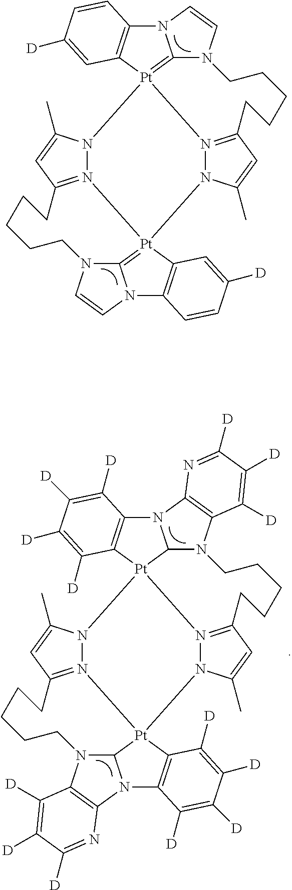

44. An organic electronic component containing the compound of any one of paragraphs 1 to 43.

45. The organic electronic component of paragraph 44, wherein the organic electronic component is an organic light-emitting diode (OLED) or a light-emitting electrochemical cell (LEEC).

46. The organic electronic component of paragraph 44 or 45 wherein the compounds are in a light-emitting layer.

47. The organic electronic component of any one of paragraphs 44 to 46, further containing an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located between the anode and the light-emitting layer, and wherein the electron transport region is located in between the cathode and the light-emitting layer.

48. The organic electronic component of paragraph 46 or 47, wherein the light-emitting layer is fabricated by vacuum deposition, spin-coating or ink printing (such as, ink-jet printing or roll-to-roll printing).

49. A light-emitting layer containing the compound of any one of paragraphs 1 to 43.

50. The light-emitting layer of paragraph 49, further containing a pure organic emitter, wherein the compound:
(i) acts as a sensitizer to transfer energy to the pure organic emitter, or
(ii) has a higher-lying singlet state than the pure organic emitter.

51. An OLED, containing the light-emitting layer of paragraph 49 or 50.

52. A device, containing the OLED of paragraph 51, wherein the device is selected from stationary visual display units, mobile visual display units, illumination units, keyboards, clothes, ornaments, garment accessories, wearable devices, medical monitoring devices, wall papers, tablet computers, laptops, advertisement panels, panel display units, household appliances, or office appliances.

### EXAMPLES

### Example 1: Synthesis and Characterization of Compounds

The new di-platinum(II) complexes, such as fluorine-free complexes, show strong deep blue phosphorescence, with outstanding emission quantum yields of up to 0.74 in thin films at room temperature. The emission can be further tuned by the substituent(s) on the cyclometalating NHC ligands. The most striking feature of the new Pt(II) emitter is its deep blue emission (emission maximum at 447 nm) and the exceptionally short radiative lifetime down to around 2 μs. The preliminary results of the vapor-deposited deep blue OLEDs exhibit EQE and CE of 12.1% and 7.53 cd/A, respectively with CIE (x,y) of 0.16, 0.07. To the best of Applicant's knowledge, this is one of the few examples of a metal complex based device that could meet National Television System Committee's (NTSC) coordinates definition for pure blue of (0.14, 0.08).

### Materials and Methods

The chemical reagents used for synthesis were purchased from commercial sources such as Dieckmann, Tiv Scientific, J & K Scientific, BLDpharm, Bidepharm, Strem Chemicals. They were directly used without further processing. The solvents used for synthesis were purchased from Duksan, RCI Labscan, Scharlau. They were directly used without further processing.

### Characterization

¹H and ¹¹C NMR spectra were recorded on DPX-400 or DPX-500 Bruker FT-NMR spectrometer. The chemical shift of proton or carbon signals were calibrated by the corresponding solvent residual signals. High resolution mass spectra were measured with Bruker Impact II mass spectrometer.

Fabrication Process of OLEDs

Indium-tin-oxide (ITO) coated glass with a sheet resistance of 10 Ω/sq was used as the anode substrate. Before film deposition, patterned ITO substrates were cleaned with detergent, rinsed in de-ionized water, acetone, and isopropanol, and then dried in an oven for 1 h in a cleanroom. The slides were then treated in an ultraviolet-ozone chamber for 5 min. The OLEDs were fabricated in a Kurt J. Lesker SPECTROS vacuum deposition system with a base pressure of 10⁻⁷ mbar. In the vacuum chamber, organic materials were thermally deposited in sequence at a rate of 0.5 Ås⁻¹. The doping process in the emissive layers (EMLs) was realized using co-deposition technology. Afterward, LiF (1.2 nm) and Al (100 nm) were thermally deposited at rates of 0.02 and 0.2 nm s⁻¹, respectively. The film thicknesses were determined in situ with calibrated oscillating quartz-crystal sensors.

Characterization of OLEDs

Current density-brightness-voltage characteristics, EL spectra, and EQE of electroluminescent (EL) device were obtained by using a Keithley 2400 source-meter and an absolute external quantum efficiency measurement system (C9920-12, Hamamatsu Photonics). All devices were encapsulated in a 200-nm-thick Al₂O₃ thin film deposited by atomic layer deposition (ALD) in a Kurt J. Lesker SPECTROS ALD system before measurements.

### (i) Synthesis of Ligand

Scheme 1 shows syntheses of tridentate NHC ligands (L1 and L2).

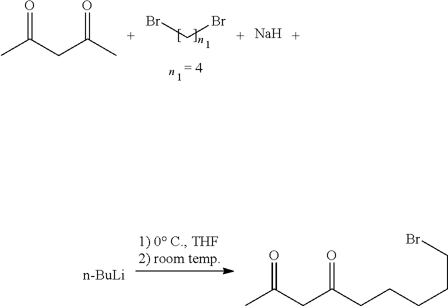

Synthesis of 9-bromononane-2,4-dione (Chen, et al., Chem. Commun., 2011, 47, 9519-9521): Acetylacetone (1 eq.) was added to NaH (1.15 eq.) at 0° C. in 20 mL dry THF. The reaction mixture was stirred for 30 mins before n-BuLi (1.2 eq.) was added. The reaction mixture was stirred for 30 mins more. Dibromoalkane (1.5 eq., n₁=4 (L1/L2)) was added and was stirred for 2 hours at 0° C. and 2 hours at room temperature. Water was added and the reaction mixture was acidified to pH-2. The aqueous phase was extracted with CHCl₃. The combined organic fraction was dried with MgSO₄, filtered, and concentrated under reduced pressure. The crude product was used in next step without further purification.

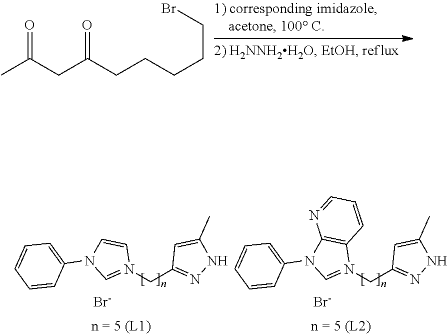

1-Phenylimidazole for L1 or 3-phenyl-3H-imidazo[4,5-b]pyridine (Pinter, et al., Organometallics 2016, 35, 673-680) for L2 (0.66 equiv.) and 9-bromononane-2,4-dione (Chen, et al., Chem. Commun., 2011, 47, 9519-9521) (1.00 equiv.) were stirred for 48 h at 100° C. in acetone (1 mL per 1 mmol of imidazole). The solvent was removed under reduced pressure and the residue was used in next step without further purification. Hydrazine hydrate (1.1 equiv.) and EtOH (2 mL per 1 mmol of imidazole) was added and the reaction mixture was refluxed overnight. The solvent was removed under reduced pressure and the residue was purified with silica gel column with acetone/EtOH.

L1: Overall yield: 54%. ¹H NMR (500 MHz, DMSO): δ 11.99 (s, 1H), 9.80 (s, 1H), 8.30 (s, 1H), 8.01 (s, 1H), 7.76 (d, J=8.1 Hz, 2H), 7.64 (t, J=7.7 Hz, 2H), 7.56 (t, J=7.4 Hz, 1H), 5.73 (s, 1H), 4.21 (t, J=7.2 Hz, 2H), 3.41 (q, J=6.8 Hz, 2H), 2.08 (s, 3H), 1.93-1.84 (m, 2H), 1.62-1.53 (m, 2H), 1.33-1.27 (m, 2H). HRMS (ESI) for C₁₈H₂₃N₄[M]⁺: calcd 295.1923, found 295.1916.

L2: Overall yield: 22%. ¹H NMR (500 MHz, DMSO): δ 10.44 (s, 1H), 8.82 (d, J=4.8 Hz, 1H), 8.75 (d, J=8.4 Hz, 1H), 7.93 (d, J=7.9 Hz, 2H), 7.90-7.85 (m, 1H), 7.75 (t, J=7.7 Hz, 2H), 7.68 (t, J=7.6 Hz, 1H), 5.94 (s, 1H), 4.58 (t, J=7.1 Hz, 2H), 2.19 (s, 3H), 2.06-2.00 (m, 2H), 1.70-1.62 (m, 2H), 1.56-1.53 (m, 2H), 1.50-1.42 (m, 2H).

### (ii) Synthesis of Platinum (II) Emitter

Scheme 2 shows the syntheses of dinuclear platinum(II) emitter complexes.

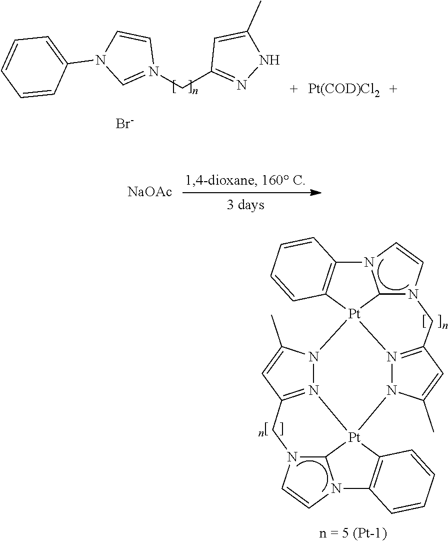

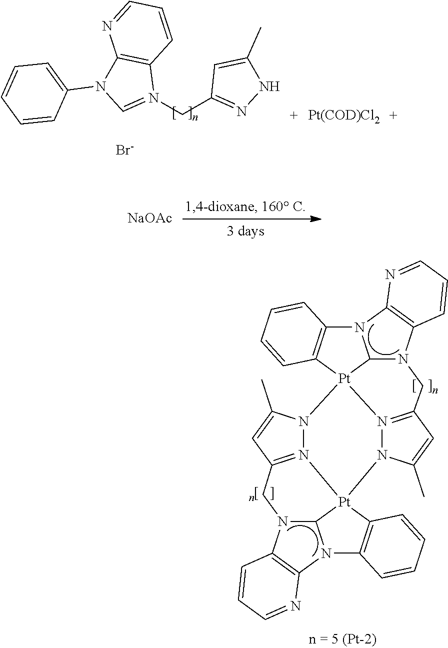

L1 or L2 (1 eq.), Pt(COD)C₁₂, (1.04 eq.) and NaOAc (3 eq.) was stirred in 1,4-dioxane (1 mL per 0.1 mmol of imidazolium salt) at 160° C. for 3 days. Water was added to the reaction mixture and the aqueous phase was extracted with DCM. The organic phase was dried with MgSO4, filtered and concentrated under reduced pressure. The crude product was purified with silica gel column using DCM/hexane as eluent.

Pt-1: Yield: 17%. ¹H NMR (500 MHz, DMSO): δ 7.89 (s, 2H), 7.26 (s, 2H), 7.21 (d, J=7.6 Hz, 2H), 6.96-6.87 (m, 4H), 6.74 (t, J=7.3 Hz, 2H), 6.00 (s, 2H), 3.65-3.57 (m, 2H), 3.47-3.40 (m, 2H), 2.97-2.90 (m, 2H), 2.63-2.58 (m, 2H), 2.16 (s, 6H), 2.02-1.92 (m, 2H), 1.86-1.74 (m, 2H), 1.74-1.59 (m, 4H), 1.57-1.48 (m, 2H), 1.30-1.24 (m, 2H). HRMS (ESI) for C₃₆H₄₁N₈Pt₂ [M+H]⁺: calcd. 975.2750, found 975.2724.

Pt-2: Yield: 2%. ¹H NMR (500 MHz, CD₂Cl₂): δ 8.36 (s, 1H), 8.35 (s, 1H), 7.61 (d, J=8.1 Hz, 1H), 7.20-7.11 (m, 2H), 7.06 (t, J=7.4 Hz, 1H), 6.89 (t, J=7.4 Hz, 1H), 6.15 (s, 1H), 4.33-4.23 (m, 1H), 3.91-3.83 (m, 1H), 3.16 (t, J=13.7 Hz, 1H), 2.79 (d, J=15.2 Hz, 1H), 2.32 (s, 3H), 2.11-2.02 (m, 1H), 1.96-1.80 (m, J=39.1 Hz, 3H), 1.65-1.58 (m, 2H). HRMS (ESI) for C₄₂H₄₃N₁₀Pt₂ [M+H]⁺: calcd 1077.2968, found 1077.2950.

### Results

The results of the instant work are presented below.

Photophysical Characterization of the Dinuclear Complexes in Host Compounds

The dinuclear Pt(II) complexes (Pt-1 and Pt-2) display strong deep blue to blue photoluminescence at 447-480 nm with emission quantum yield of 0.74-0.82 in PMMA film at room temperature. The emission lifetimes are short, of 1.3-2.0 μs, giving rise to large radiative rate constant of 3.7×10⁵ s⁻¹ to 6.3×10⁵ s⁻¹ or short radiative lifetimes of 1.6-2.7 μs. The absorption and emission data, and related photophysical data are shown in Table 1.

TABLE 1
Emission data of Pt-1 at room temperature

| | | | | Φₑₘ; | kᵣ/×10⁵ s⁻¹; |
|---|---|---|---|---|---|
| | medium | λₑₘ/nm | FWHM/nm | τₑₘ/μs | τᵣ/μs |
| Pt-1 | 4 wt/wt % | 425, 447 | 60 | 0.74; 2.0 | 3.7; 2.7 |
| | t in PMMA | | | | |
| Pt-2 | 4 wt/wt % | 480 | 74 | 0.82; 1.3 | 6.3; 1.6 |
| | in PMMA | | | | |

Vacuum-deposited devices fabricated with Pt-1 exhibited deep-blue electroluminescence with CIE(x, y) of (0.15-0.16, 0.07-0.08) at different doping concentrations. The maximum EQE and CE of the devices doped with 4 wt/wt % of Pt-1 were 12.14% and 7.53 cd/A, respectively, giving decent blue-index of 108.

TABLE 2
Performance data of vacuum-deposited devices with Pt-1

| | | CE [cd A⁻¹] | | PE [lm W⁻¹] | | EQE [%] | | | | |
|---|---|---|---|---|---|---|---|---|---|---|
| | | | at | | at | | at | | | |
| | | | 1000 | | 1000 | | 1000 | | | |
| Pt-1 | L [cd | | cd | | cd | | cd | CIE | FWHM | λmax |
| conc. | m⁻²] | Max | m⁻² | Max | m⁻² | Max | m⁻² | [(x,y)] | [nm] | [nm] |
| 4 | 3900 | 7.53 | 2.29 | 6.45 | 0.92 | 12.14 | 3.69 | 0.16, | 56 | 449 |
| wt/wt % | | | | | | | | 0.07 | | |
| (A) | | | | | | | | | | |
| 8 | 3730 | 7.35 | 2.95 | 6.42 | 1.22 | 10.71 | 4.24 | 0.15, | 58 | 452 |
| wt/wt % | | | | | | | | 0.07 | | |
| (A) | | | | | | | | | | |
| 16 | 2030 | 6.51 | 2.21 | 5.59 | 0.81 | 8.55 | 2.92 | 0.16, | 60 | 453 |
| wt/wt % | | | | | | | | 0.08 | | |
| (A) | | | | | | | | | | |

(A) Device structure: ITO/HAT-CN(5 nm)/TAPC(40 nm)/TcTa(7 nm)/CzSi(3 nm)/Pt-1:CzSi (10 nm)/TSPO1(30 nm)/LiF (1 nm)/Al (100 nm)

TABLE 3
Comparison with other Pt(II) blue emitters

| | Current data | | |
|---|---|---|---|
| | for Pt-1 | IP00584 | IP01050 |
| Kᵣ; kₙᵣ (s⁻¹) | 3.7 × 10⁵; | 1.0 × 10⁵; | 2.4 × 10⁵; |
| | 1.3 × 10⁵ | 2.5 × 10⁴ | 6.7 × 10⁴ |
| CIE (x, y) | (0.15, 0.07) | (0.14, 0.16) | (0.15, 0.11) |
| Maximum Brightness (cd/m²) | 3730 | NA | 2620 |
| Current efficiency @1000 | 3.0 | 21.6 | 12.4 |
| cd/m² (cd/A) | | | |
| Power efficiency @1000 | 1.2 | 13.6 | 7.0 |
| cd/m² (lm/W) | | | |
| External quantum efficiency | 4.3 | 16.6 | 11.4 |
| @1000 cd/m² (%) | | | |
| LT | NA | NA | NA |

Work is ongoing to (i) further enhance the thermal stability of the complex for facile application in vacuum-deposition fabrication techniques, and (ii) further elucidate structure-property relationship that could guide the enhancement of photophysical attributes (such as emission band-width, color purity) to cater for blue OLED applications.

Unless defined otherwise, all technical and scientific terms used herein have the same meanings as commonly understood by one of skill in the art to which the disclosed invention belongs. Publications cited herein and the materials for which they are cited are specifically incorporated by reference.

Further, unless otherwise indicated, use of the expression “wt %” refers to “wt/wt %.”

Those skilled in the art will recognize, or be able to ascertain using no more than routine experimentation, many equivalents to the specific embodiments of the invention described herein. Such equivalents are intended to be encompassed by the following claims.

We claim:

1. A compound having a structure: 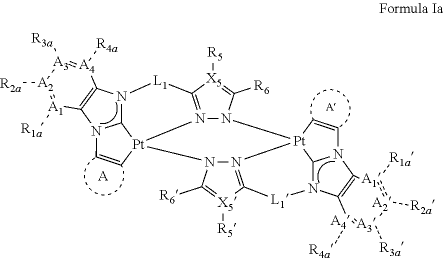
wherein:
the compound has an overall neutral, negative, or positive charge,
the dashed linear lines denote the presence or absence of a bond,
A and A′ are independently a substituted cycloalkyl, an unsubstituted cycloalkyl, a substituted cycloalkenyl, an unsubstituted cycloalkenyl, a substituted cycloalkynyl, an unsubstituted cycloalkynyl, a substituted C₁-C₂₀ heterocyclyl, an unsubstituted C₁-C₂₀heterocyclyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, or fused combinations thereof; preferably A and A′ are independently a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, or fused combinations thereof,
X₅, and X₅, are independently carbon or nitrogen, and are independently bonded to one or no hydrogen atom according to valency, preferably, X₅ and X₅, are carbon,
R₅, R₆, R_{5′}, and R₆, are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or R₅ and R₆ together, R₅, and R₆, together, with the atom to which they are attached, form a substituted aryl, an unsubstituted aryl, a substituted heteroaryl, an unsubstituted heteroaryl, a substituted C₁-C₂₀ heterocyclyl, an unsubstituted C₁-C₂₀ heterocyclyl, fused combinations thereof, or preferably R₅, R₆, R_{5′}, and R₆, are independently absent, hydrogen, substituted alkyl, unsubstituted alkyl, substituted aryl, unsubstituted aryl,
A₁, A₂, A₃, A₄, A_{1′}, A₂, A_{3′}, and A₄, are independently absent, hydrogen, deuterium, carbon, nitrogen, unsubstituted aryl, or unsubstituted aryl, and, when present, are independently bonded to one, two, three, four, five, or no hydrogen atom according to valency,
R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, unsubstituted C₁-C₂₀heterocyclyl, a fused combination thereof (such as dibenzofuran-4-yl, dibenzofuran-3-yl, dibenzothiopen-4-yl, dibenzothiopen-3-yl, etc.), or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, fused combinations thereof, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, fused combinations thereof, and
L₁ and L_{1′} are independently substituted alkyl, unsubstituted alkyl, substituted alkenyl, unsubstituted alkenyl, substituted alkynyl, unsubstituted alkynyl, unsubstituted alkoxy, substituted alkoxy, unsubstituted aroxy, substituted aroxy, unsubstituted alkylthio, substituted alkylthio, unsubstituted carbonyl, substituted carbonyl, unsubstituted carboxyl, substituted carboxyl, unsubstituted ester, substituted ester, unsubstituted ether, substituted ether, unsubstituted polyether, substituted polyether, substituted amino, unsubstituted amino, substituted amide, unsubstituted amide, substituted aryl, unsubstituted aryl, substituted heteroaryl, unsubstituted heteroaryl, substituted polyaryl, unsubstituted polyaryl, substituted polyheteroaryl, unsubstituted polyheteroaryl, substituted C₃-C₂₀ cycloalkyl, unsubstituted C₃-C₂₀cycloalkyl, substituted C₁-C₂₀heterocyclyl, unsubstituted C₁-C₂₀ heterocyclyl, substituted C₃-C₂₀ cycloalkenyl, unsubstituted C₃-C₂₀ cycloalkenyl, substituted C₃-C₂₀ cycloalkynyl, unsubstituted C₃-C₂₀ cycloalkynyl, or fused combinations thereof.

2. The compound of claim 1, wherein L₁ and L_{1′} are independently substituted alkyl or unsubstituted alkyl.

3. The compound of claim 1, wherein L₁ and L_{1′} are independently substituted C₁-C₁₀ alkyl, unsubstituted C₁-C₁₀ alkyl, substituted C₂-C₁₀ alkyl or unsubstituted C₂-C₁₀ alkyl, preferably wherein the substituted alkyl, substituted C₁-C₁₀ alkyl, substituted C₂-C₁₀ alkyl contains one or more alkyl substituents (such as methyl, ethyl, propyl, iso-propyl, n-butyl, sec-butyl, tert-butyl), one or more ether bonds, one or more amine groups (such as substituted amine or unsubstituted amine), one or more substituted aryl groups, one or more substituted heteroaryl groups, one or more substituted C₃-C₂₀ cycloalkyl groups, one or more substituted C₁-C₂₀ heterocyclyl groups, or a combination thereof.

4. The compound of claim 1, wherein R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀heterocyclyl, fused combinations thereof.

5. The compound of claim 1, having a structure: 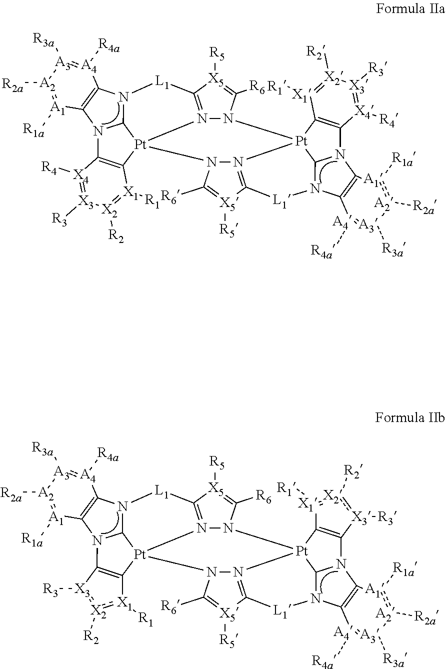
wherein:
the dashed linear lines denote the presence or absence of a bond,
X₁, X₂, X₃, X₄, X_{1′}, X_{2′}, X_{3′}, and X_{4′} when present, are independently carbon, nitrogen, oxygen, or sulfur, and are independently bonded to one or no hydrogen atom according to valency,
R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted alkenyl, unsubstituted alkenyl, substituted alkynyl, unsubstituted alkynyl, substituted aryl (such as mesityl (2,4,6-trimethylphenyl), 3,5-di-tert-butylphenyl, 2,6-dimethylphenyl), unsubstituted aryl, halogen (such as fluorine), hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₁-C₂₀ heterocyclyl, unsubstituted C₁-C₂₀heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, or R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted cycloalkyl, an unsubstituted cycloalkyl, a substituted cycloalkenyl, an unsubstituted cycloalkenyl, a substituted cycloalkynyl, an unsubstituted cycloalkynyl, a substituted aryl, an unsubstituted aryl, a substituted heteroaryl, an unsubstituted heteroaryl, a substituted polyaryl, an unsubstituted polyaryl, a substituted polyheteroaryl, an unsubstituted polyheteroaryl, a substituted C₁-C₂₀heterocyclyl, an unsubstituted C₁-C₂₀ heterocyclyl, or fused combinations thereof.

6. The compound of claim 5, wherein R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀ heterocyclyl, or fused combinations thereof.

7. The compound of claim 1, having a structure: 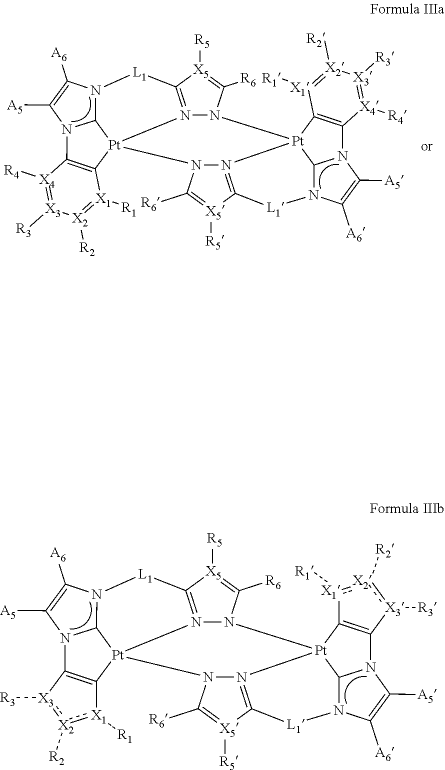
wherein:
the dashed linear lines denote the presence or absence of a bond,
A₅, A₆, A_{5′}, and A₆, are independently hydrogen, deuterium, unsubstituted alkyl, substituted alkyl, substituted aryl, unsubstituted aryl, unsubstituted heteroaryl, substituted heteroaryl, unsubstituted polyheteroaryl, substituted polyheteroaryl, substituted C₁-C₂₀ heterocyclyl, or unsubstituted C₁-C₂₀heterocyclyl; or preferably hydrogen, unsubstituted alkyl, substituted alkyl, deuterium, substituted aryl, or unsubstituted aryl.

8. The compound of claim 7, wherein A₅, A₆, A_{5′}, and A₆, are hydrogen or deuterium.

9. The compound of claim 7, wherein A₅, A₆, A_{5′}, and A₆, are
(i) unsubstituted alkyl (such as unsubstituted C₁-C₁₀ alkyl, unsubstituted C₁-C₅ alkyl, or unsubstituted C₁-C₃ alkyl) or substituted alkyl (such as substituted C₁-C₁₀ alkyl, substituted C₁-C₅ alkyl, or substituted C₁-C₃ alkyl), or
(ii) hydrogen, substituted aryl, or unsubstituted aryl, with the proviso at least one of A₅ and A₆, or A₅, and A₆, is substituted aryl or unsubstituted aryl.

10. The compound of claim 5, wherein for Formula IIa or IIIa, X₁, X₂, X₃, X₄, X_{1′}, X_{2′}, X_{3′}, and X_{4′} are carbon, and are independently bonded to one or no hydrogen atom according to valency.

11. The compound of claim 5, wherein for Formula IIa or IIIa, one or more of X₁, X₂, X₃, and X₄, and one or more of X_{1′}, X_{2′}, X_{3′}, and X_{4′} are nitrogen, and X₁, X₂, X₃, X₄, X_{1′}, X_{2′}, X_{3′}, and X_{4′} are independently bonded to one or no hydrogen atom according to valency.

12. The compound of claim 5, wherein for Formula IIa or IIIa, X₂ and X_{2′} are nitrogen, X₁, X₃, X₄, X_{1′}, X_{3′}, and X_{4′} are carbon, and X₁, X₂, X₃, X₄, X_{1′}, X_{2′}, X_{3′}, and X_{4′} are independently bonded to one or no hydrogen atom according to valency.

13. The compound of claim 5, wherein for Formula IIa or IIIa, R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, halogen (such as fluorine), or R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

14. The compound of claim 5, wherein for Formula IIa or IIIa, R₁, R₂, R₃, R₄, R_{1′}, R_{2′}, R_{3′}, and R₄, are independently absent, hydrogen, deuterium, substituted alkyl (such as trifluoromethyl), unsubstituted alkyl, substituted aryl (such as mesityl (2,4,6-trimethylphenyl), 3,5-di-tert-butylphenyl, 2,6-dimethylphenyl), unsubstituted aryl, or halogen (such as fluorine).

15. The compound of claim 5, wherein for Formula IIa or IIIa, R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

16. The compound of claim 5, wherein for Formula IIa or IIIa, R₁ and R₂ together, R₂ and R₃ together, R₃ and R₄ together, R₁, and R_{2′} together, R_{2′} and R_{3′} together, R_{3′} and R_{4′} together, or a combination thereof, with the atom to which they are attached, form: 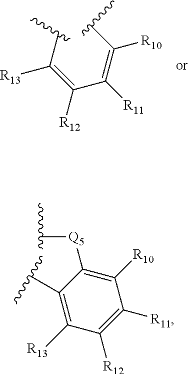
wherein Q₅ is NR₁₄, carbon, or sulfur, or oxygen; and R₁₀-R₁₄ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₁-C₂₀heterocyclyl, or unsubstituted C₁-C₂₀heterocyclyl.

17. The compound of claim 16, wherein Q₅ is NR₁₄, carbon, or sulfur, or oxygen, such as oxygen; and R₁₀-R₁₄ are independently absent, hydrogen, substituted alkyl, or unsubstituted alkyl.

18. The compound of claim 16, wherein Q₅ is oxygen; and R₁₀-R₁₄ are hydrogen.

19. The compound of claim 5, wherein for Formula IIb or IIIb, one or more of X₁, X₂, and X₃, and one or more of X_{1′}, X_{2′} and X_{3′} are sulfur, oxygen, or nitrogen, and X₁, X₂, X₃, X_{1′}, X_{2′} and X_{3′} are independently bonded to one or no hydrogen atom according to valency.

20. The compound of claim 5, wherein for Formula IIb or IIIb, one of X₁, X₂, and X₃, and one of X_{1′}, X_{2′} and X_{3′} are sulfur, and X₁, X₂, X₃, X_{1′}, X_{2′} and X_{3′} are independently bonded to one or no hydrogen atom according to valency.

21. The compound of claim 5, wherein for Formula IIb or IIIb, one of X₁, X₂, and X₃, and one of X_{1′}, X_{2′} and X_{3′}, are oxygen, and X₁, X₂, X₃, X_{1′}, X_{2′}, and X_{3′} are independently bonded to one or no hydrogen atom according to valency.

22. The compound of claim 5, wherein for Formula IIb or IIIb, R₁, R₂, R₃, R_{1′}, R_{2′}, and R_{3′} are independently absent, hydrogen, substituted alkyl, unsubstituted alkyl, substituted aryl, unsubstituted aryl, halogen, or R₁ and R₂ together, R₂ and R₃ together, R₁, and R_{2′} together, R_{2′} and R_{3′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀heterocyclyl, or fused combinations thereof.

23. The compound of claim 5, wherein for Formula IIb or IIIb, R₁, R₂, R₃, R_{1′}, R_{2′}, and R_{3′} are absent, hydrogen, or a combination thereof.

24. The compound of claim 5, wherein for Formula IIb or IIIb, R₁ and R₂ together, R₂ and R₃ together, R₁, and R_{2′} together, R_{2′} and R_{3′} together, or a combination thereof, with the atom to which they are attached, form a substituted aryl, an unsubstituted aryl, a substituted heteroaryl, an unsubstituted heteroaryl, a substituted C₁-C₂₀heterocyclyl, an unsubstituted C₁-C₂₀ heterocyclyl, or fused combinations thereof.

25. The compound of claim 5, wherein for Formula IIb or IIIb, R₁ and R₂ together, R₂ and R₃ together, R₁, and R_{2′} together, R_{2′} and R_{3′} together, or a combination thereof, with the atom to which they are attached, form: 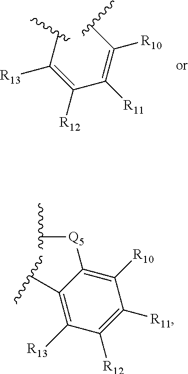
wherein Q₅ is NR₁₄, carbon, or sulfur, or oxygen; and R₁₀-R₁₄ are independently absent, hydrogen, substituted alkyl, unsubstituted alkyl, substituted alkenyl, unsubstituted alkenyl, substituted alkynyl, unsubstituted alkynyl, substituted aryl, unsubstituted aryl, halogen, hydroxyl, amino, amido, ether, thiol, cyano, nitro, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted carbonyl, substituted carbonyl, unsubstituted ester, substituted ester, substituted C₁-C₂₀heterocyclyl, or unsubstituted C₁-C₂₀heterocyclyl.

26. The compound of claim 27, wherein Q₅ is NR₁₄, carbon, sulfur, or oxygen, such as sulfur, and R₁₀-R₁₄ are independently absent, hydrogen, substituted alkyl, or unsubstituted alkyl.

27. The compound of claim 25, wherein Q₅ is sulfur; and R₁₀-R₁₄ are hydrogen.

28. The compound of claim 1, wherein for Formula Ia, IIa, or IIb, the compound has a structure: 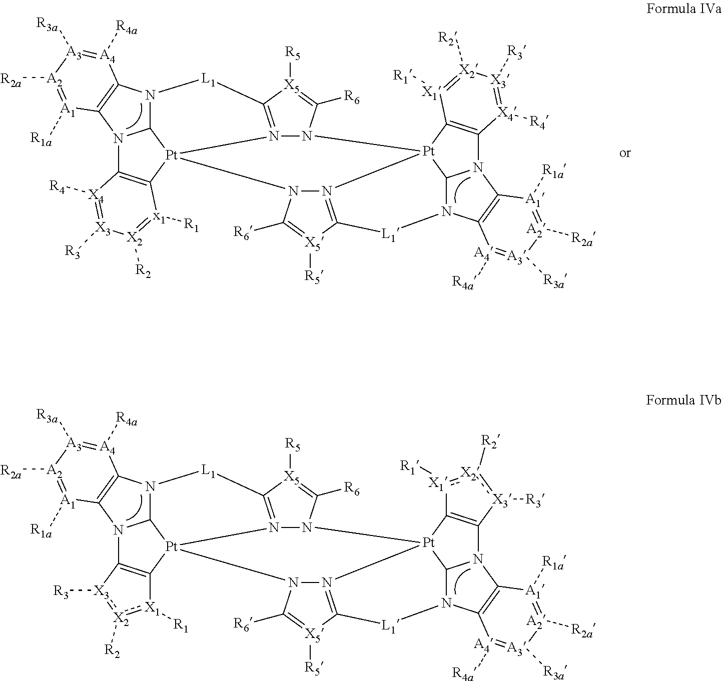
wherein:
A₁, A₂, A₃, A₄, A_{1′}, A₂, A_{3′}, and A_{4′} are independently carbon, nitrogen, oxygen, or sulfur, and are independently bonded to one or no hydrogen atom according to valency, and
X₁, X₂, X₃, X₄, X_{1′}, X_{2′}, X_{3′}, and X₄, when present, are independently carbon, nitrogen, oxygen, or sulfur, and are independently bonded to one or no hydrogen atom according to valency.

29. The compound of claim 28, wherein for Formula IVa, A₁, A₂, A₃, A₄, A_{1′}, A_{2′}, A_{3′}, and A₄, are carbon, and are independently bonded to one or no hydrogen atom according to valency, and X₁, X₂, X₃, X₄, X_{1′}, X_{2′}, X_{3′}, and X_{4′} are carbon, and are independently bonded to one or no hydrogen atom according to valency.

30. The compound of claim 28, wherein for Formula IVa, R₁, R₂, R₃, R₄, R_{1′}, R_{2′}, R₃, and R_{4′} are independently absent, hydrogen, deuterium, substituted alkyl, unsubstituted alkyl, substituted aryl, unsubstituted aryl, or halogen.

31. The compound of claim 28, wherein for Formula IVa, R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl, or R₁ₐ and R₂ₐ together, R₂ₐ and R₃ₐ together, R₃ₐ and R₄ₐ together, R_{1a′} and R_{2a′} together, R_{2a′} and R_{3a′} together, R_{3a′} and R_{4a′} together, or a combination thereof, with the atom to which they are attached, form a substituted aryl, or an unsubstituted aryl.

32. The compound of claim 28, wherein for Formula IVa, R₁ₐ and R₂ₐ together, R₃ₐ and R₄ₐ together, R_{1a′} and R_{2a′} together, R_{3a′} and R_{4a′} together, with the atom to which they are attached, form a substituted aryl, or an unsubstituted aryl.

33. The compound of claim 1, wherein for Formula Ia, IIa, or IVa, one or more of A₁, A₂, A₃, and A₄ are nitrogen, one or more of A_{1′}, A₂, A_{3′}, and A₄, are nitrogen, and A₁, A₂, A₃, A₄, A_{1′}, A₂, A_{3′}, and A₄, are independently bonded to one or no hydrogen atom according to valency, and X₁, X₂, X₃, X₄, X_{1′}, X_{2′}, X_{3′}, and X_{4′} are carbon, and are independently bonded to one or no hydrogen atom according to valency.

34. The compound of claim 33, wherein for Formula IVa, R₁, R₂, R₃, R₄, R_{1′}, R_{2′}, R_{3′}, and R₄, are independently absent, hydrogen, deuterium, substituted alkyl, unsubstituted alkyl, substituted aryl (such as mesityl (2,4,6-trimethylphenyl), 3,5-di-tert-butylphenyl, 2,6-dimethylphenyl), unsubstituted aryl, or halogen (such as fluorine).

35. The compound of claim 33, wherein R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl (such as phenyl).

36. The compound of claim 33, wherein for Formula IVa, one of A₁, A₂, A₃, and A₄ is nitrogen and the others are carbon, one of A_{1′}, A_{2′}, A_{3′}, and A₄, is nitrogen and the others are carbon, and A₁, A₂, A₃, A₄, A_{1′}, A_{2′}, A_{3′}, and A₄, are independently bonded to one or no hydrogen atom according to valency.

37. The compound of claim 33, wherein for Formula IVa, two of A₁, A₂, A₃, and A₄ are nitrogen and the others are carbon, two of A_{1′}, A_{2′}, A_{3′}, and A₄, are nitrogen and the others are carbon, and A₁, A₂, A₃, A₄, A_{1′}, A_{2′}, A_{3′}, and A₄, are independently bonded to one or no hydrogen atom according to valency.

38. The compound of claim 1, wherein for Formula Ia, IIa, or IVa, one or more of A₁, A₂, A₃, and A₄ are oxygen, nitrogen, or sulfur, one or more of A_{1′}, A_{2′}, A_{3′}, and A₄, are oxygen, nitrogen, or sulfur, and A₁, A₂, A₃, A₄, A_{1′}, A_{2′}, A_{3′}, and A₄, are independently bonded to one or no hydrogen atom according to valency, and one or more of X₁, X₂, X₃, X₄, X_{1′}, X_{2′}, X_{3′}, and X_{4′} are oxygen, nitrogen, or sulfur, and X₁, X₂, X₃, X₄, X_{1′}, X_{2′}, X_{3′}, and X_{4′} are independently bonded to one or no hydrogen atom according to valency.

39. The compound of claim 38, wherein for Formula IVa, R₁, R₂, R₃, R₄, R_{1′}, R_{2′}, R_{3′}, and R₄, are independently absent, hydrogen, deuterium, substituted alkyl, unsubstituted alkyl, substituted aryl, unsubstituted aryl, or halogen (such as fluorine).

40. The compound of claim 38, wherein R₁ₐ, R₂ₐ, R₃ₐ, R₄ₐ, R_{1a′}, R_{2a′}, R_{3a′}, and R_{4a′} are independently absent, hydrogen, deuterium, substituted alkyl, unsubstituted alkyl, substituted aryl, or unsubstituted aryl.

41. The compound of claim 38, wherein for Formula IVa, one or more of A₁, A₂, A₃, and A₄ are nitrogen, one or more of A_{1′}, A₂, A_{3′}, and A₄, are nitrogen, and A₁, A₂, A₃, A₄, A_{1′}, A_{2′}, A_{3′}, and A₄, are independently bonded to one or no hydrogen atom according to valency, and one or more of X₁, X₂, X₃, X₄, X_{1′}, X_{2′}, X_{3′}, and X_{4′} are nitrogen, and X₁, X₂, X₃, X₄, X_{1′}, X_{2′}, X_{3′}, and X_{4′} are independently bonded to one or no hydrogen atom according to valency.

42. The compound of claim 38, wherein for Formula IVa, one of A₁, A₂, A₃, and A₄ is nitrogen and the others are carbon, one of A_{1′}, A_{2′}, A_{3′}, and A₄, is nitrogen and the others are carbon, and A₁, A₂, A₃, A₄, A_{1′}, A_{2′}, A_{3′}, and A₄, are independently bonded to one or no hydrogen atom according to valency, and one of X₁, X₂, X₃, and X₄ is nitrogen and the others are carbon, one of X_{1′}, X_{2′}, X_{3′}, and X_{4′} is nitrogen and the others are carbon, and X₁, X₂, X₃, X₄, X_{1′}, X_{2′}, X_{3′}, and X_{4′} are independently bonded to one or no hydrogen atom according to valency.

43. The compound of claim 1, having a structure:

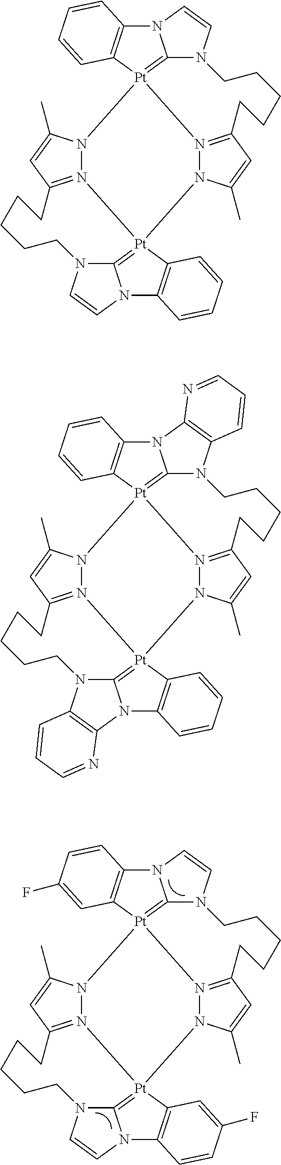

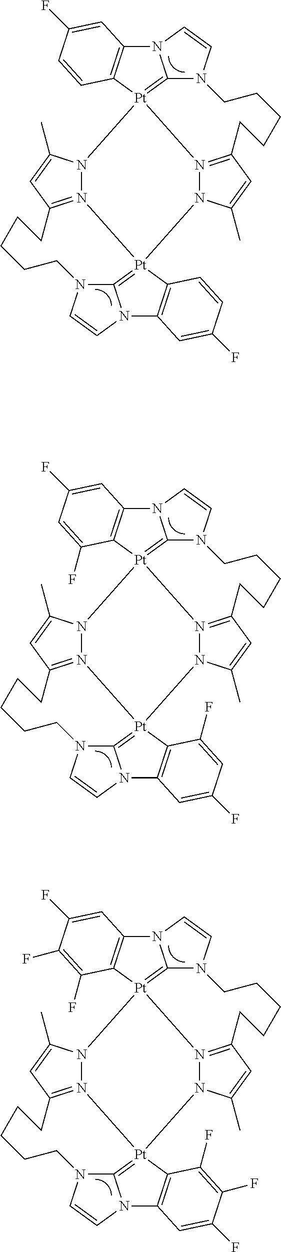

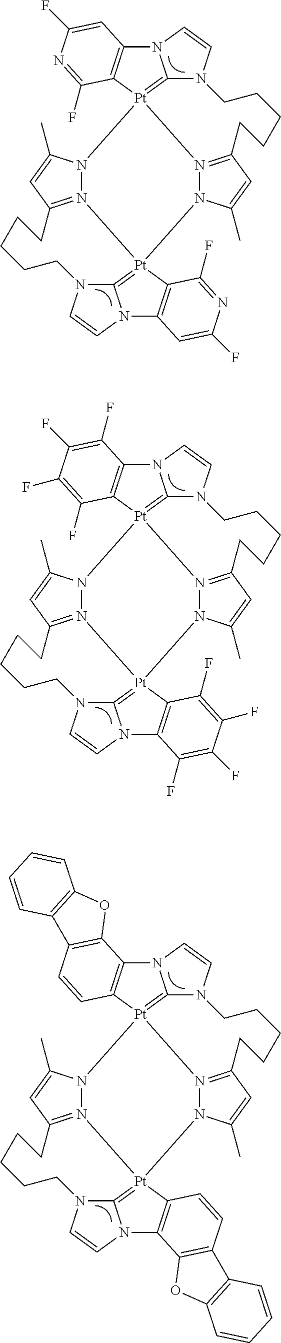

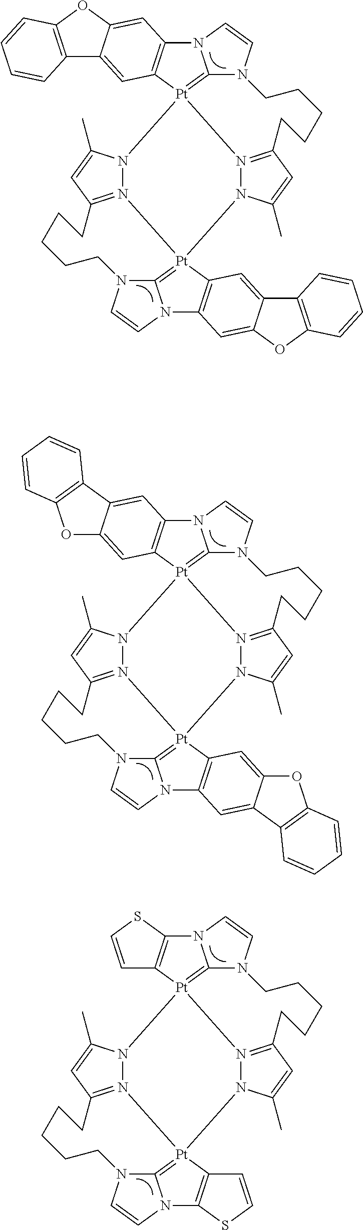

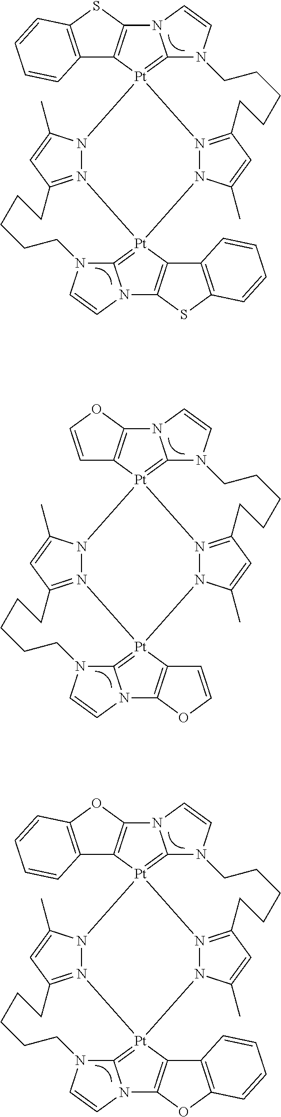

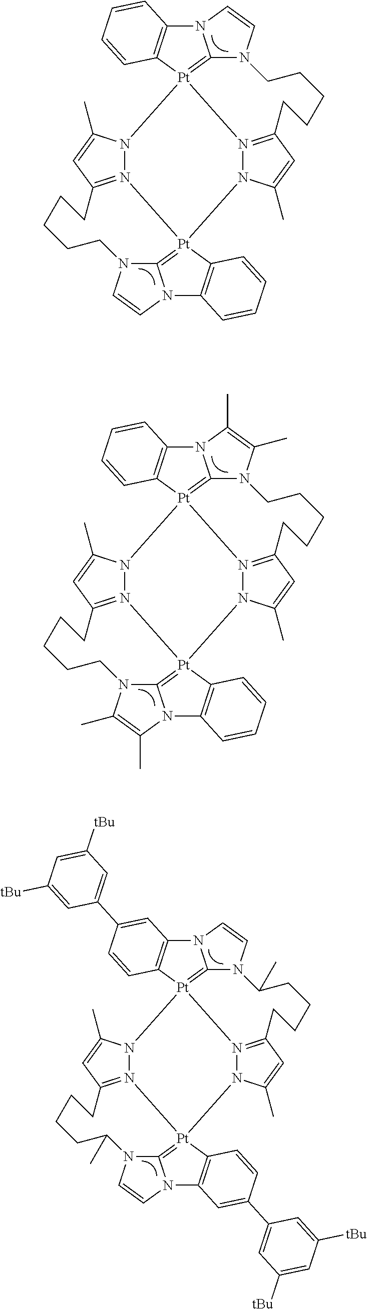

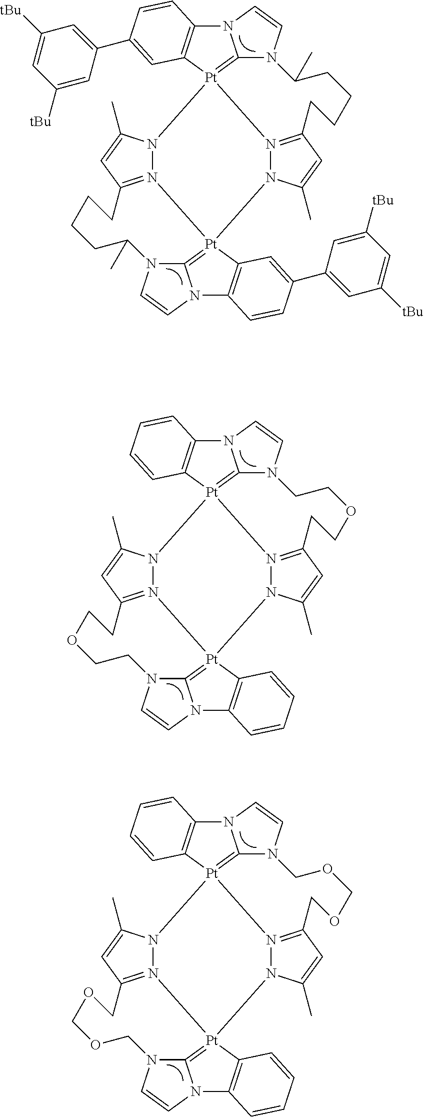

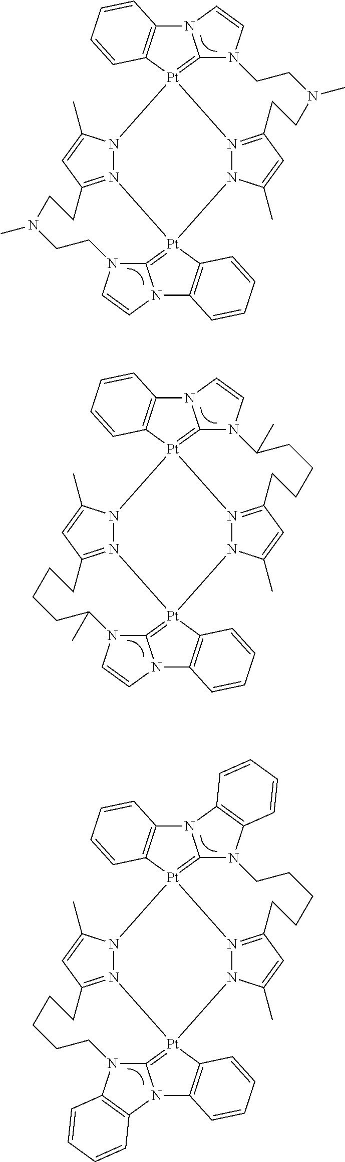

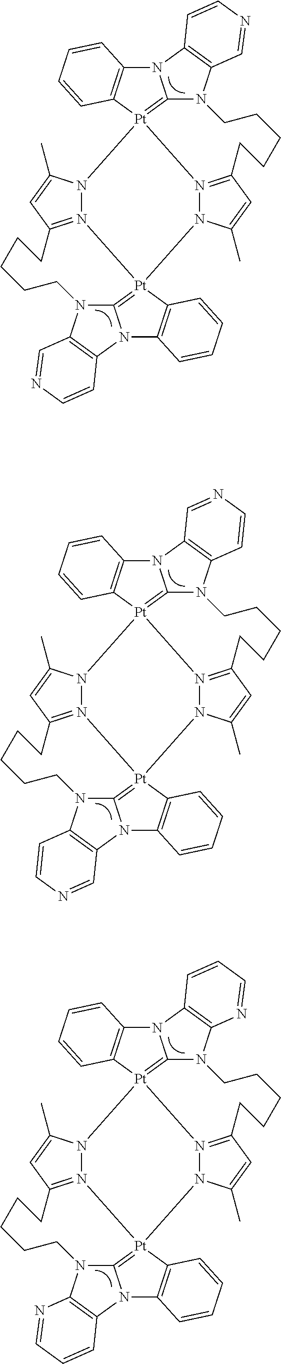

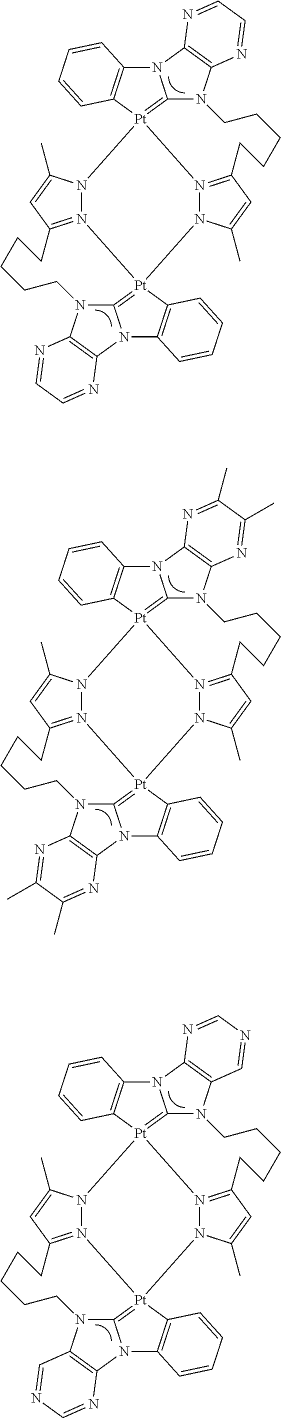

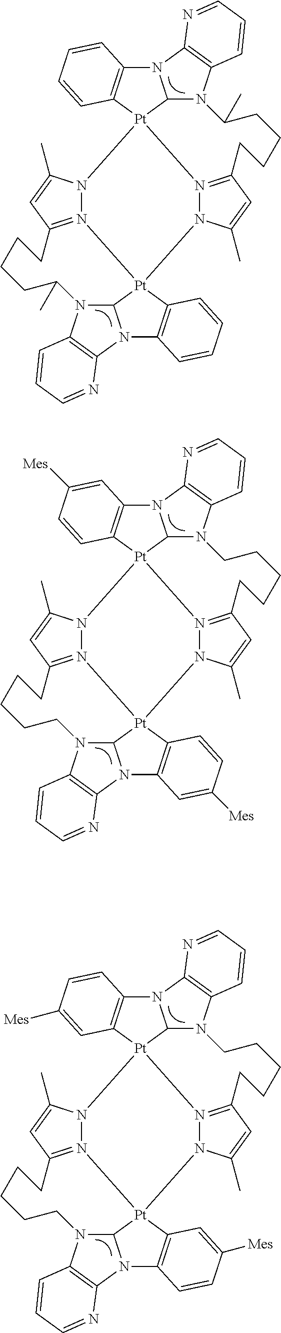

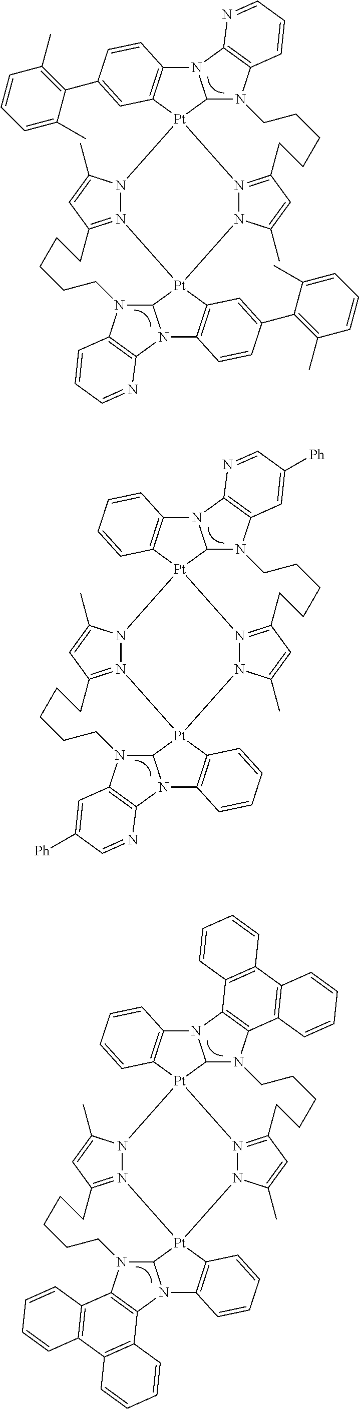

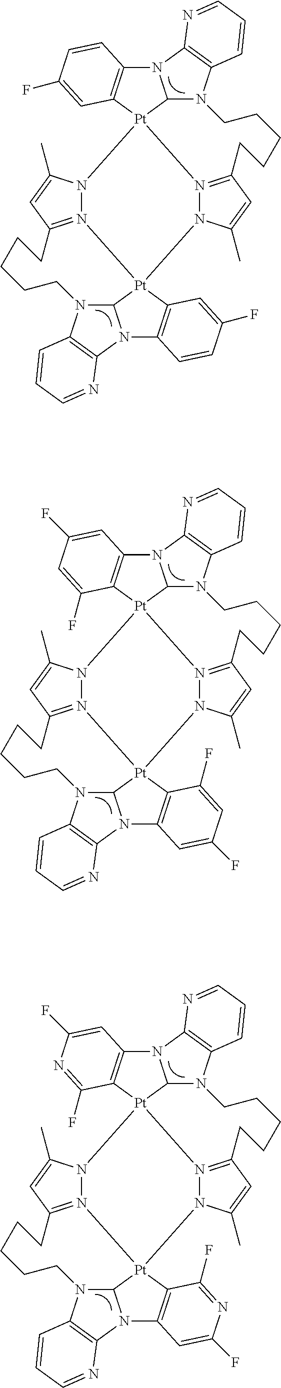

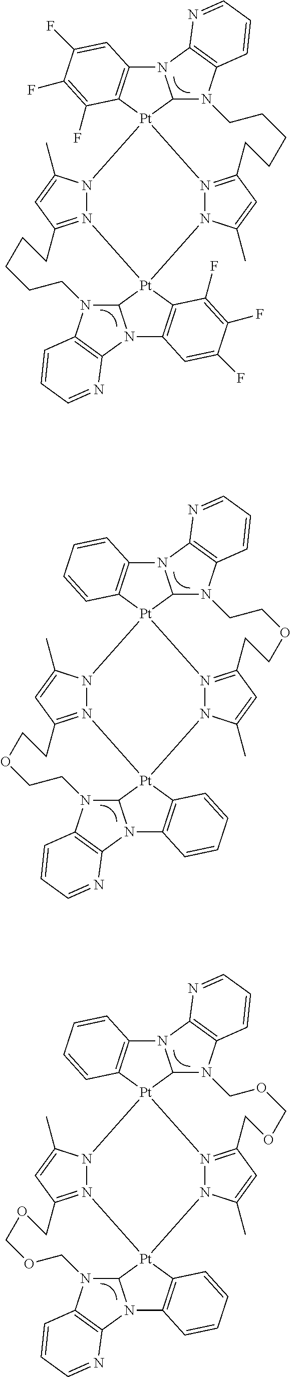

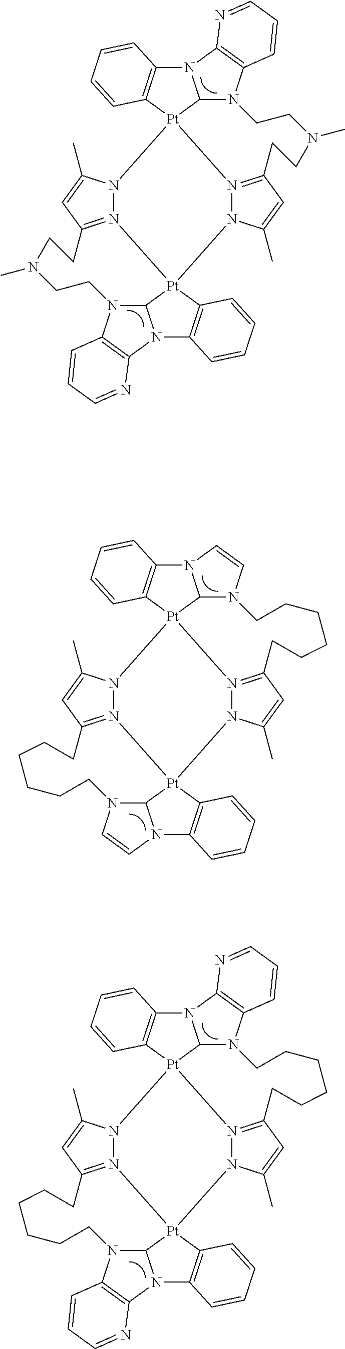

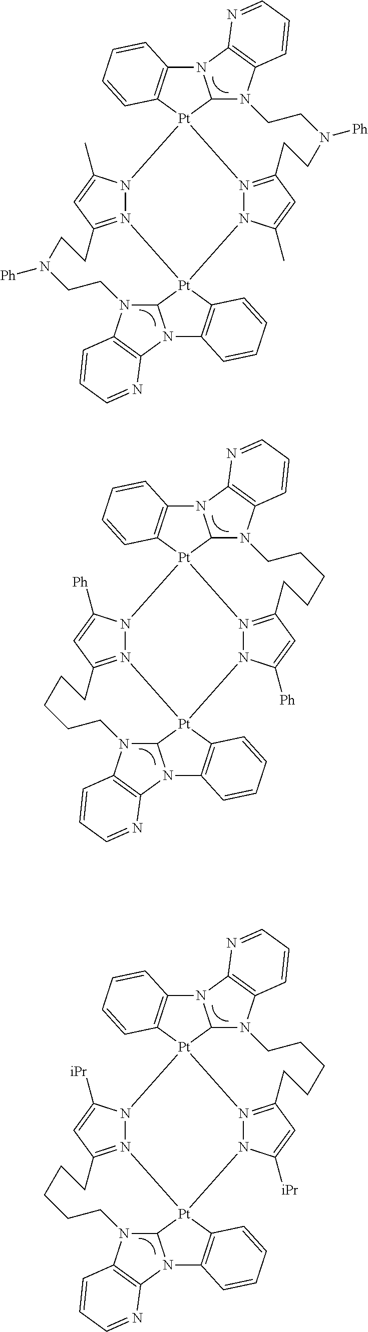

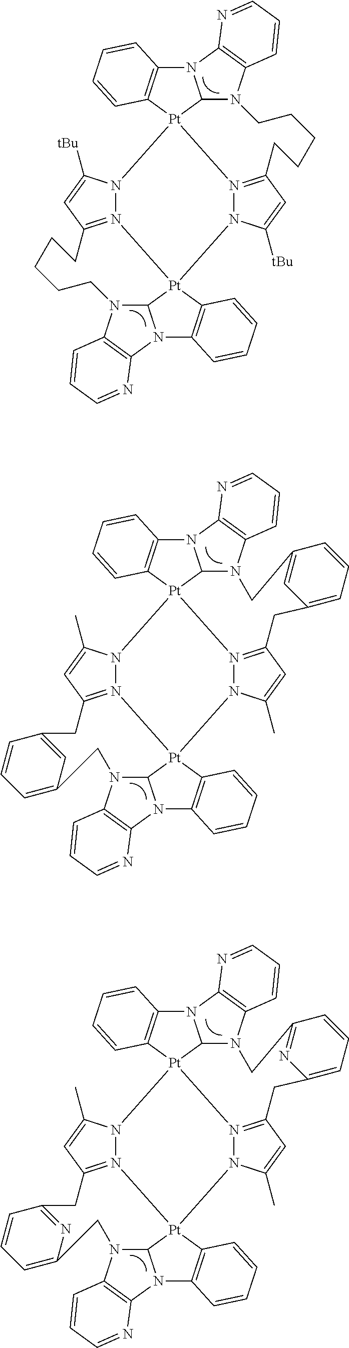

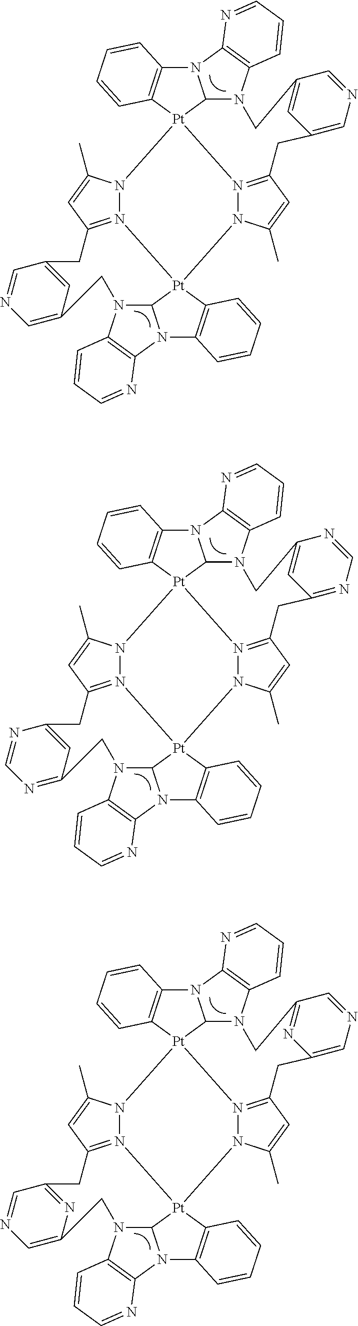

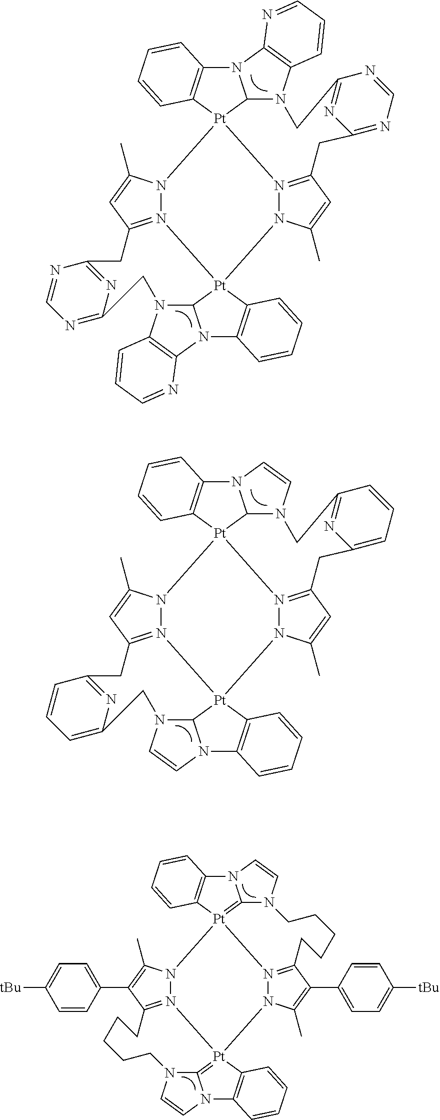

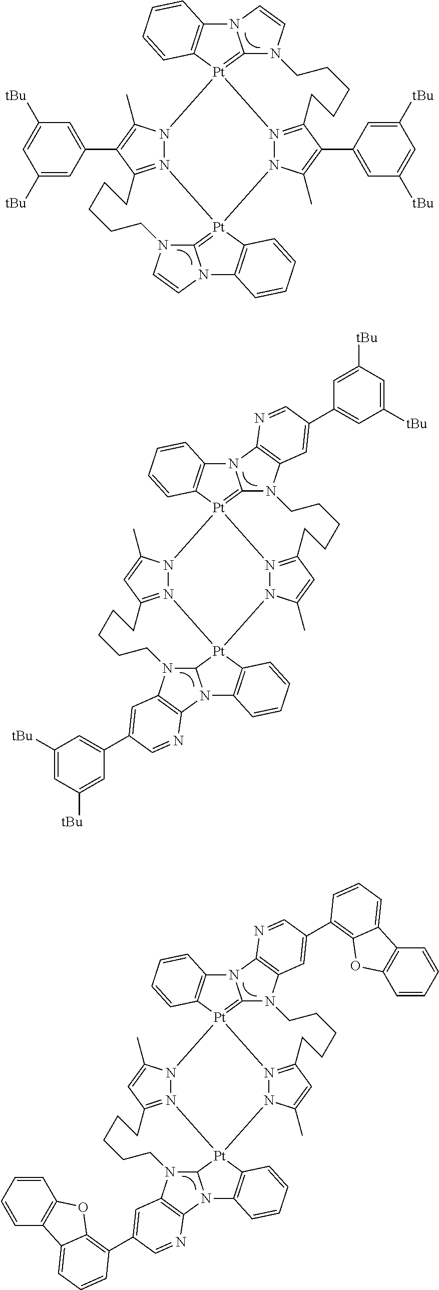

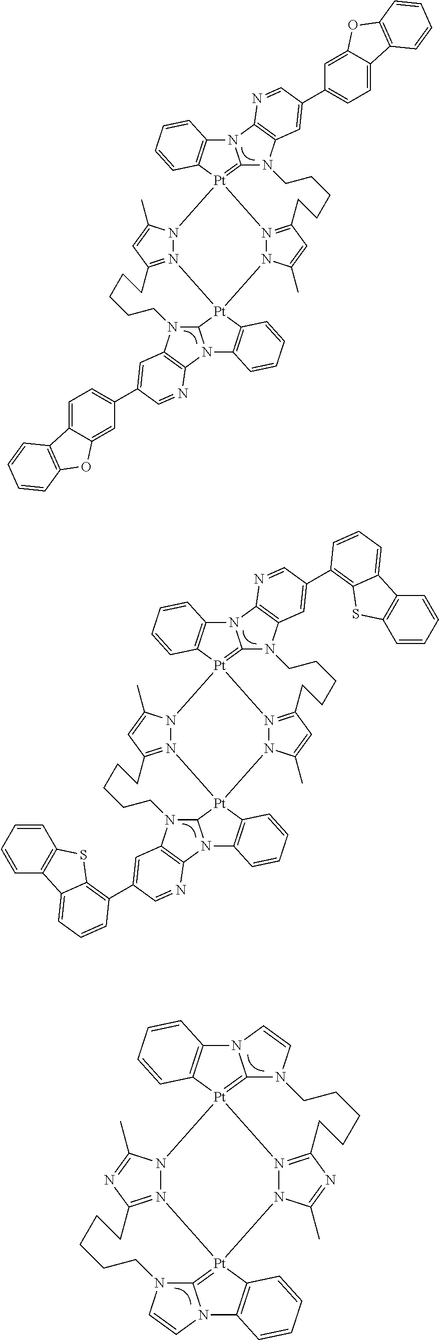

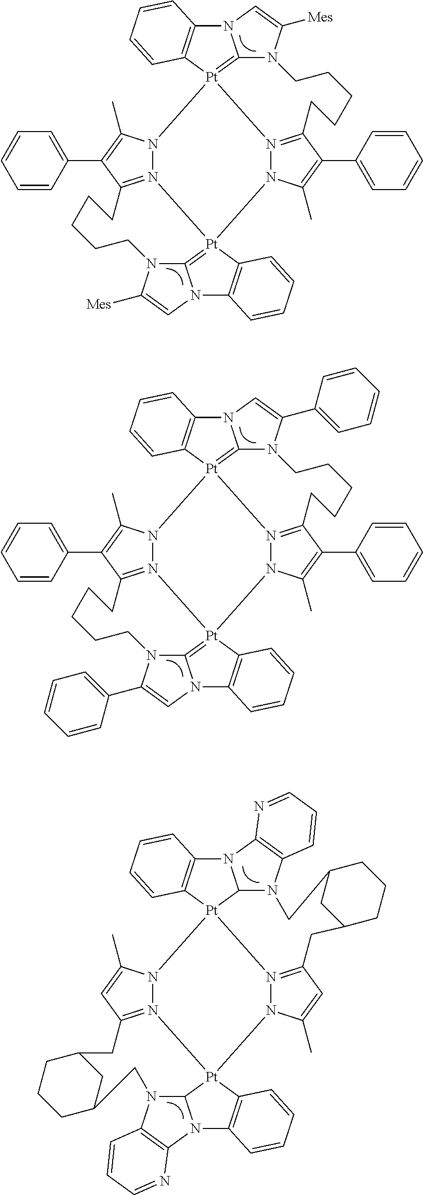

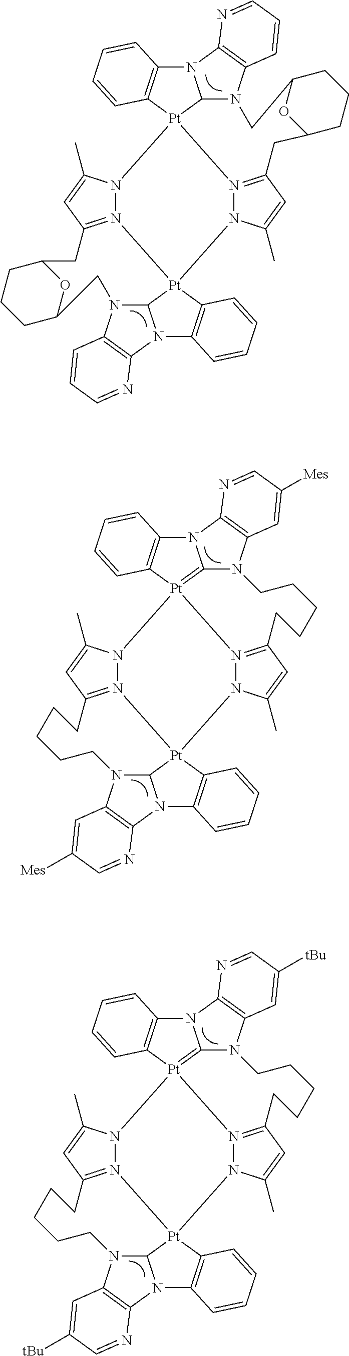

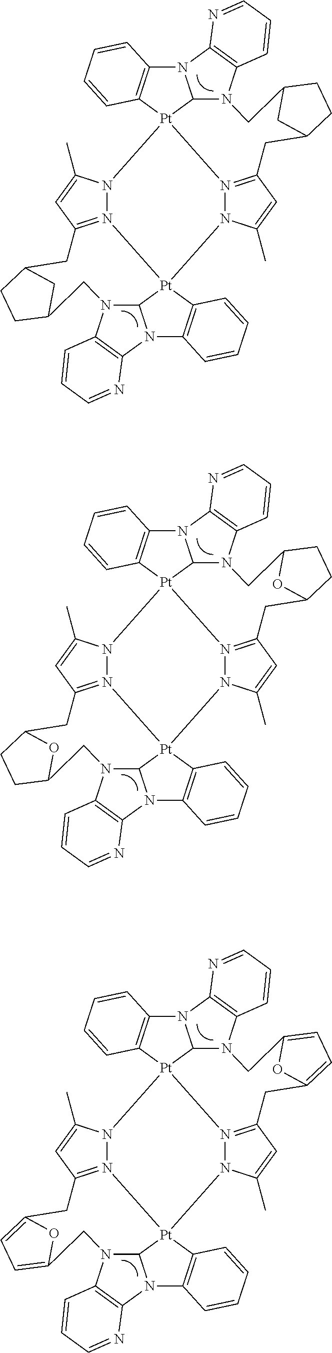

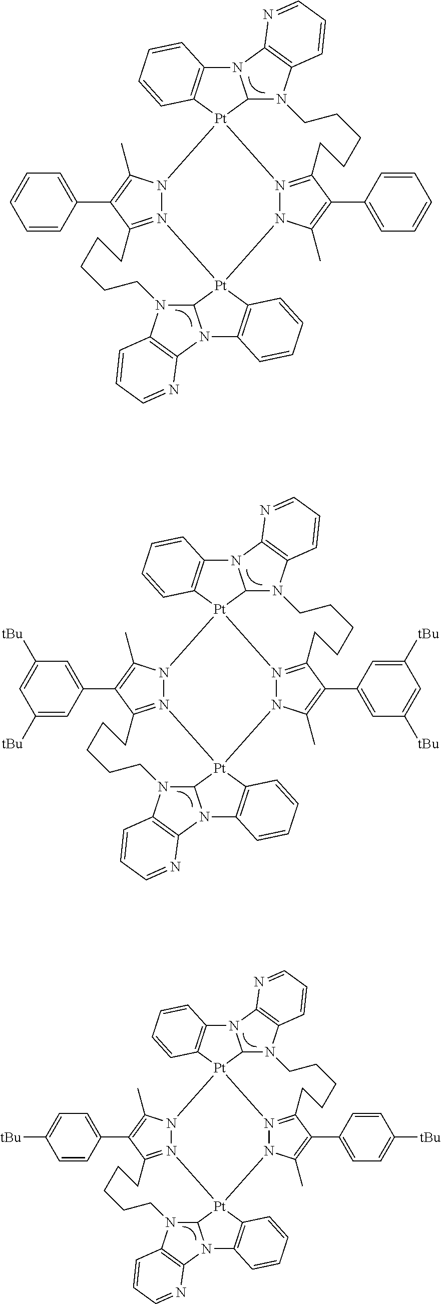

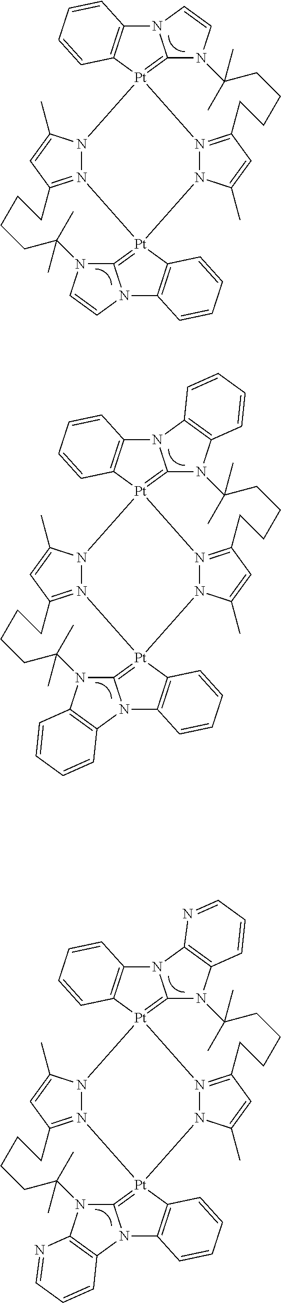

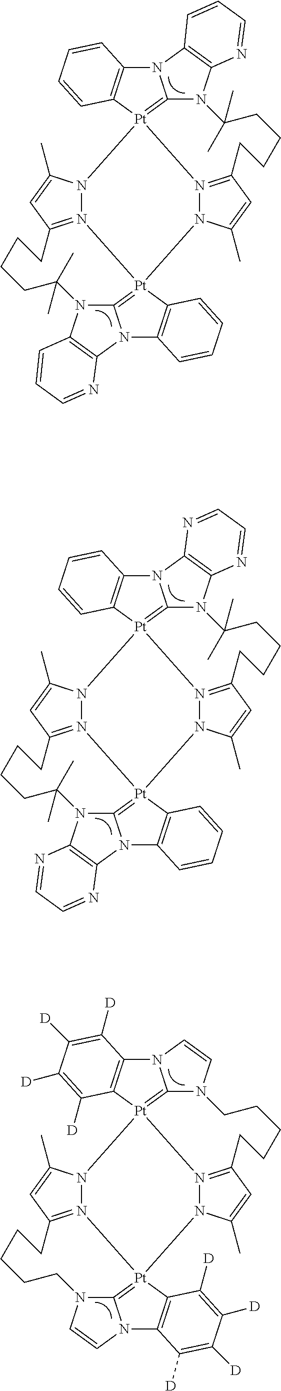

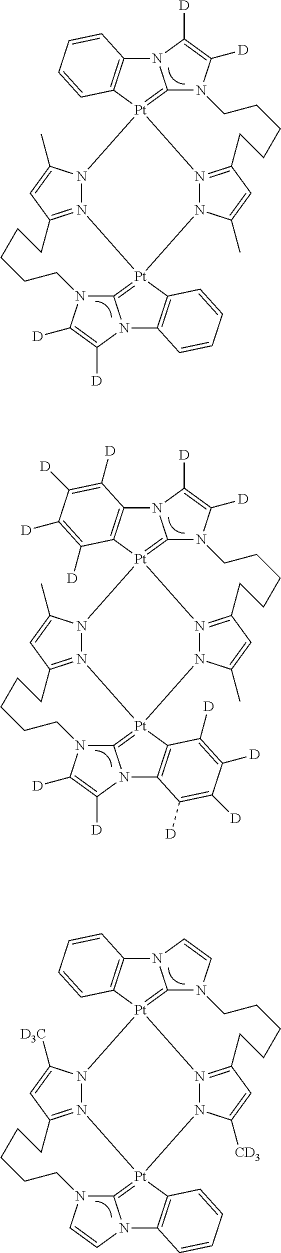

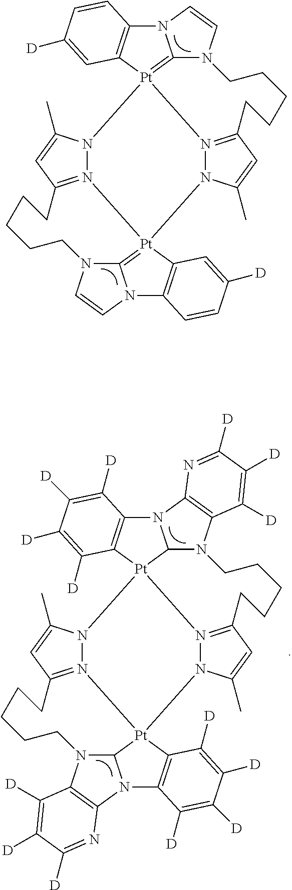

44. An organic electronic component comprising the compound of claim 1.

45. The organic electronic component of claim 44, wherein the organic electronic component is an organic light-emitting diode (OLED) or a light-emitting electrochemical cell (LEEC).

46. The organic electronic component of claim 44 wherein the compounds are in a light-emitting layer.

47. The organic electronic component of claim 44, further comprising an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located between the anode and the light-emitting layer, and wherein the electron transport region is located in between the cathode and the light-emitting layer.

48. The organic electronic component of claim 46, wherein the light-emitting layer is fabricated by vacuum deposition, spin-coating or ink printing (such as, ink-jet printing or roll-to-roll printing).

49. A light-emitting layer comprising the compound of claim 1.

50. The light-emitting layer of claim 49, further comprising a pure organic emitter, wherein the compound:
(i) acts as a sensitizer to transfer energy to the pure organic emitter, or
(ii) has a higher-lying singlet state than the pure organic emitter.

51. An OLED, comprising the light-emitting layer of claim 49.

52. A device, comprising the OLED of claim 51, wherein the device is selected from stationary visual display units, mobile visual display units, illumination units, keyboards, clothes, ornaments, garment accessories, wearable devices, medical monitoring devices, wall papers, tablet computers, laptops, advertisement panels, panel display units, household appliances, or office appliances.
